(19) United States
(12) Patent Application Publication
(10) Pub. No.: US 2008/0002460 A1
(43) Pub. Date: Jan. 3, 2008

(54) Structure and method of making lidded chips

(75) Inventors: David B. Tuckerman, Lafayette, CA (US); Giles Humpston, Aylesbury (GB); Michael J. Nystrom, San Jose, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/711,882

(22) Filed: Feb. 27, 2007

Related U.S. Application Data
(60) Provisional application No. 60/777,940, filed on Mar. 1, 2006.

(51) Int. Cl. H01L 31/0232; G11C 11/00; H01L 21/02; H01L 21/82; H01L 23/02; H01L 23/04

(52) U.S. Cl. 365/158; 257/432; 257/678; 257/680; 257/698; 438/113; 438/118; 438/121; 438/128; 257/E23.011; 257/E23.079; 257/E23.08; 257/E21.599; 257/E21.602

(57) ABSTRACT

Methods are provided for fabricating packaged chips, each packaged chip having a protective layer, e.g., a transparent lid, metallic enclosure layer, shield layer, etc., and methods are provided for manufacturing such protective layer to be incorporated into a packaged chip. Lidded chip structures, and assemblies are also provided which include lidded chips.

### CROSS-REFERENCE TO RELATED APPLICATIONS

This application claims the benefit of the filing date of U.S. Provisional Patent Application No. 60/777,9.40 filed Mar. 1, 2006, the disclosure of which is hereby incorporated herein by reference. The following applications are hereby incorporated by reference herein. U.S. patent application Ser. No. 10/949,575 filed Sep. 24, 2004, U.S. Provisional Patent Application Nos. 60/506,500 filed Sep. 26, 2003 60/515,615 filed Oct. 29, 2003, 60/532,341 filed Dec. 23, 2003, 60/568,041 filed May 4, 2004, 60/574,523 filed May 26, 2004, and U.S. patent application Ser. No. 10/928,839 filed Aug. 27, 2004. The following U.S. Patent Applications and U.S. Provisional Patent Applications are also hereby incorporated herein by reference: 11/121,434 filed May 4, 2005, 10/711,945 filed Oct. 14, 2004, 11/120,711 filed May 3, 2005, 11/068,830 filed Mar. 1, 2005, 11/068,831 filed Mar. 1, 2005, 11/016,034 filed Dec. 17, 2004, 11/284,289 filed Nov. 21, 2005, 11/300,900 filed Dec. 15, 2005, 10/977,515 filed Oct. 29, 2004, 11/025,440 filed Dec. 29, 2004, 11/204,680, filed Aug. 16, 2005, 60/664,129 filed Mar. 22, 2005, 60/707,813 filed Aug. 12, 2005, 60/732,679 filed Nov. 2, 2005 and 60/736,195 filed Nov. 14, 2005.

### BACKGROUND OF THE INVENTION

The present invention relates to microelectronic packaging. Microelectronic chips typically are thin, flat bodies with oppositely facing, generally planar front and rear surfaces and with edges extending between these surfaces. Chips generally have contacts on the front surface, which are electrically connected to the circuits within the chip. Certain chips require a protective element, referred to herein as a cap or lid, over all or part of the front surface. For, example, chips referred to as surface acoustic wave or “SAW” chips incorporate acoustically-active regions on their front surfaces, which must be protected from physical and chemical damage by a cap. Micro-electromechanical or “MEMS” chips include microscopic electromechanical devices, e.g., acoustic transducers such as microphones, which must be covered by a cap. The caps used for MEMS and SAW chips must be spaced from the front surface of the chip to an open gas-filled or vacuum void beneath the cap in the active area, so that the cap does not touch the acoustical or mechanical elements. Certain electro-optical chips such as optical sensing chips and light-emitting chips have photosensitive elements which also must be protected by a lid. Voltage controlled oscillators (VCOs) sometimes also require a cap to be placed over the active area.

Miniature SAW devices can be made in the form of a wafer formed from or incorporating an acoustically active material such as lithium niobate or lithium tantalate material. The wafer is treated to form a large number of SAW devices, and typically also is provided with electrically conductive contacts used to make electrical connections between the SAW device and other circuit elements. After such treatment, the wafer is severed to provide individual devices. SAW devices fabricated in wafer form can be provided with caps while still in wafer form, prior to severing. For example, as disclosed in U.S. Pat. No. 6,429,511 a cover wafer formed from a material such as silicon can be treated to form a large number of hollow projections and then bonded to the top surface of the active material wafer, with the hollow projections facing toward the active wafer. After bonding, the cover wafer is polished to remove the material of the cover wafer down to the projections. This leaves the projections in place as caps on the active material wafer, and thus forms a composite wafer with the active region of each SAW device covered by a cap.

Such a composite wafer can be severed to form individual units. The units obtained by severing such a wafer can be mounted on a substrate such as a chip carrier or circuit panel and electrically connected to conductors on the substrate by wire-bonding to the contacts on the active wafer after mounting, but this requires that the caps have holes of a size sufficient to accommodate the wire bonding process. This increases the area of the active wafer required to form each unit, requires additional operations and results in an assembly considerably, larger than the unit itself.

In another alternative disclosed by the 511 patent, terminals can be, formed on the top surfaces of the caps and electrically connected to the contacts on the active wafer prior to severance as, for example, by metallic vias formed in the cover wafer prior to assembly. However, formation of terminals on the caps and vias for connecting the terminals to the contacts on the active wafer requires a relatively complex series of steps.

Similar problems occur in providing terminals for MEMS devices. For these and other reasons, further improvements in, processes and structures for packaging SAW, MEMS, electro-optical and other capped devices would be desirable.

### SUMMARY OF THE INVENTION

In accordance with an aspect of the invention, a method is provided for manufacturing a metal-containing lid for use in protectively covering a device region of, a chip. In such method a first metal layer is electro-formed on a mandrel having a first major surface, a second major surface opposite the first major surface. Desirably, a plurality of projections extending from at least one surface of the mandrel to form a plurality of through holes in the first metal layer corresponding to the projections. Walls of the plurality of through holes are desirably aligned at defined angles to the first major surface.

In accordance with a particular aspect of the invention, the metal layer may consist essentially of at least one of copper or nickel. The method may further include depositing a layer including aluminum to overlie at least portions of the through holes.

In accordance with a preferred embodiment, the layer of aluminum overlies a portion of at least one of the first and major surfaces of the metal layer.

In a particular embodiment, the layer includes aluminum. The layer may then be anodized to form an insulating layer including anodized aluminum overlying at least a portion of the first metal layer.

Desirably, an insulating material is deposited over the first metal to form an insulating layer overlying at least a portion of the first metal layer.

In a particular embodiment, the insulating material includes a polymer. The thickness of insulating material may desirably be at least one micron.

When the method includes forming an anodized aluminum layer, the layer desirably has a pore height from between about 10 microns and about 100 microns. In a particular embodiment, the thickness of the anodized aluminum layer can be at least about one micron.

In a particular embodiment, the step of anodizing the layer includes imparting one of a plurality of selectable colors to the anodized layer.

The method may further include interconnecting at least some bond pads of the chip to the first metal layer of the lid, such that the lid functions as a conductive plane, e.g., a ground plane.

In accordance with another aspect of the invention, a packaged magnetically shielded memory includes magnetoresistive (“MR”) storage cells. Included in the magnetically shielded memory is a chip which includes a memory with a plurality of MR storage cells, the chip having a front face, and a rear face remote from the front face. Desirably, a plurality of bond pads are exposed at the front face. A first layer of material having a relatively high magnetic permeability desirably underlies the rear face of the chip. A second layer of material having a relatively high magnetic permeability may overlie the front face of the chip and has a plurality of through holes aligned with the bond pads at the front face. Desirably, a plurality of conductive interconnections extend from the bond pads at least partially through the through holes.

In accordance with one or more preferred aspects of the invention, the packaged memory may further include dielectric layers lining the through holes in the second layer. Desirably, wettable metal layers overlie the dielectric layers. The conductive interconnections may include a fusible material that overlies the wettable metal layers.

The wettable metal layers may overlie intermediate metal layers and the intermediate metal layers then overlie contact metal layers which contact the dielectric layers.

In a particular embodiment, the memory may include a magnetoresistive random access memory (“MRAM”).

In an embodiment, the first and second layers of the shielded memory structure include mu-metals.

Through holes of the structure desirably have first widths at an inner surface of the second layer and have second widths wider than the first widths at an outer surface of the second layer. The walls of the through holes may also be inclined outwardly between the inner surface and the outer surface.

According to another aspect of the invention, a method is provided for fabricating a plurality of packaged magnetically shielded memory chips each of which includes magnetoresistive (“MR”) storage cells. In accordance with such aspect, a wafer element is provided which includes a plurality of the chips. A first layer having a high magnetic permeability desirably underlies the rear face of the wafer element and a second layer having a high magnetic permeability can overlie the front face of the wafer. A plurality of through holes may be aligned to bond, pads of chips within the wafer element. A plurality of conductive interconnections can be formed which extend from the bond pads at least partially through the through holes.

In accordance with another aspect of the invention, a lidded optical chip is provided which includes a chip having a device region and bond pads exposed at a front surface of the chip. A lid including a light transmissive inorganic material may be mounted above the front surface of the chip, the lid having an inner surface disposed adjacent to the front surface of the chip and an outer surface remote from the front surface. At least one optical layer can be provided disposed such that it either overlies the outer surface of the lid or underlies the lid's inner surface. The optical layer may also include an organic material which is operable to perform at least one of altering an optical characteristic of light incident on the optical layer, or imparting a property to the lid.

The optical layer may be such as to perform at least one of filtering the light incident on the optical layer or to impart at least one of an anti-reflective, anti-static, anti-fogging, or anti-scratch property to the lid.

In one embodiment, the optical layer may include a first optical layer overlying the outer surface and a second optical layer underlying the inner surface.

In accordance with another aspect of the invention, a method is provided for making a microelectronic device. Such method includes (a) assembling a lid element with a wafer element. The wafer element desirably has a front surface including a plurality of regions, each such region including an active area and a plurality of contacts exposed at the front surface outside of the active area. The lid element may overlie the front surface of the wafer element. In a step (b) holes may be formed in the lid element so as to expose individual ones of the contacts. In a step (c), the wafer element and the lid element may then be severed along severance lines intersecting the holes to thereby form a plurality of units. Each such unit can then include a lid which has one or more holes aligned to individual ones of the contacts.

In accordance with an aspect of the invention, a method is provided for making a microelectronic device. Such method includes (a) assembling a lid element with a wafer element. The wafer element may have a front surface including a plurality of regions and each such region may an active area and a plurality of contacts exposed at the front surface outside of the active area. Desirably, the lid element overlies the front surface of the wafer element. In a step (b) holes can be drilled in the lid element to expose the contacts, and in a step (c) the wafer element and the lid element can be severed along severance lines to thereby form a plurality of units. Each such unit can then include a lid having one or more openings aligned with the contacts. The openings may coincide with the holes.

In accordance with one or more preferred aspects of the invention, the lid element has an outer surface and an inner surface. The assembling step may be performed so that the outer surface faces upwardly, away from the wafer unit. In addition, the hole-forming step can be performed so that the holes taper inwardly in a downward direction from the outer surface toward the inner surface.

Desirably, the method may further include forming a seal extending between the wafer unit and the lid element which overlies the contacts. Holes may then be formed in the seal in alignment with the holes in the lid element prior to the severing step.

In a particular embodiment, the holes in the seal can be formed by laser drilling after the holes are formed in the lid element. Holes in the seal may be formed by etching after the holes are formed in the lid element.

Desirably, the step of drilling is performed using an ultrasonic drilling tool. Desirably, the ultrasonic drilling tool may include removable rods for contacting the outer surface of the lid element to form the holes. Desirably, the removable rods are desirably removable when worn and replaceable with other removable rods.

Desirably, prior to the hole-forming step, the lid element has planar inner and outer surfaces.

Desirably, the step of drilling the holes in the lid element is performed using an ultrasonic tool. The lid element may be severed along the lines of severance by simultaneously machining the lid element with the ultrasonic tool while drilling the holes in the lid element.

Desirably, the seal includes at least a portion having a low modulus of elasticity and the seal underlies the severance lines of the lid element. The lid element may desirably be severed such that at least a portion of the seal underlying the severance lines remains after the lid element is severed during the simultaneous machining. The wafer element can be severed along severance lines of the wafer after drilling the holes and machining the lid element.

In a particular embodiment, the seal may include at least a portion which has a low modulus of elasticity, the seal underlying the severance lines of the wafer element such that when the wafer element is severed at least a portion of the seal underlying the severance lines remains after the wafer element is severed. The remaining portion of the seal may connect portions of the lid element and the wafer element severed by the machining of the lid element and by the step of severing the wafer element.

In accordance with another embodiment of the invention, a packaged chip-on-board optoelectronic assembly is provided which may include a circuit panel which has a major surface and a recess extending downwardly from the major surface into a body of the circuit panel. An optoelectronic chip may be provided which has a front face and a rear face remote from the front face. An optoelectronic device may be exposed at the front face of the optoelectronic chip, and the rear face may be disposed below the major surface within the recess. A turret is mounted to the circuit panel, the turret having an optical element which is aligned to the optoelectronic device of the chip. Desirably, the rear face of the chip is bonded to the circuit panel within the recess.

Desirably, the chip is bonded with a die attach adhesive to the circuit panel, and the die attach adhesive is disposed wholly below the major surface of the circuit panel.

In a particular embodiment, the recess is a blind cavity, wherein dimensions of the recess align the chip to the turret. Desirably, the dimensions of the recess align the chip to the turret with respect to translation and rotation.

In one embodiment, the recess is a first recess, and the circuit panel further includes at least one second recess. The turret may include at least one member mounted to the circuit panel within the second recess. Desirably, the member at least assists in aligning the turret to the circuit panel.

In a particular embodiment, the circuit panel may include a plurality of the second recesses and a plurality of the members can be mounted to the circuit panel within the second recesses. In such case, the members can positively align the turret to the circuit panel with respect to translation and rotation.

Joints between the members of the turret and the circuit panel may include adhesives which bond multiple surfaces of the members to inner walls of the second recesses.

A method is provided for making a microelectronic device according to another embodiment of the invention. Such method includes (a) assembling a lid element with a wafer element, the wafer element having a front surface including a plurality of regions. Each region may include an active area and a plurality of contacts exposed at the front surface outside of the active area. The lid element may overlie the front surface of the wafer element and have a plurality of openings which expose the contacts of the wafer element. In a step (b) a metal may be electrolessly plated in the openings to form conductive interconnects extending from the contacts at least partially up a height of the openings.

Desirably, the lid element and the wafer element are assembled with a layer of adhesive between the lid element and the wafer element. The method desirably further includes forming holes in the layer of adhesive aligned to the contacts after assembling the lid element with the wafer element and prior to the step of electrolessly plating the metal to form the conductive interconnects.

Desirably, the metal includes at least one metal selected from the group consisting of copper, nickel, silver, gold and alloys of any of copper, nickel, silver and gold.

In accordance with yet another embodiment of the invention, a method is provided for making a microelectronic device. Such method includes (a) assembling a lid element with a wafer element. The wafer element has a front surface including a plurality of regions. Each such region desirably includes an active area and a plurality of contacts exposed at the front surface outside of the active area. The lid element desirably overlies the front surface of the wafer element and has a plurality of openings which expose the contacts of the wafer element. In a step (b) conductive interconnects may be formed in the openings, and the conductive interconnects may extend from the contacts at least partially up a height of the openings. The steps of a) assembling and b) forming the conductive interconnects can be performed at temperatures which do not exceed 100 degrees Celsius.

In accordance with another embodiment of the invention, a lidded chip is provided which includes a chip having an upwardly facing front surface and a plurality of bond pads exposed in a bond pad region at the front surface. A lid having an outer surface, an inner surface opposite the outer surface, and a plurality of openings extending between the inner and outer surfaces can be mounted to the chip and spaced therefrom to define a void. A plurality of electrically conductive interconnects may be provided which extend at least partially through the openings. A heat spreader can be mounted to a rear surface of the chip opposite from the front surface. The heat spreader can cover substantially all of the rear surface.

Desirably, the mechanical strength of the lidded chip is increased by presence of the heat spreader.

In a particular embodiment, the bond pad region extends to edges of the chip. Each of the openings may extend in a direction along the edges to expose a plurality of the bond pads.

Desirably, each of the edges of the chip and the heat spreader are aligned.

In accordance with one aspect of the invention, a lidded chip is provided which includes a chip having a device at a front face of the chip, such as a microelectronic or a micro-electromechanical device at a front face of the chip. A lid may overlie the at least one device. A supporting structure may overlie the front face to support the lid above the front face. In such embodiment, the supporting structure has a first material affixed to one of an inner surface of the lid or the front face of the chip. An adhesive including a second material may join the supporting structure to the other of the inner surface of the lid or the front face of the chip.

In a particular embodiment, the adhesive is a flowable adhesive and can be applied to an exposed surface of the supporting structure to join the supporting structure to the other of the inner surface of the lid or the front face of the chip. Desirably, the adhesive is applied to the exposed surface of the supporting structure using a roller.

In one embodiment, the adhesive can have a thickness of about 1 micron.

In one embodiment, the thickness of the supporting structure in a direction of a height of the inner surface of the lid above the front surface is greater than the thickness of the adhesive in that direction. Desirably, the supporting structure has a thickness about 10 times greater than the thickness of the adhesive.

The supporting structure can be affixed to the inner surface of the lid. For example, the supporting structure can be affixed to the front face of the chip.

Desirably, the lidded chip further includes a plurality of conductive interconnects exposed at an outer surface of the lid. The conductive interconnects can extend, for example, from contacts on the front face of the chip at least partially through the through holes in the lid.

In accordance with another aspect of the invention, a method is provided for fabricating an assembly including a plurality of vertically stacked packaged chips. Such method desirably includes (a) aligning a temporary element on a fixture, and (b) aligning a packaged chip with an opening in the temporary element. The steps (a) and (b) may be repeated in succession one or more times, each time by stacking another temporary element on the fixture and aligning another packaged chip within an opening in the another temporary element. The packaged chips may then be bonded to each other.

In one preferred embodiment, the temporary elements can be soluble in a solvent and the method may further include dissolving the temporary elements in the solvent after the step of bonding the packaged chips to each other.

The packaged chips may include a plurality of contacts having a fusible conductive material exposed at surfaces of the contacts. The step of bonding be performed by raising a temperature of the packaged chips to a temperature sufficient to cause the fusible conductive material to contact at least adjacent ones of the packaged chips.

Desirably, the temporary elements include water-soluble paper and the method includes dissolving the temporary elements in water.

Desirably, the step of aligning the temporary elements to the fixture includes aligned holes of the temporary elements with pins of the fixture.

In accordance with another embodiment of the invention, an assembly can be provided which includes an optoelectronic chip. Such assembly desirably includes a chip which has an optoelectronic device and microelectronic circuits exposed at a major surface. A film may overlie the optoelectronic device and the microelectronic circuits, the film desirably being substantially transparent to wavelengths of radiation of interest to operation of the optoelectronic device and being substantially opaque to at least either wavelengths below the wavelengths of interest or above the wavelengths of interest, or both.

Desirably, the assembly may include a partially transparent item mounted above the optoelectronic device and the microelectronic circuits of the chip. The partially transparent item may be substantially opaque to a range of wavelengths above the wavelengths of interest. In a particular example, the partially transparent item may include a polymer.

In a particular embodiment, the partially transparent item may be substantially opaque to the wavelengths above the wavelengths of interest and may be substantially transparent to the wavelengths of interest. The film can also be substantially opaque to the wavelengths below the wavelengths of interest.

In accordance with yet another embodiment of the invention, a lidded optoelectronic device chip is provided which desirably includes a chip having an optoelectronic device and microelectronic circuits exposed at a surface of the chip. A lid may be mounted to overlie the optoelectronic device and the microelectronic circuits at the surface of the chip. An opaque film may be mounted to the lid to overlie the microelectronic circuits while exposing the optoelectronic device.

Desirably, an adhesive mounts the surface of the chip to an inner surface of the lid. The inner surface of the lid may be substantially planar over the dimensions of the lid, and the adhesive can mount or bond the surface of the chip directly to the inner surface of the lid. The thickness of the lid may be much greater than the thickness of the adhesive.

Desirably, the opaque film is disposed between the inner surface of the lid and the surface of the chip. The opaque film can be incorporated in the adhesive.

In a particular embodiment, the opaque film includes a metal foil. In one embodiment, the opaque film can include a metal foil disposed between a first layer of adhesive overlying the surface of the chip and a second layer of adhesive overlying the metal foil.

In accordance with one or more particular aspects of the invention, the opaque film may absorb light incident thereon. Alternatively, or in addition thereto, the opaque film can reflect light that is incident thereon.

In one preferred embodiment, an opaque film is provided which includes a metal foil disposed between a first layer of adhesive overlying the surface of the chip and a second layer of adhesive overlying the metal foil. At least some bond pads of the chip are conductively connected to the metal foil, such that the metal foil functions as a ground plane.

In one embodiment, the metal foil functions as an electromagnetic screen to prevent passage of electromagnetic radiation at frequencies of interest.

In accordance with one or more particular aspects of the invention, a lidded optoelectronic device chip may be provided which includes a chip having an optoelectronic device and microelectronic circuits exposed at a surface of the chip. A lid may be mounted to overlie the optoelectronic device and the microelectronic circuits of the chip. A light-refracting film can be mounted to the lid to overlie the microelectronic circuits while exposing the optoelectronic device.

In accordance with another aspect of the invention, a lidded optoelectronic device chip is provided which includes a chip having an optoelectronic device. Desirably, microelectronic circuits are exposed at a surface of the chip. A lid may be mounted to overlie the optoelectronic device and the microelectronic circuits of the chip. A plurality of light polarizing filters having different polarizations may be mounted to either the chip or the lid. At least two of the plurality of light polarizing filters can have different polarizations. The filters may cover the same area overlying the microelectronic circuits and may block at least some light from reaching the microelectronic circuits.

Desirably, the optoelectronic device of the lidded chip includes an image sensor. The chip may be mounted with an active surface of the chip including the optoelectronic device face up, and with a rear surface mounted to a circuit panel. A turret is desirably mounted above the optoelectronic device of the chip.

In accordance with a particular embodiment of the invention, a lidded optoelectronic device chip is provided which includes a chip having an optoelectronic device and microelectronic circuits exposed at a surface of the chip. A lid may be mounted to overlie the optoelectronic device and the microelectronic circuits at the surface of the chip. A plurality of conductors may be disposed between a first layer of adhesive overlying the surface of the chip and a second layer of adhesive overlying the metal foil. Some of the bond pads of the chip may be conductively connected to the metal foil such that the metal foil functions as a ground plane.

In a particular embodiment, the metal foil can function as an electromagnetic screen to prevent passage of electromagnetic radiation at frequencies of interest.

In accordance with another aspect of the invention, a method of fabricating lidded chips is provided which includes assembling a lid element with a wafer element containing a plurality of chips such that the lid overlies the plurality of chips. The lid element overlying individual ones of the plurality of chips can be severed into individual portions which overlie individual ones of the chips such as by sawing through the lid element along lines of severance. In addition, the wafer element underlying the lid element can be sawn through a portion of its thickness along the lines of severance. The wafer element may then be cleaved along trenches in the wafer element produced by the step of partially sawing, desirably so as to form individual lidded chips.

Desirably, the step of severing the lid element and sawing partially through the thickness of the wafer element are performed simultaneously using one saw blade. In one embodiment, the one saw blade has coarse grit. The wafer element may be sawn by the coarse grit blade to a depth less than a size of a grit of the coarse grit saw blade.

In a preferred embodiment, an adhesive can be provided between the lid element and the wafer element during the step of assembling the lid element with the wafer element.

Desirably, the step of severing the wafer element to form individual lidded chips may include cleaving the wafer element along trenches in the wafer element produced by the step of partially sawing. For example, the step of cleaving can be initiated by a saw which performs the sawing.

In accordance with another embodiment of the invention, a lidded chip can be provided which includes a microelectronic chip having a device region on a device-bearing surface and edges bounding the device-bearing surface. A lid may be attached to the microelectronic chip so as to overlie the device region. Edges of the microelectronic chip can include sawn surfaces which extend from the device-bearing surface downward. The edges may further include cleaved surfaces extending below the sawn surfaces. Desirably, the sawn surfaces include sawing marks and the cleaved surfaces are free of sawing marks.

In accordance with another aspect of the invention, a lidded chip can be provided which includes a chip having a front face and at least one device selected from a microelectronic or micro-electromechanical device exposed at the front face. A lid may be mounted to the chip over the at least one device, the lid having at least one opening exposing a portion of the front face of the chip. A passive or active circuit element or both can be mounted to the exposed portion of the front face of the chip. In addition, conductive contacts can be exposed at an exterior surface of at least one of the lid or the chip.

In such lidded chip, desirably, the contacts include bond pads. The lid may have an inner surface disposed adjacent to the front face of the chip and an outer surface remote from the inner surface. A plurality of through holes can extend between the inner and outer surfaces of the lid, and the conductive contacts can include conductive vias extending from the bond pads at least partially through the through holes.

Desirably, the conductive contacts include bond pads of the chip exposed by openings in the lid. The lid may include a plurality of recesses which extend inwardly from peripheral edges of the chip. The bond pads can be exposed within the recesses.

In accordance with one or more preferred aspects of the invention, the lidded chip may further include a plurality of wiring patterns disposed between the front surface of the chip and the lid. The wiring patterns can extend in a direction of a plane of the front surface. At least one of the wiring patterns may be conductively connected to a contact of the chip. At least one other of the wiring patterns may be conductively connected to one of the exposed conductive contacts.

Desirably, an adhesive bonds the lid to the chip. Desirably, the wiring patterns are embedded in the adhesive between the lid and the chip.

In accordance with another aspect of the invention, a lidded chip is provided which includes a chip. Desirably, the chip has a front face and at least one device selected from a microelectronic or micro-electromechanical device exposed at the front face. A lid can be mounted to the chip over the at least one device, the lid having an inner surface adjacent to the front face of the chip and an outer surface remote from the inner surface. The inner surface of the lid may include at least one cavity overlying a portion of the front face of the chip. A passive or active circuit element can be mounted to the portion of the front face of the chip underlying the cavity. In addition, conductive contacts can be exposed at an exterior surface of at least one of the lid or the chip.

In a particular form of such embodiment, the contacts can include bond pads. The lid can have an inner surface disposed adjacent to the front face of the chip and an outer surface remote from the inner surface. A plurality of through holes may extend between the inner and outer surfaces. The conductive contacts can include conductive vias which extend from the bond pads at least partially through the through holes.

Desirably in such embodiment, the conductive contacts include bond pads of the chip exposed by openings in the lid. In a particular variation of such embodiment, the lid may include a plurality of recesses extending inwardly from peripheral edges of the chip and the bond pads be exposed within the recesses of the lid.

In one variation of such embodiment, a plurality of wiring patterns can be disposed between the front surface of the chip and the lid, the wiring patterns extending in a direction of a plane of the front surface. At least one of the wiring patterns may be conductively connected to a contact of the chip. At least one other of the wiring patterns may be conductively connected to one of the exposed conductive contacts.

In addition, the lidded chip may further include an adhesive which bonds the lid to the chip. Wiring patterns may be embedded in the adhesive between the lid and the chip.

In accordance with an aspect of the invention, a lidded chip is provided which includes a chip having a front face and at least one device selected from a microelectronic or micro-electromechanical device exposed at the front face. A lid can be mounted to the chip over the at least one device. The lid may have an inner surface adjacent to the front face of the chip and an outer surface remote from the inner surface. The lid can be mounted at a height above the front face of the chip to enclose a space between the inner surface of the lid and the front face of the chip. At least one of a passive or active circuit element may be mounted within the enclosed space to a portion of the front face of the chip adjacent to the at least one device. Conductive contacts can be exposed at an exterior surface of at least one of the lid or the chip.

In a particular embodiment, the conductive contacts include bond pads and the lid may have an inner surface disposed adjacent to the front face of the chip, an outer surface remote from the inner surface, and a plurality of through holes extending between the inner and outer surfaces. The conductive contacts may include conductive vias extending from the bond pads at least partially through the through holes.

Desirably, the conductive contacts include bond pads of the chip that are exposed by openings in the lid.

Desirably, the lid includes a plurality of recesses which extend inwardly from peripheral edges of the chip. The bond pads may be exposed within the recesses.

Desirably, the lidded chip further includes a plurality of wiring patterns disposed between the front surface of the chip and the lid. The wiring patterns may extend in a direction of a plane of the front surface. At least one of the wiring patterns may be conductively connected to a contact of the chip and at least one other of the wiring patterns is conductively connected to one of the exposed conductive contacts.

Desirably, an adhesive bonds the lid to the chip. The plurality of wiring patterns may be embedded, for example, in the adhesive between the lid and the chip.

In accordance with another aspect of the invention, a lidded chip is provided which includes a chip having a front face. A device selected from a microelectronic or micro-electromechanical device may be exposed at the front face. A lid can be mounted to the chip over the at least one device, the lid having an inner surface adjacent to the front face of the chip and an outer surface remote from the inner surface. Conductive contacts may be exposed at an exterior surface of at least one of the lid or the chip. Desirably, an adhesive is disposed between the lid and the front face of the chip which bonds the lid to the front face. A plurality of wiring patterns can be embedded within the adhesive. The wiring patterns can extend, for example, in a direction of a plane of the front surface. At least one of the wiring patterns can be conductively connected to a contact of the chip and at least one other of the wiring patterns is conductively connected to one of the exposed conductive contacts.

In a particular embodiment, the conductive contacts may include bond pads. The lid can have an inner surface disposed adjacent to the front face of the chip, an outer surface remote from the inner surface. A plurality of through holes may extend between the inner and outer surfaces. The conductive contacts can include conductive vias extending from the bond pads at least partially through the through holes. Desirably, the conductive contacts are displaced in one or more lateral directions from the contacts of the chip.

At least some of the contacts of the chip can be disposed along peripheral edges of the chip and at least some of the conductive contacts may be displaced laterally inward from the contacts of the chip.

In a particular embodiment, the conductive contacts can include bond pads of the chip exposed by openings in the lid.

In another particular embodiment, the lid may include a plurality of recesses which extend inwardly from peripheral edges of the chip. The bond pads may be exposed within the recesses.

In one preferred embodiment, the conductive contacts can be displaced in one or more lateral directions from the contacts of the chip.

In accordance with another aspect of the invention, a method is provided for forming lidded chips. In such method, a lid element can be assembled with a wafer element containing a plurality of chip regions joined together along lines of severance, desirably such that the lid element overlies the plurality of chip regions. The lid element may then be severed into individual portions overlying individual ones of the chip regions by using a first blade having a first width to saw through the lid element. The wafer element can be severed along the lines of severance into individual chips using a second blade having a second width to saw through the wafer element. In one example, the first blade can be mounted to a first spindle of a sawing apparatus and the second blade can be mounted to a second spindle of the sawing apparatus that is moved in tandem with the first spindle of the sawing apparatus.

Desirably, the first blade has greater thickness and produces a wider saw cut than the second blade.

The first blade can include a coarser grit size than the second blade.

The assembling step may include providing a layer of adhesive between the lid element and the wafer element to bond the lid element to the wafer element. The step of severing the lid element may include sawing only partially through the layer of adhesive using the first blade.

In a particular embodiment, both the step of severing the lid element and the step of severing the wafer element can be performed from a direction of an outer surface of the chip towards the front face of the wafer element.

### BRIEF DESCRIPTION OF THE DRAWINGS

FIG. 1 is a sectional view illustrating a cap element.

FIG. 2A is a sectional view illustrating a stage in fabrication of capped chipped units using a cap element as shown in FIG. 1.

FIG. 2B is a plan view illustrating a plurality of chips attached together in form of a wafer.

FIGS. 3A, 3B and 3C are sectional views illustrating stages in fabrication of capped chips in accordance with an embodiment of the invention.

FIG. 3D is a top-down plan view of a chip included in a capped chip according to an embodiment of the invention.

FIGS. 3E-3F are a sectional view and a plan view illustrating a capped chip according to another embodiment of the invention.

FIGS. 3G-3H are sectional views illustrating a method of forming a capped chip according to the embodiment shown in FIGS. 3E-3F.

FIGS. 3I-3N are sectional views illustrating a method of forming capped chip according to a variation of the embodiment shown in FIGS. 3G-3H.

FIGS. 3O-3R are sectional views illustrating capped chips according to still other embodiments of the invention.

FIGS. 3S-3V are views illustrating a method of severing capped chips according to another embodiment of the invention.

FIG. 3W is a sectional view illustrating a method of severing capped chips in accordance with a variation of the embodiment illustrated in FIGS. 3S-3V.

FIGS. 3X-3Z are sectional views illustrating a method of severing capped chips in accordance with another variation of the embodiment illustrated in FIGS. 3S-V.

FIGS. 4A and 4B are a sectional view and a plan view corresponding thereto, illustrating a particular embodiment of the invention in which a redistribution wiring trace is provided.

FIGS. 4C and 4D are views illustrating a capped chip on which redistribution traces are provided on an underside of the cap, according to an embodiment of the invention.

FIG. 4E is a plan view illustrating a layout of a chip having bond pads disposed along both vertical and horizontal edges of the chip.

FIG. 4F is a plan view illustrating a layout of a chip which is advantageously packaged according to an embodiment of the invention, the chip having bond pads disposed along only vertical edges or only horizontal edges.

FIG. 5 is a sectional view illustrating a particular embodiment in which a bonding layer of a chip is formed through a cap, after mounting the cap to the chip.

FIGS. 6A-6B are sectional views illustrating a method of forming capped chips having electrical interconnects which include stud bumps.

FIGS. 7A-7B are a sectional view and a plan view, respectively, illustrating an embodiment of a capped chip having redistribution wiring traces on the cap.

FIGS. 7C-7E are sectional views illustrating embodiments of the invention in which conductive interconnects are provided in form of wire-bonds.

FIGS. 8A-11B are sectional views illustrating various methods of mounting a unit including a capped chip to a circuit panel.

FIGS. 12-17 are sectional views illustrating stages in a method of patterning and using a sacrificial coating on a cap element to provide a capped chip.

FIGS. 18-23 are sectional views illustrating stages in a method of making capped chips in which conductive features of the chips assist in self-locating the cap element.

FIGS. 24-26 are sectional views illustrating a variation of the embodiment shown in FIGS. 18-23 in which the conductive features include conductive spheres having solid cores.

FIGS. 27-32 are sectional views illustrating embodiments of capped chips in which electrical interconnects are formed which include stud bumps extending from the chip into through holes in the cap.

FIGS. 33 and 34A are plan views illustrating a plurality of chips, and a cap, respectively, from which microelectronic units are fabricated, according to an embodiment of the invention.

FIG. 34B is a sectional view of microelectronic units fabricated from the chips and the cap illustrated in FIGS. 33-34A.

FIG. 35 is a plan view illustrating a plurality of caps of a cap element from which microelectronic units are fabricated, according to one embodiment of the invention.

FIGS. 36A-B are a plan view and a sectional view, respectively, illustrating a plurality of caps of a cap element from which microelectronic units are fabricated, according to one embodiment of the invention.

FIG. 37-43 are sectional views illustrating various embodiments of microelectronic units having lidded or capped chips, and assemblies including such: units, according to various embodiments of the invention.

FIGS. 44-49B are sectional views illustrating methods of fabricating microelectronic units having lidded or capped chips, which have edge connections, and methods of mounting the units to circuit panels or other elements.

FIGS. 50-56 include sectional and elevational views illustrating various embodiments of microelectronic units having bottom unit connections and methods of making such units.

FIGS. 57-60 are sectional views illustrating stages in fabrication of microelectronic units in which an impermeable medium is used to seal the units.

FIG. 61 is a sectional view illustrating an alternative embodiment of that shown in FIG. 60, in which the impermeable medium is conductive and is patterned to form conductive traces.

FIGS. 62-66 are sectional views illustrating stages in fabrication of a metal lid for incorporation in lidded chips in accordance with an embodiment of the invention.

FIG. 67 is a perspective view and FIG. 68 is a sectional view illustrating the structure of a lidded chip having components for magnetically shielding the chip within an interior thereof.

FIG. 69 is a sectional view illustrating another embodiment of the invention in which the lid includes a transparent or light-transmissive lid.

FIGS. 70-74 are sectional views illustrating a method of forming a plurality of lidded chips in accordance with another embodiment of the invention.

FIG. 75 is a plan view illustrating an ultrasonic tool head having replaceable metal rods inserted therein for use in fabricating a lidded chip in accordance with an embodiment of the invention.

FIG. 76 is a sectional view illustrating a stage in a method of singulating individual lidded chip units in accordance with an embodiment of the invention.

FIG. 77 is a sectional view illustrating a chip-on-board type assembly in accordance with an embodiment of the invention.

FIG. 78 is a top-down plan view illustrating interconnection between a chip and a circuit panel in accordance with the embodiment of the invention illustrated in FIG. 77.

FIG. 79 is a partial sectional view of a mounting arrangement between a turret and a wiring board in accordance with the embodiment of the invention illustrated in FIG. 77.

FIG. 80 is a plan view illustrating a mounting arrangement between a turret and a wiring board in accordance with the embodiment of the invention illustrated in FIG. 77.

FIG. 81 is a plan view illustrating a mounting arrangement between a turret and a wiring board in accordance with a variation of the embodiment of the invention illustrated in FIG. 80.

FIG. 82 is a sectional view of a lidded chip in accordance with another embodiment of the invention in which the sealing structure between chip and lid has a layered structure.

FIG. 83 is a sectional view of a lidded chip in accordance with a variation of the embodiment of the invention shown in FIG. 82 in which the layers of the sealing structure are inverted relative to that shown in FIG. 82.

FIG. 84 is a sectional view of a lidded chip in accordance with another variation of the embodiment illustrated in FIG. 82 in which bond pads of the chip are exposed within recesses of the lid.

FIG. 85 is a plan view of the lidded chip corresponding to the embodiment illustrated in FIG. 84.

FIG. 86 is a sectional view illustrating a lidded chip in accordance with an embodiment of the invention which includes a thermal layer.

FIG. 87 is a sectional view illustrating a lidded chip in accordance with a variation of the embodiment of the invention shown in FIG. 86 in which bond pads are exposed within recesses of the lid.

FIG. 88 is a sectional view illustrating a lidded chip in accordance with another embodiment of the invention shown in which bond pads are exposed beyond the peripheral edges of the lid.

FIG. 89 is a corresponding plan view of a lidded chip in accordance with the embodiment of the invention illustrated in FIG. 88.

FIG. 90 is a plan view illustrating a cutout sheet for use in conducting a method of forming a vertically stacked set of packaged chips in accordance with an embodiment of the invention.

FIG. 91 is a plan view illustrating features of a packaged chip to be incorporated in a vertically stack set of packaged chips in accordance an embodiment of the invention.

FIGS. 92-94 are sectional views illustrating stages in a method of forming a set of vertically stacked packages in accordance with an embodiment of the invention.

FIG. 95 is a plan view illustrating placement of external contacts in relation to the location of device regions on the chip.

FIG. 96 is a sectional view of a lidded chip having a protective light-blocking, light-reflecting or light-refracting coating disposed on a surface of the lid.

FIG. 97A is a sectional view illustrating a variation of the lidded chip shown in FIG. 96.

FIG. 97B is a sectional view illustrating another variation of the lidded chip shown in FIG. 96.

FIG. 97C is a sectional view illustrating another variation of the lidded chip shown in FIG. 96.

FIG. 98 is a sectional view illustrating another variation of the lidded-chip shown in FIG. 96.

FIGS. 99 and 100 are a sectional view and a corresponding plan view, respectively, of a lidded chip in accordance with an embodiment of the invention in which the lid includes an opening within which a component is mounted to a face of the chip.

FIGS. 101 and 102 are a sectional view and a corresponding plan view, respectively, of a lidded chip in accordance with a variation of the embodiment of the invention shown in FIGS. 99 and 100 in which bond pads of the chip are exposed within recesses of the lid.

FIGS. 103-106 are sectional views illustrating stages in methods of manufacturing lidded chips in accordance with the embodiments illustrated in FIGS. 99 and 100 or FIGS. 101 and 102.

FIG. 107 is a sectional view illustrating a lidded chip in an embodiment according to a variation of the lidded chip illustrated in FIGS. 99 and 100.

FIG. 108 is a sectional view illustrating a lidded chip in an embodiment according to a variation of the lidded chip illustrated in FIGS. 101 and 102.

FIG. 109 is a sectional view illustrating a lidded chip having conductive traces embedded within a sealing medium in accordance with another embodiment of the invention.

FIGS. 110A and 110B are a sectional view and a corresponding plan view of a chip to be incorporated in a lidded chip package in accordance with an embodiment of the invention.

FIGS. 111A and 111B are a sectional view and a corresponding plan view, respectively of a lidded chip package in accordance with an embodiment of the invention.

FIG. 111C is a partial fragmentary sectional view illustrating the lidded chip package in accordance with the embodiment of the invention illustrated in FIGS. 111A and 111b.

FIGS. 112A and 112B are a sectional view and a corresponding plan view, respectively of a lidded chip package in accordance with an embodiment of the invention.

### DETAILED DESCRIPTION

Particular types of devices, such as SAW devices and MEMs need to be sealed hermetically in order to function appropriately over the life of the device. For many silicon semiconductor devices, a package is considered to be hermitic if it has a leak rate of helium below 1×10⁻⁸ Pa m³/sec. Other devices such as electro-optical devices do not require hermeticity, but nevertheless are best packaged under a protective lid, e.g., one that is optically transmissive, as a way of preventing particles from reaching a surface of the electro-optic device.

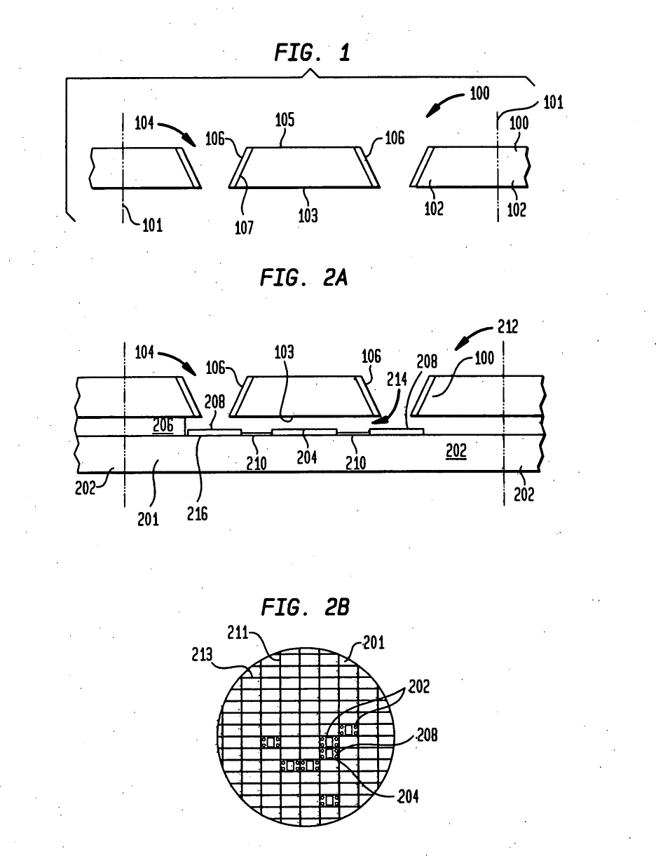

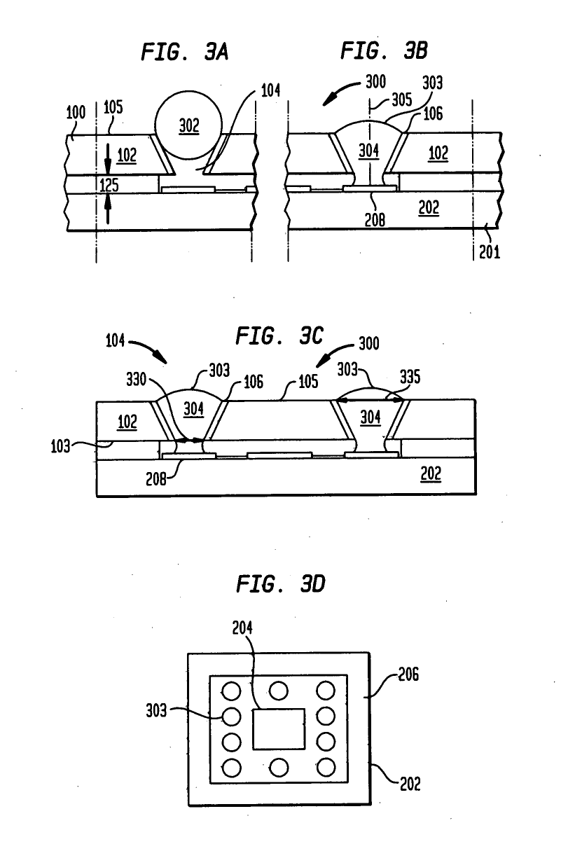

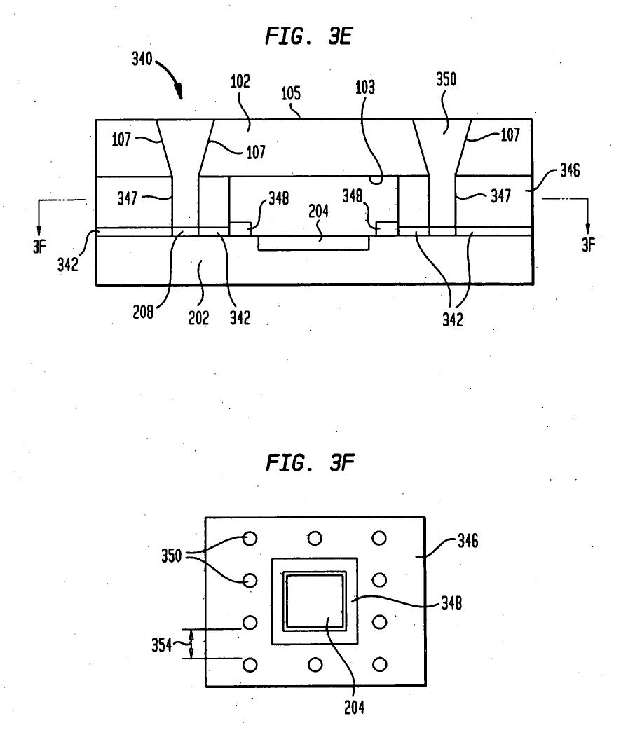

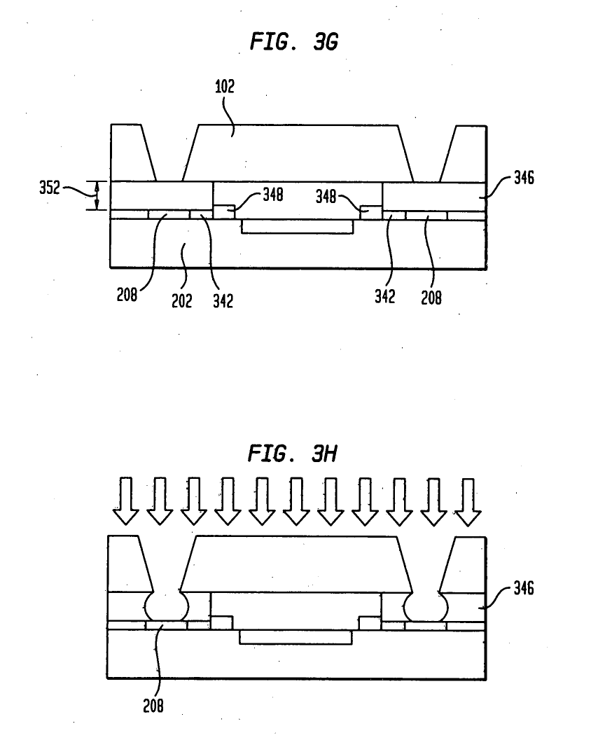

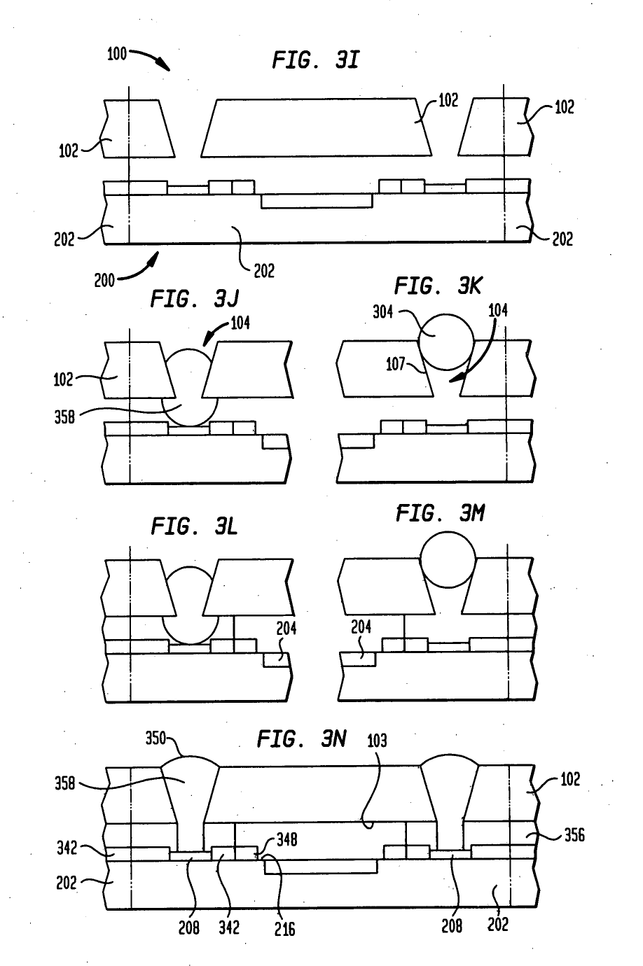

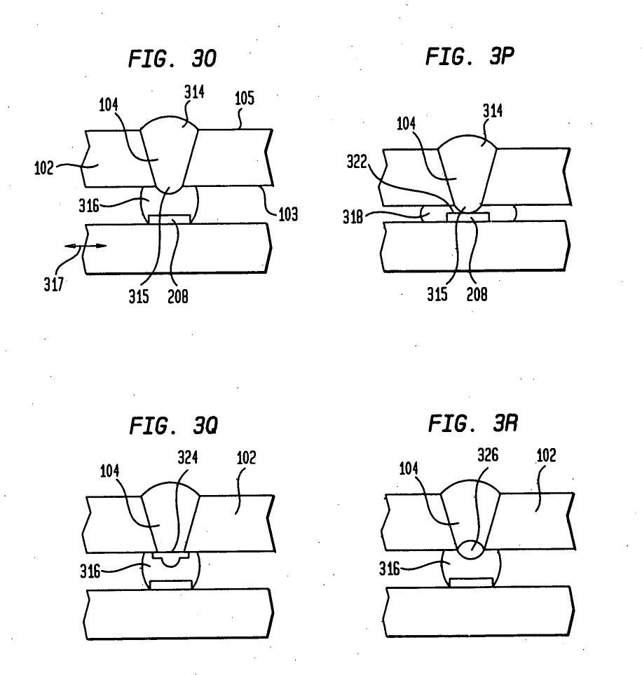

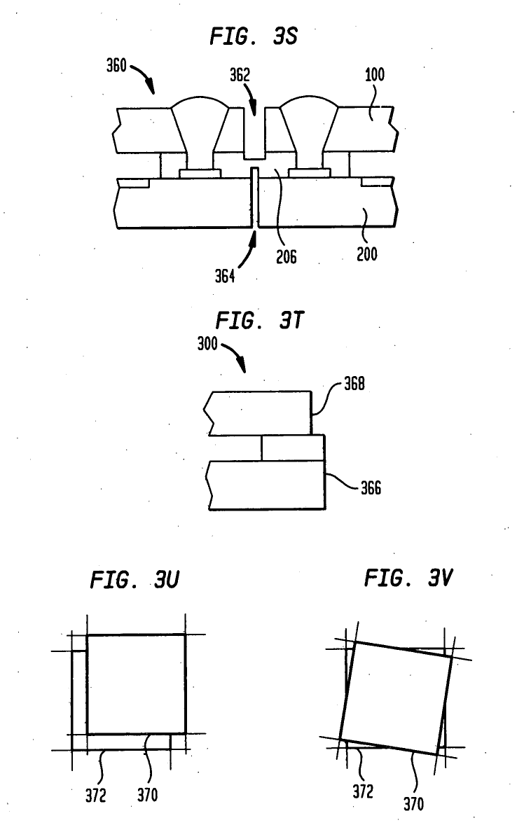

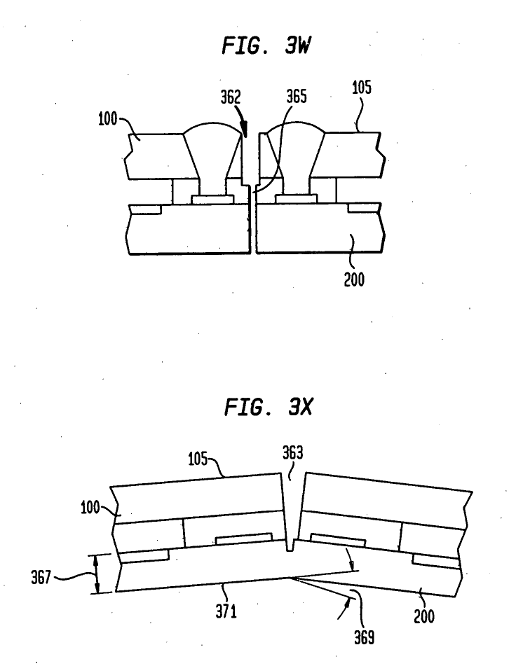

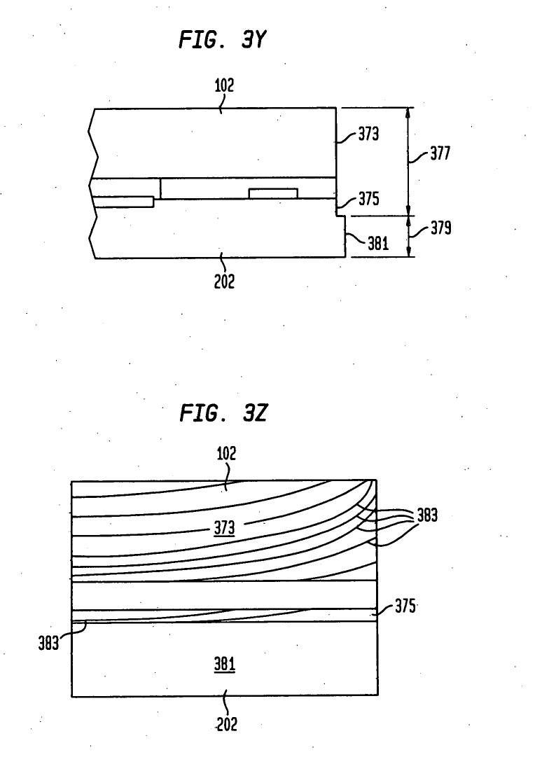

With reference to FIGS. 1-3D, in a method of forming the capped chips, a plurality of caps 102, e.g., as contained in a multiple cap-containing element 100 or wafer, are simultaneously mounted to a plurality of chips, e.g., a wafer containing the chips, and then the chips are severed to form capped chip units 300, as best seen in FIG. 3C. In such method, as shown in FIG. 1, the cap element 100 includes a plurality of caps 102, joined at boundaries 101. The cap element 100 can be either rigid or somewhat flexible, and a variety of materials are available for its construction. In one embodiment, when the area of the cap element 100 and the chips to be joined are fairly large, the cap element 100 consists essentially of one or more materials or a composition of materials which has a coefficient of thermal expansion (hereinafter “CTE”) similar to that of the chips that are to be capped. For example, the cap element 100 may include or consist of one or more materials such as ceramics, metals, glasses and semiconductor materials. When the chips are provided on a silicon wafer or other such semiconductor wafer having a relatively low CTE, the cap element 100 can consist of a CTE-matched material such as silicon or other semiconductor, nickel alloys, including those having especially low CTEs such as alloys of nickel and iron and alloys of nickel and cobalt. Other reasonably closely CTE-matched metals include molybdenum.

When the device region 208 includes a SAW device, the cap element is desirably constructed of a material having a CTE which is matched to that of the SAW device, when such SAW devices are fabricated in lithium tantalate wafers, a preferred choice for the cap element is aluminum. Aluminum has a low modulus of elasticity, such that it does not cause differential strain due to changes in temperature. In addition, aluminum can be oxidized to form aluminum oxide, which is an insulator, by processes such as “anodizing”. In such manner, insulating layers are formed on the top surface, bottom surface, and through holes with which to isolate respective ones of the subsequently formed electrical interconnects from each other.

As further shown in FIG. 1, the cap element 100 and each cap 102 thereof has a top surface 105 and a bottom surface 103. In one embodiment as shown, the top and bottom surfaces define respective planes. Through holes 104 are provided in the cap element 100, the cap element 100 generally having one or more through holes per chip. Through holes are provided by any technique suited for the particular material or materials of which the cap element is made. For example, when the cap element 100 is composed predominantly of silicon, metal, ceramics and glasses, the through holes can be provided by a subtractive process such as etching or drilling. Alternatively, when the cap element 100 includes a polymer, the through holes are more desirably provided through a molding process. In the embodiment shown in FIG. 1, the cap element 100 consists predominantly of a dielectric or semiconductor material such as a glass, ceramic or a silicon wafer. Typical etching methods applied to wafers of such materials result in through holes which are tapered as shown to grow smaller from one surface towards the other surface, such that they have a substantially frusto-conical shape. In this embodiment shown in FIG. 1, the through holes are tapered to become smaller in a direction from the top surface towards the bottom surface. In the embodiment shown in FIG. 1, bonding layers, e.g., regions 106 which are wettable, illustratively, by a fusible medium such as solder, tin, or a eutectic composition, are provided on the sidewalls 107 of the through holes 104. The tapered profile of the through holes generally assists in permitting the wettable regions to be formed on the sidewalls 107 of the through holes 104 by deposition. Suitable bonding layers will vary with the material of the cap element and the fusible material which is used to form the bond. The particular fusible medium may affect the impedance characteristics of the bond that is formed. For use with a fusible medium such as a low-melting point tin-based solder and a semiconductor, ceramic or glass cap element 100, one exemplary bonding layer includes a 0.1 μm thick layer of titanium overlying the sidewalls of the through holes 104, an additional 0.1 μm thick layer of platinum overlying the titanium layer, and a 0.1 μm thick exposed layer of gold overlying the platinum layer.

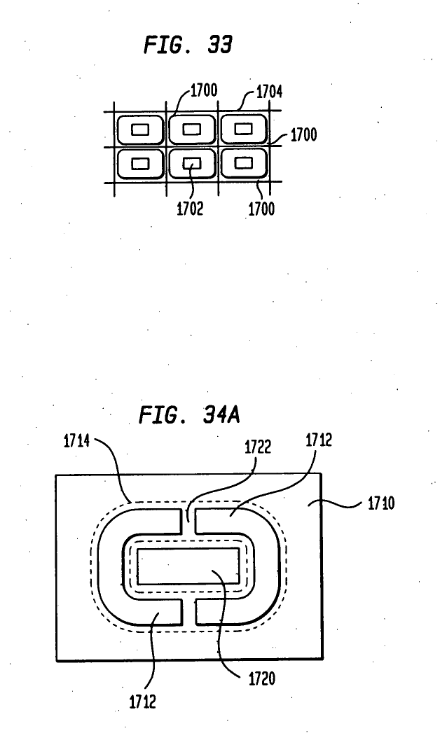

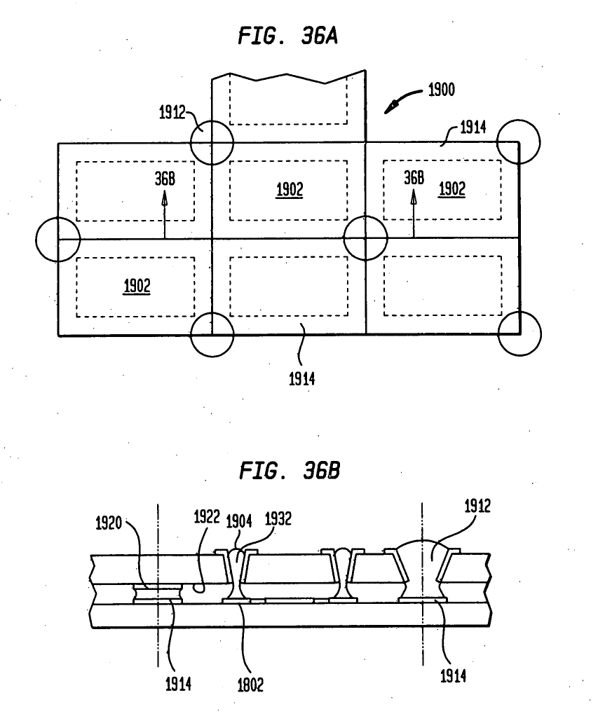

As shown in FIG. 2A, the cap element 100 is aligned to a plurality of attached chips 202, such as contained in a wafer 201 or portion of a wafer and is sealed to the water by a sealing medium 206. The sealing medium 206 includes, illustratively, an adhesive, a glass, especially those which have a low-melting point, a fusible material such as solder, or another material which forms a diffusion bond to elements, e.g., the sealing medium may be such as to form a bond to a bonding ring, as will be shown and described below with reference to FIGS. 33-36B. The sealing material preferably includes a material such as any one or more of the following: a thermoplastic, an adhesive, and a low melting point glass, which typically will bond the bottom surface 103 of the cap directly to the front surface 216 of the chip, without requiring intervening metallizations. Otherwise, bonding may be performed by solder, eutectic composition or one or more metals capable of forming a diffusion bond with a metallization provided on the front surface 216 of the chip, e.g., a sealing ring 1914 (FIG. 36B), and a corresponding metallization 1920 provided therefor on the bottom surface 1922 of the cap. When the sealing material has an attach temperature that is coincident with the solder flow temperature, the seal forms as the abutting bottom surface of the cap and the front surface of the chip are drawn together by the decreasing height of the solder.

The wafer 201 is also shown in plan view in FIG. 2B. Illustratively, the wafer is one of many available types of wafers which include at least a layer of semiconductor material, including but not limited to silicon, alloys of silicon, other group IV semiconductors, III-V semiconductors and II-VI semiconductors. Each chip 202 includes a semiconductor device region 204 provided in the semiconductor device layer, which contains, for example, one or more active or passive devices formed integrally to the semiconductor material of the chip. Examples of such device include, but are not limited to a microelectronic or micro-electromechanical device such as a SAW device, MEMS device, VCO, etc., and an electro-optic device. When such device is present, the bottom surface 103 is spaced from the front surface 216 of the chip 202 so as to define a gas-filled void or vacuum void 214 between the cap element 100 and the chip 202. The device region 204 of each chip 202 is conductively connected by wiring 210 to bond pads 208 disposed in a bond pad region at the front surface 216 of each chip. In some types of chips, the bond pads 208 include solder-wettable regions which are exposed at the front surface. In one embodiment, the device region 204 includes a SAW device, and the sealing medium is disposed in an annular or ring-like pattern in a way that surrounds the bond pads 208 and the device region 204 to hermetically seal each cap 102 to each chip 202.

FIGS. 3A-3C are further sectional views illustrating further stages in which electrically conductive interconnects 303 are formed which extend from the bond pads 208 of each chip 202 into through holes 104. As shown in FIG. 3A, a mass, e.g. a ball of a flowable conductive medium 302 is provided at the through hole 104 at the top surface 105 of the cap element 100. Illustratively, the ball 302 includes a fusible conductive material such as, solder, tin or a eutectic composition. The mass of fusible material 302 may be placed on the cap element 100 so as to rest somewhat inside the through hole 104, as shown. When the fusible material 302 is a solder ball or ball of other fusible material, the balls can be placed at or in the through holes of the cap element by placing and aligning a screen containing holes over the cap element and allowing the balls to drop through the holes of the screen into the through holes 104 until one such ball rests in each through hole in which a conductive interconnect is to be formed. Thereafter, as shown in FIG. 3B, the fusible material of the balls is caused to form bonds to the bond pads 208 of the chips 202 of the wafer. For example, when the conductive material is a fusible material such as solder, tin or eutectic composition, heat is applied to the balls directly or by heating the cap element and the chip to a point that causes the material to flow. As a result of this process, the fusible material flows onto and wets the metallizations 106, and flows onto and wets the bond pads 208 to form a bond to the bond pads 208 of the chip 202. Another result of this process is that the fusible conductive material 304 forms a unified solid electrically conductive interconnect 303 which extends from the bond pad 208 into the through hole to form a solid mass of the fusible conductive material. The thus formed conductive mass extends across the full width of the through hole to seal the through hole and to thereby separate the void 214 underlying the cap from the ambient medium which is present above the through hole.

Thereafter, the assembly formed by the cap element 100 and the wafer 201 is severed at dicing lanes defining their boundaries 101 into individual capped chips, one of which is shown in FIG. 3C.

The plan view of FIG. 3D illustrates features on the surface of the chip 202 as completed, the features including the device area 204 of the chip 202, the interconnects 303 which are joined to bond pads of the chip, and the seal 206 which is disposed as an annular or “ring” structure surrounding the bond pads and the device area 204.

Note, with respect to the above processing, that various stages of processing can optionally be performed in different facilities, as the required cleanroom level, i.e., a level specifying the maximum concentration of contaminating particles in the air and on surfaces of the facility, varies during the stages of processing. Moreover, some of the stages of processing are best performed in facilities which are oriented to performing certain steps of processing. In addition, in a preferred embodiment, testing is performed as to intermediate results of processing to eliminate product and materials from the process stream which are determined to be defective at particular stages of processing.

Thus, with respect to the processes described in the foregoing, a facility can fabricate cap elements, e.g. cap wafers having dimensions sized to fit the chip-containing wafers to be covered thereby. As an example, such cap elements are fabricated from blank wafers, which can be either new or possibly wafers recycled from previous processing. The cap elements are subjected to processing to form the through holes, which are then tested to assure conformance to standards of quality, e.g., placement, location, alignment, pitch, depth, sidewall angle, etc., and any of several other criteria for assuring quality. In either the same or in another facility, when the through holes include wettable regions, e.g., under bump metallizations (“UBM”) on the sidewalls thereof, processing is then performed to form the wettable regions. Because of the techniques used, and the increased sizes of features of the cap element, and tolerances therefor, these particular steps can be performed in facilities which need not be geared to the fabrication of semiconductor devices. However, such steps can be performed in a semiconductor fabrication facility, if such is desired. Again, at the conclusion of this processing, testing is optionally performed to assure that the wettable regions of the cap element meet quality standards.

Thereafter, the cap element and the chip-containing wafer are joined together according to processing such as described above with reference to FIG. 2A, such joining process preferably being performed in a facility having a high cleanroom level. For example, such process is desirably performed in a semiconductor fabrication facility, such as the facility in which the chip wafer is made. When the chips include optically active elements such as imaging sensors, processing to complete the conductive interconnects 303 (FIG. 3B) of each cap element can be deferred until later processing, if desired, since the primary concern is to mount the cap element as a cover over the chip wafer to avoid dust contamination. However, if the chip contains a SAW device, MEMs device or other such device requiring hermetic packaging, it is desirable to form the conductive interconnects 303 at this time as well, to form a seal which protects the SAW device during subsequent stages of processing. Again, some testing is then desirably performed to assure that quality standards are met prior to proceeding to subsequent stages of fabrication. Subsequent processing to form the electrical interconnects, if not formed already, and to provide any further sealing, if necessary, is then performed. Such processing can be performed in another facility other than the semiconductor fabrication facility, and at a cleanroom level that is not required to be as high as that of a semiconductor fabrication facility.

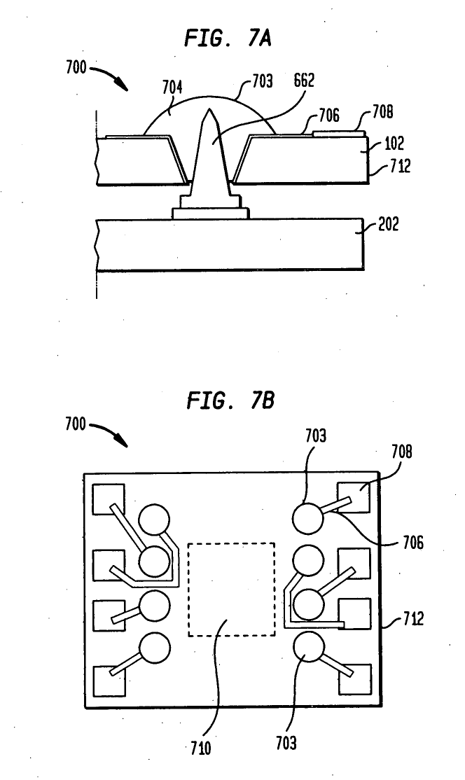

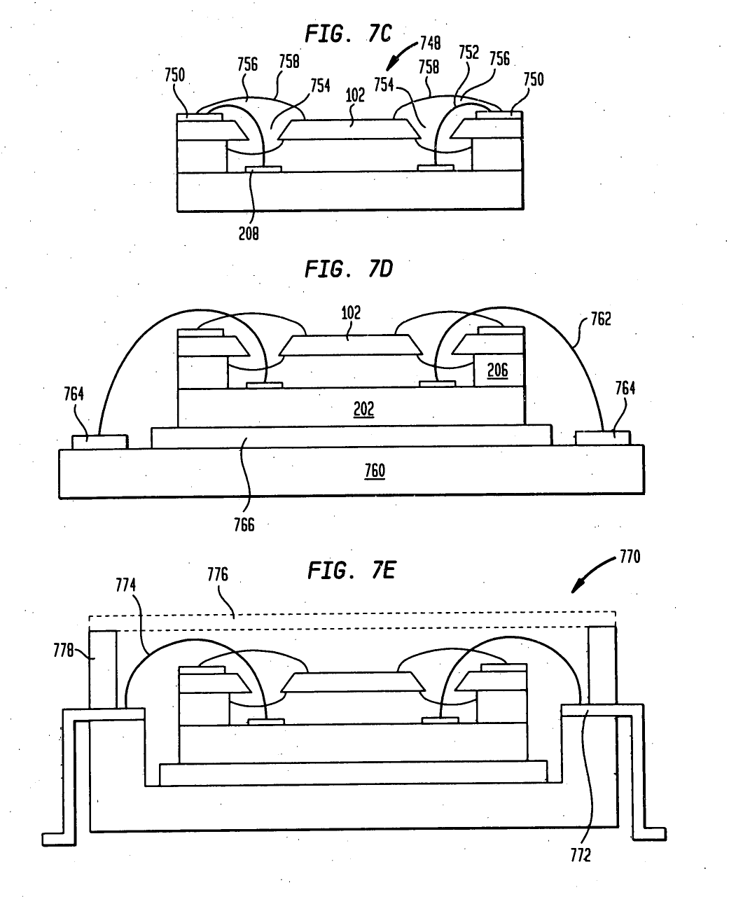

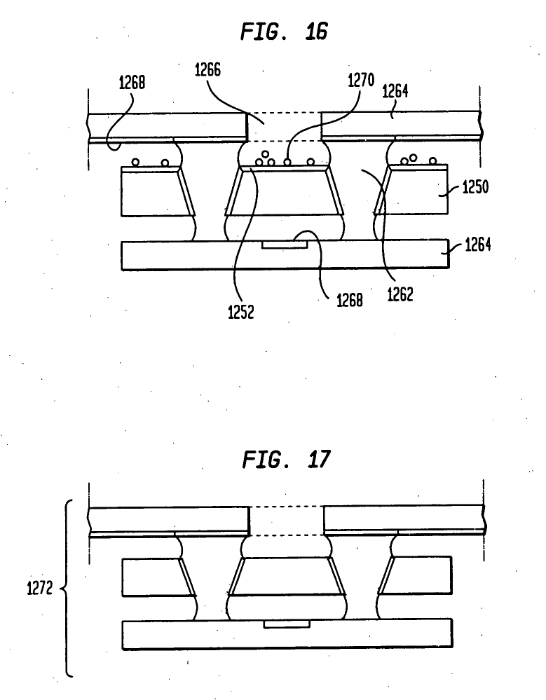

Similarly, subsequent processing to complete the packaging, as by adding other elements, e.g., optical lenses, interposer elements, thermally conductive elements and the like, and processing to mount the packaged chip to a circuit panel, such as the processes described below with reference to FIGS. 7C-11B, or FIGS. 16-17, for example, need not be performed in the same facility. Such subsequent processing can be performed in environments which do not have the same cleanroom level as that in which the cap element is mounted to the chip-containing wafer, that step preferably being performed in the semiconductor fabrication facility.

The mounting of a cap element to a chip wafer, as described in the foregoing, is especially advantageous for the packaging of certain types of chips, especially those including SAW devices, MEMs devices, and optical devices, potentially resulting in increased yields, due to the ability of such processing to be performed efficiently in cleanroom environments of semiconductor fabrication facilities, where sources of contamination are kept to a minimum. In particular, it is especially desirable to protect chips which include imaging sensors such as charge-coupled device (CCD) arrays and the like from dust or other particle contamination by attaching a cap or lid to the front surface of the chip, as early in the packaging process as possible. Such imaging sensors include an imaging device array of a chip, over which a layer including an array of bubble-shaped microlenses is formed in contact with the device array. The array of microlenses typically includes one microlens per pixel unit of the device array, the pixel unit having dimensions of a few microns on each side. In addition, such microlenses are often made of a sticky material to which dust tends to adhere after manufacture. Particles and dust, if allowed to settle directly on an imaging sensor, can obscure a portion of the pixel area of the imaging sensor, causing the image captured by the sensor to exhibit a black spot or degraded image.

However, owing to the shape of the microlenses and their number, and the sticky nature of the material used to make them, it is virtually impossible to remove dust or other particles that settle on the surface of a typical imaging sensor having such microlenses. Thus, any particles which settle on the imaging sensor at any time after the microlens array is formed, such as during the packaging process, render the imaging sensor defective, such that it must be discarded. This provides an explanation why such imaging sensor chips, when packaged according to conventional chip-on-board techniques, exhibit a yield rate in the final packaged chips, which is only 80% to 85% of the chips fabricated on each wafer.

On the other hand, particles and dust which settle on a transparent cap or cover above the outer surface of the chip do not obscure a portion of the image because the outer surface of the cap lies outside of the focal plane of the device. At worst, particles settling on the cover result in slightly decreased light intensity striking a portion of the imaging sensor. The slightly decreased light intensity rarely affects the quality of the image captured by the imaging sensor. Moreover, as described herein, the caps or covers can be mounted over the imaging sensors of the chips while the chips remain attached in wafer form, i.e., before the wafer is diced into individual chips. The mounting of the caps is preferably performed in substantially the same level of cleanroom environment as that used to fabricate the wafer, e.g., before the chip wafer leaves the semiconductor fabrication facility. In such manner, dust and particles are prevented from ever reaching the surface of imaging sensors of the chips. Moreover, once the chips are protected by such transparent caps, it becomes possible to clean the top surfaces of the covers if particles such as dust reach them. This is because the transparent caps can be made substantially planar, unlike the topography of the bubble-shaped microlenses of the imaging sensor, and are typically made of a material such as glass, which is readily cleaned by a solvent. Because the potential for direct dust contamination of the imaging sensor is virtually eliminated once the transparent cap wafer is mounted to the chip wafer, it is estimated that imaging sensor chips which are provided with transparent covers early in the packaging cycle have a yield rate of 97%-99%. In such case, the defect rate becomes no longer primarily due to contamination of the imaging sensors, but rather, for other reasons such as electrical functionality.

Desirably, wafer-level testing is performed on the chip-containing wafer 201 (FIG. 3B) prior to the cap element 100 being joined to the wafer 201 and the conductive interconnects 304 formed thereto. “Wafer-level testing” refers to such testing as is generally performed on chips, prior to the chips being severed into individual chips. More extensive testing, commonly referred to as “chip-level testing,” is typically performed only after the chip has been severed from the wafer and packaged as an individual chip.

Wafer-level testing typically tests for basic functionality, such as for electrical continuity, and basic functional operation of each chip. Such testing is desirably performed prior to individually packaging each chip, in order to eliminate the costs of packaging chips that are later determined to be defective. Thus, it is desirable to perform steps to complete the packaging of chips only with respect to chips which have passed initial wafer-level testing, i.e., “known good dies.” By completing the packaging only as to “known good dies,” unnecessary packaging operations and/or rework of packaging operations are avoided.

Wafer-level testing generally takes much less time, perhaps as much as 100 times smaller amount of time per chip tested than chip-level testing. However, the cost per chip of wafer-level testing performed by equipment capable of mechanically probing the surface of the wafer can equal or exceed that of the cost of chip-level testing, despite the greater amount of time per chip needed to perform chip-level testing. The special equipment required to precisely, mechanically probe the contacts on the wafer surface is very expensive. For that reason, such special equipment is typically also subject to resource constraints within the manufacturing facility. Moreover, fewer contacts per chips are capable of being simultaneously contacted by such equipment than is generally the case for chip-level testing, for which chips are generally placed in sockets for testing. Another factor that affects the cost of wafer-level testing is that the special equipment used to probe the contacts of the wafer is limited to testing a single chip at a time, to at most a few chips at one time.

On the other hand, chips that are processed into capped chips in wafer form or lidded chips in wafer form, as described herein, e.g., in FIGS. 1-3D, are capable of being tested at the wafer level, with test equipment that is potentially less expensive than the mechanical probing equipment described above, because interconnects of the chips are disposed on the top surface of the cap wafer and for that reason, are capable of being probed by equipment similar to that used to perform chip-level testing. For example, the top or outer surface of the cap wafer can be mechanically contacted by a contact-bearing dielectric element of test equipment, the contacts of the test equipment being held in contact with the conductive interconnects of multiple chips of the wafer, as by mechanical force. In such manner, testing is performed through voltages and/or currents applied through the interconnects 303 of each capped chip 300 to a plurality of the chips which remain attached in form of the wafer 201 (FIG. 3B). In that way, a plurality of chips of each wafer are simultaneously tested and determined to be good or defective, using equipment that can be less expensive than the above-described test equipment, because the need to mechanically probe the wafer surface directly is eliminated. In a particular embodiment, a greater subset of tests than is generally performed as “wafer-level testing” is performed to the capped chips. This is possible because the wafer containing the capped chips is able to be tested by test equipment that is less expensive than the mechanical probing equipment discussed above. In addition, the ability to test a greater number of the chips at one time permits more testing to be performed per chip for the same total amount of test time using the less expensive test equipment. In a highly preferred embodiment, the capped chips are tested in such equipment for all or nearly all of the same functions ordinarily performed during chip-level testing, prior to the chips being severed from the capped chip-containing wafer into individual capped chips.

FIGS. 3E and 3F illustrate a variation of the above-described embodiment, in which a sealing material is disposed between the chip 202 and the cap 102 in such way that it separates electrical interconnects 350 of the capped chip from adjacent electrical interconnects.

FIGS. 3E and 3F are a sectional view of such capped chip and a plan view corresponding thereto, through line 3F-3F. In this embodiment, the capped chip 340 includes a sealing material 346 which surrounds the device area 204 of the chip 202, as in the above embodiment, but also encompasses the area of the electrical interconnects 250. Preferably, the sealing material is an insulating material, for example, a nonconductive polymer, e.g., adhesive such as epoxy or other adhesive, a thermoplastic, a glass, e.g., low-melting point glass, etc., such as described above, such that the sealing material provides an isolating medium between adjacent ones of the electrical interconnects.

As further shown in FIG. 3E, optionally, a seal ring layer 342 is disposed on the front surface of the chip 202, such that the sealing material 346 adheres to the seal ring layer 342. The seal ring layer presents a surface that is wettable by the sealing material 346 such that the sealing material preferentially wets the seal ring layer and forms a bond thereto. The capped chip optionally includes a guard ring 348 which is used to prevent the sealing material from flowing beyond the wettable seal ring layer towards the device area 204 of the chip 202. The guard ring-presents a surface which is not wettable by the sealing material. Certain materials present nonwettable surfaces to other materials. For example, polytetrafluoroethylene (PTFE) presents a surface to which most other materials will not adhere or wet. In one embodiment, the guard ring 348 includes PTFE as a material at the exposed surface thereof. A similar seal ring layer and guard ring are optionally provided on the facing surface 103 of the cap.

Herein, while processes and accompanying figures are generally described in relation to individual chips and individual caps, unless otherwise noted, they shall also be understood to apply to the simultaneous processing of multiple attached chips, e.g., a wafer, and multiple attached caps of a cap element, e.g., a cap wafer.

FIGS. 3G through 3H illustrate one option for fabricating the capped chip shown in FIGS. 3E-3F. As in the above-described embodiment, this embodiment is preferably practiced as a way of simultaneously mounting a chip member including a plurality of chips to a cap member including a plurality of caps, after which the resulting joined article is severed to provide individual capped chips. As shown in FIG. 3G, the insulative sealing material 346 is placed on the surface of the chip 202 or the cap 102. The cap, having pre-formed through holes therein, is then juxtaposed and aligned to the chip such that the sealing material 346 contacts and wets respective areas of the cap 102 and the chip 202, including the seal ring layer 342, but not wetting the guard ring 348. As a result, the sealing material flows onto and is disposed on the contacts, e.g., the bond pads 208 of the chip 202.

Thereafter, as shown in FIG. 3H, a process is performed to remove unwanted sealing material 346 which is disposed on the bond pads 208. Such process is preferably tailored to the specific sealing material that is used. For example, when the sealing material is a glass, the process is preferably performed by etching, which is preferably performed anisotropically, e.g., such as by reactive ion etching, sputter etching, or other process which includes removal of material primarily in the vertical direction. However, in another embodiment, the etching process need not be highly anisotropic. The etching process may even be a generally isotropic process, if the relative thickness 352 of the sealing material being removed is comparatively smaller than the dimensions 354 (FIG. 3F) between adjacent ones of the bond pads 208. In that way, the removal of the sealing material 346 from on top of the bond pads 208 does not result in areas wide enough for adjacent electrical interconnects to contact each other. In a particular embodiment, when the sealing material is an organic material, e.g., a polymer such as an adhesive or thermoplastic, the removal is performed by a “plasma ashing” process, in which plasma etching results in the polymer being converted to an ash-like substance, leaving the surfaces of the bond pads 208 exposed. Thereafter, the electrically conductive interconnects 350 are formed by a process such as one of the above-described processes.

In a particular embodiment, interconnects 350 (FIG. 3E) are formed by plating a metal onto the exposed bond pads 208, inner walls 107 of the through holes and inner walls 347 of the sealing medium 346 to preferably fill the volume within the through holes between the bond pads 208 and the top surface 105 of the cap. In this embodiment, interconnects 350 are preferably formed by electroless plating. An electroless plating process is appropriate in this context because it does not require all features being plated to be connected to one common potential.

In order for electroless plating to succeed, an appropriate seeding layer must exist on the walls 107 of the through holes and inner walls 347 of the sealing material. To form such seeding layer, physical vapor deposition (sputtering) and/or chemical vapor deposition can be used, for example. Alternatively, an autocatalytic exchange reaction can be employed to form the seeding layer, the exchange reaction being such as occurs in a zincate or palladium strike process.

An advantage of forming the interconnects by metal plating is that it is an aqueous wet chemical process that can be conducted at a temperature that is at most about 100 degrees Celsius, and which can be performed more typically at a temperature of about 50 degrees Celsius which is only slightly elevated above room temperature. Accordingly, a capped wafer assembly structure including the device wafer and cap wafer mounted thereto are subjected only to a minor thermal excursion, such that any thermal expansion mismatch that is present during fabrication is reduced in comparison to hot solder reflow processes, especially for lead-free solders which typically melt at higher temperatures than leaded solders. Thus, when the interconnects are formed by plating, a substantially broader range of materials can be considered as candidates for various parts of the capped wafer assembly. In particular, a greater choice of materials exists for the cap wafer which now need not withstand temperatures needed to reflow solder. Thus, a greater choice of polymeric materials exists from which the cap wafers can be fabricated and a greater choice of adhesive compositions exists which can be used, for example, as a sealing material which bonds the cap wafer to the device wafer.

In a particular embodiment, the conductive interconnects 350 consist essentially of one or metals, especially noble metals which are mechanically robust and are compatible with solder, tin or eutectic compositions used for conductively bonding the interconnects of the capped unit 340 to another microelectronic element. For example, the interconnects can be formed by plated and can consist essentially of copper, nickel, silver or gold or an alloy of any one or more of copper, nickel, silver or gold. With the mechanical robustness afforded by the plated metal interconnects, a wider choice of interconnection techniques are available for bonding the interconnects of the capped chip to other microelectronic elements. In particular, techniques such as wire-bonding, lead-bonding, and techniques involving conductive adhesives, anisotropic adhesives and non-conductive adhesives, or soldering can be used to further connect the interconnects 350 to other microelectronic elements.

FIGS. 3I through 3N illustrate an alternative process for making capped chips similar to those described above with reference to FIGS. 3E through 3H. Referring to the completed capped chip as shown in FIG. 3N, this embodiment differs from the embodiment described therein, in that the sealing material 356 is a self-fluxing underfill. A self-fluxing underfill is an insulative material that is frequently used to fill a space between the front surface of a chip and a packaging element to which it is mounted in a flip-chip arrangement. Typically, a self-fluxing underfill material is an epoxy-based material, which is viscous as applied at a normal ambient temperature, or at a slightly elevated temperature, but which hardens into a solid mass upon heating. The self-fluxing aspect of the material relates to components of the composition which cause it to function as a flux when articles are soldered in its presence. Stated another way, the self-fluxing underfill material carries away reaction products, e.g., oxidation products from the soldering process that is performed in contact with it. In a particular embodiment shown in FIG. 3N, the self-fluxing underfill material is disposed in contact with a sealing ring layer 342 and is prevented from contacting the device area 204 of the chip by a guard ring. The sealing ring layer is similar to the sealing ring layer and the guard ring described above with reference to FIGS. 3E-3F. A Similar sealing ring layer (not shown) and guard ring (not shown) may also be disposed on the underside 103 (bottom side) of the cap member 100.

A process of forming capped chips using such self-fluxing material will now be described, with reference to FIGS. 3I through 3N. An initial stage in fabricating a capped chip is illustrated in FIG. 3I. In such stage, a cap member 100 including a plurality of caps 102 is aligned to and disposed overlying a chip member 200 which includes a plurality of attached chips 202. For example, the cap member 100 and the chip member 200 can be held together in a fixture. Thereafter, as shown in FIG. 3K, the through vias of the cap are loaded with a fusible conductive medium, e.g. solder, tin, eutectic composition, or diffusion bondable medium, etc. In such case, the fusible conductive medium may adhere to the walls 107 of the through holes, the walls preferably presenting surfaces which are wettable by the fusible conductive medium. Alternatively, the walls are metallized to provide surfaces wettable by the fusible medium, as described above. One method of applying the fusible medium shown in FIG. 3J is by paste screening. Another method includes application of molten solder to the cap 102 at the through hole, for example. The result of this step is to provide a solder mass held to the cap 102 at the through hole 358, such as through a bond, adhesion, surface tension, etc. FIG. 3K illustrates an alternative, in which the fusible medium is applied in form of a ball such as a solder ball 304, in a manner such as that described above with reference to FIG. 3A. Thereafter, the self-fluxing underfill material is applied between the cap member 100 and the chip member 200 to the space surrounding the device region 204 of each chip, resulting in the structure as shown in FIGS. 3L and 3M. The self-fluxing underfill material can be provided to the sealing surfaces at the periphery of each chip of the chip member and each cap of the cap member through capillary action. For example, referring again to FIG. 2B, the filling process is conducted by applying the sealing material onto the sealing surfaces of the chips and the caps that are disposed along rectilinear dicing channels, including the vertical dicing channels 211 of a chip member such as a wafer, and also along horizontal dicing channels 213.

In a particular embodiment, if the above-described capillary action is not sufficient to achieve adequate fill quality, the process can be conducted as to a smaller number of attached chips and caps, for which such filling method is adequate. For example, in an embodiment, the cap member contains a one-cap wide strip of chips and the chip member contains a one-chip wide strip of chips. The underfill is applied to the interface between peripheral edges of each chip and each cap on the strip, and the self-fluxing material is then drawn onto the wettable sealing ring layers that are disposed adjacent to the peripheral edges of each chip.

After the underfill is applied, the structure, as shown in either of FIGS. 3L and 3M is heated, such that the fusible medium, e.g., solder, flows down the walls of the through holes to wet, contact and bond with the bond pads 208 of the chips 202, as shown in FIG. 3N. During such heating step, the self-fluxing underfill 356 is displaced by the molten medium. The self-fluxing underfill then preferably also provides flux to carry away oxides which may occur due to the bonding process, such that a good conductive bond is achieved between the resulting electrical interconnects 350, as provided by the fusible medium 358, and the bond pads 208. Thereafter, as in the embodiment described above with reference to FIGS. 1-3D, the structure is severed into individual capped chips.

In a variation of the above embodiment, the self-fluxing underfill material is provided to at least one of the opposing surfaces 103, 216 of the chip member and the cap member prior to aligning and placing the cap member into a desired position relative to the chip member.

In another embodiment as shown in FIG. 3O, masses of fusible conductive material are pre-bonded to wettable surfaces of the through holes 104 of the cap 102, and the cap is then bonded by a conductive adhesive 316 provided on bond pads 208 of the chip 202, to form electrically conductive interconnects extending from the bond pads 208 through the through holes to the top surface 105 of the cap 102. Again, this process is preferably performed simultaneously as to a plurality of attached chips, such as a chip-containing wafer and a plurality of caps, such as a cap wafer, and the joined structures then severed to form individual capped chips. This process permits the cap wafer and the chip-containing wafer to be joined at room temperature or at most, a minimally elevated temperature, i.e., without requiring heating to a temperature sufficient to cause the flowing of a fusible material such as solder. Such process is advantageous, in order to avoid problems of differential expansion between the chip-containing wafer and the cap wafer, e.g., when the two wafers are not CTE matched.

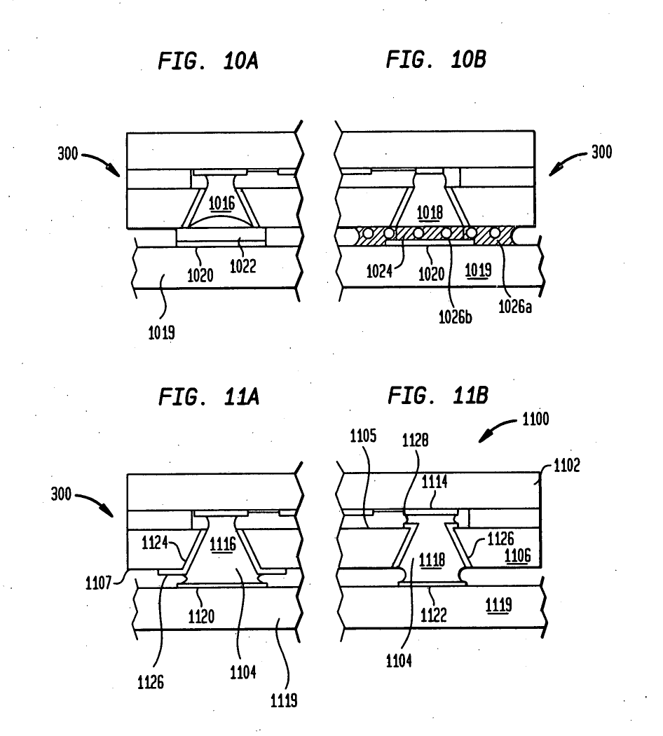

The masses of fusible material are provided, for example, by screen printing a controlled amount of solder into each through hole of the cap wafer. Alternatively, the masses of fusible material can be provided by contacting a cap wafer having tapered through holes wettable by solder with a bath of solder, such that the solder is drawn onto the wettable surfaces of the through holes, to fill the through holes with the solder. The through holes are preferably tapered, either in the manner shown, i.e., growing smaller from the top surface 105 towards the bottom surface 103, or alternatively, growing smaller from the bottom surface towards the top surface. In another alternative, the through holes are tapered from both the top and bottom sides, growing smaller towards a middle of the thickness of the through holes 104. The application of the solder results in the mass 314 of solder having a protrusion 315 extending beyond the bottom surface 103 of the cap. The protrusion 315 can be a natural consequence of applying the solder in liquid, e.g., as a solder paste, or in a molten state. In either case, due to surface tension, a sessile drop forms which causes the protrusion 315 to appear. The protrusion 315 provides a surface which displaces some amount of the conductive adhesive upon bringing the cap together with the chip, such that the solder mass 314 fully contacts the conductive adhesive 316. The conductive adhesive is preferably an anisotropically conductive adhesive, which conducts in a vertical direction by way of conductive elements in the adhesive that are pressed into contact with the solder mass 314 and the bond pad 208. As also described and shown below with reference to FIG. 10B, an anisotropically conductive adhesive does not conduct in a lateral direction 317 due to lateral spacing between the conductive elements of the adhesive.

In a variation of this embodiment, as shown in FIG. 3P, a viscous, nonconductive adhesive 318 is applied to the vicinity of the bond pad used. In this case, the protrusion 315 of the pre-formed solder mass 314 displaces the nonconductive adhesive so as to contact the upper surface of the bond pad. The nonconductive adhesive functions to maintain the solder mass 314 in contact with the bond pad 208. Application of a slightly elevated temperature may be performed to cure and/or shrink the nonconductive adhesive 318, so as to better maintain the contact between the protrusion 315 and the bond pad 208.

FIGS. 3Q an 3R illustrate further variations of this embodiment, in which additional protruding features are added to the cap wafer in each case, in registration with the through holes 104, such protruding features provided to assure the quality of contact between the pre-formed conductive interconnect structures provided in the cap wafer 102 and the bond pads of the chips 102. Specifically, in FIG. 3Q, the protruding feature includes a stud bump 324 which is applied to the cap wafer 102 at the location of the through hole 104. In a particular embodiment, the solder mass 314 is planarized, e.g., by polishing, after which the stud bump 324 is applied to make the structure shown. Embodiments including stud bumps are described in greater detail below throughout the present application. In FIG. 3R, the solder mass 314 does not completely fill the through hole. In such case, the protruding feature 326, e.g., a stud bump fills the remaining space within the through hole to project beyond the bottom surface 103 of the cap 102. Although FIGS. 3Q and 3R illustrate structures in which a conductive adhesive is used, i.e., a preferably anisotropic conductive adhesive, a nonconductive adhesive can be used instead, in the manner as described with reference to FIG. 3P.

FIGS. 3S through 3V illustrate a particular embodiment of a method by which a structure 360 including capped chips, in wafer form, are severed into individual capped chips.

As noted above, a cap wafer and a chip-containing wafer need not consist of the same or similar materials. For example, a chip-containing wafer consisting essentially of silicon may be joined to a cap wafer which consists essentially of glass. In such case, a difficulty arises in the manner in which the structure including the cap wafer, as joined to the chip-containing wafer, can be severed into individual capped chips. Conventionally, a silicon wafer can be cut by sawing using a 25 μm wide blade, which saws through the thickness of the wafer at a rate of 70 mm per minute. On the other hand, a glass wafer, having an exemplary thickness of 325 μm, must be cut using a blade having a thickness of 75 μm, which also cuts at a comparable rate. The blade optimized for cutting a silicon wafer will cause chipping if used on the glass wafer. Conversely, a blade optimized for cutting a glass wafer produces unsatisfactory results when used to cut a silicon wafer.

In order to cut through a structure including both the silicon wafer and the glass wafer, a poor compromise is presented. A sawing process capable of cutting both silicon wafer and glass wafer together operates at a rate of only 5 mm per minute, which is unacceptable, given the thickness of the combined structure, which is in the hundreds of microns. In addition, typically, dozens of cuts are required to sever all chips of such wafers into individual units.

FIG. 3S illustrates an improved method of severing the structure 360 into individual units according to an embodiment of the invention. In this embodiment, a sealing material 206 is disposed between the chip-containing wafer and the cap wafer, the sealing material 206 being such as that described above with reference to FIG. 2A or in other above-described embodiments. The cap wafer 100 and the chip-containing wafer 200 are spaced from each other by a distance. In one embodiment, the distance is controlled, for example, by features of the cap wafer or the chip wafer which protrude beyond the opposing surfaces 216, 103 of the cap wafer or the chip wafer, respectively, as described in greater detail below with reference to FIG. 23. Alternatively, the sealing material can include spacing elements, e.g., spheres, for maintaining a minimum distance between the chip and the cap wafer.

The structure 360 is sawed, first by a saw optimized for cutting one of the wafers, and thereafter by a saw which is optimized for cutting the other one of the wafers. For example, a saw having a thick blade is used to produce the wide cut 362 first, cutting through the glass cap wafer 100, as shown in FIG. 3S. Such cut 362 may touch the sealing material 206, but does not cut through the sealing material. This sawing operation is preferably then repeated to make all of the cuts through the glass across throughout the cap wafer. As stated above, this sawing operation, being optimized to the glass, proceeds quickly for that reason. Thereafter, a saw having a relatively narrow blade is applied to make the narrower cut 364, as shown in FIG. 3S. In this case, the blade and the sawing operation are optimized to cutting the silicon wafer. Preferably, this cut is performed to cut all of the way through the silicon wafer and through the remaining sealing material. In such case, given the greater width of the cut 362 in the glass wafer 100, the narrower cut 364 meets the wide cut 362 to complete the severing of the chip. Beneficial results are provided, in that the rate of sawing through each wafer separately is at about one order of magnitude or more greater than the rate of sawing through a combined structure 360 using a single saw. Thus, the rate of severing the chips is at least several times faster, for example, about 5 to 10 times faster, when the method according to this embodiment is utilized, as compared to using one blade capable of cutting through both wafers.

FIG. 3T illustrates an individual capped chip 300, diced using this embodiment of the invention. As shown therein, the edges of the chip 366 and the cap 368 of the capped chip unit 300, are not perfectly aligned. This is a consequence of the two separate sawing operations that are performed. Perfect alignment and orientation of the separately performed sawing operations is difficult, if not impossible, to achieve. FIGS. 3U and 3v are plan views illustrating the capped chips, after sawing them into individual units. Some displacement in one or more axes of the dicing lines 370, 372 produced by the two sawing operations is likely to occur, as shown in FIG. 3U. Angular displacement of none sawing operation relative to another sawing operation, may also cause angular displacement of the dicing lines 370, 372, as shown in FIG. 3V.

Referring to FIG. 3W, in a variation of the embodiment shown in FIGS. 3S and 3T, the wide saw cut 362 through the cap wafer, 100 (e.g., a glass cap wafer) and the narrower saw cut 365 through the device (e.g., silicon) wafer 200 are both performed in a downward direction from the top surface 105 of the cap wafer 100. By making both cuts from the top surface of the cap wafer downward, the two cuts can be made with a saw positioned above the device wafer/cap wafer assembly without having to turn the assembly over and realign the sawing tool with the assembly. In addition, the two cuts may even be performed simultaneously at different locations along the direction of the saw cut 362 by providing radially aligned wide and narrow saw blades on different rotating axles of the same sawing tool. When the two sawing blades are moved in a direction parallel to the direction of the saw cut, the wide cut is made to the cap wafer and then the narrow cut is made to the device wafer where the wide cut has already been made. The resulting structure appears as shown and described above with respect to FIGS. 3T through 3V.

In another variation as illustrated in FIGS. 3X, 3Y and 3Z, sawing is used to cut through the cap wafer (e.g., glass wafer) but only partially through the thickness of the device wafer. In this singulation method, the device wafer is severed not by sawing but instead by cleaving. FIG. 3x illustrates the cut 363 made in a downward direction from the top surface 105 through the cap wafer and partially through the thickness 367 of the device wafer 200. Preferably, the partial saw cut in the device wafer is made by one wide blade that is also used to saw through the thickness of the cap wafer. Alternatively, a wide cut can be made in the cap wafer using a wide blade followed by a narrower cut in the device wafer using a different, narrower blade. After making these saw cuts, the device wafer 200 is bent in an outward direction 369 from its bottom surface 371 to cleave the device wafer in a direction aligned with the previously made saw cut 363.

FIG. 3Y is a partial sectional view of a chip or other portion of the wafer after singulation by this method. A rising edge 373 of a cap element exposed by the sawing process is shown therein. As a result of cutting through the cap wafer and cutting through a portion of the device wafer in a single operation using a single blade, the edge is planar or at least substantially planar with a top edge portion 375 of an exposed edge of a wafer element or chip 202. These at least substantially planar edge features coincide with the depth 377 of the saw cut. Below the top edge portion 375 of the chip a lower edge portion 381 exists, which need not be substantially planar with the top edge portion. As the lower edge portion is cleaved rather than sawn, its characteristics are determined by the cleaving process rather than primarily by the sawing process.

FIG. 3Z is an elevational view of the chip 202 and cap element 102 assembled thereto, taken in a direction 3Z looking toward the surface of the edge 373 of the cap and looking toward the top and lower edge portions 375, 381 of the chip 202. As illustrated in FIG. 3Z, sawing marks 383 appear at the exposed surface of the edge 373, and sawing marks 383 also appear at the exposed surface of the top edge portion 375 of the chip. However, sawing marks do not appear at the exposed surface of the lower edge portion 381 because the lower edge portion of the chip was cleaved rather than sawn from the wafer.

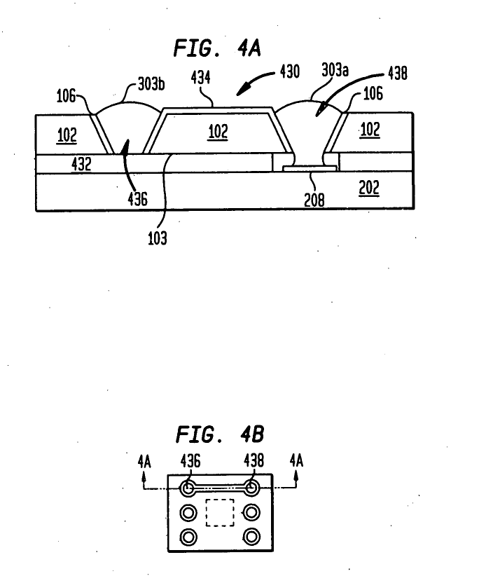

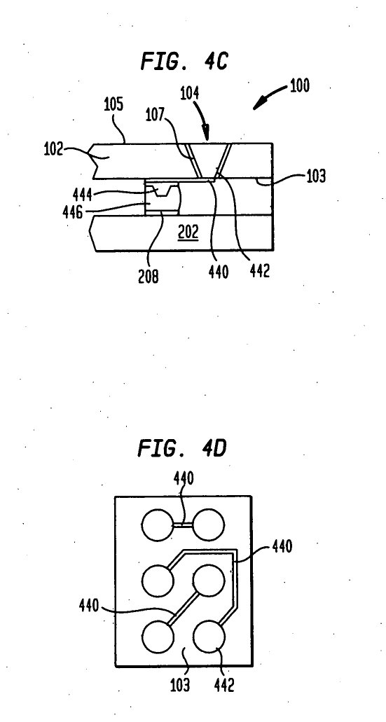

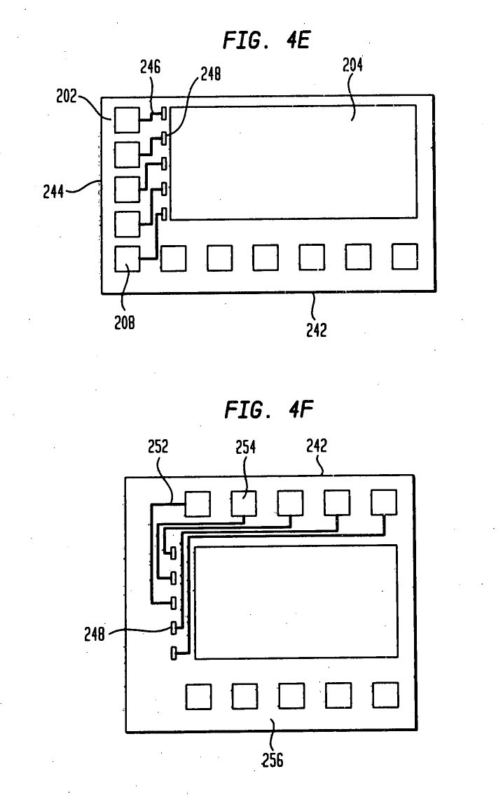

FIGS. 4A and 4B are a sectional view and a top-down view, respectively, illustrating a particular embodiment of a capped chip 430 in which the electrical interconnects 303 are conductively connected by a trace 434 formed on the top surface of the cap 102, such as for the purpose of redistributing an electrical connection. In such embodiment, the trace 434 extends from a bonding layer 106 provided on the sidewall through a through hole at one electrical interconnect 303a to a bonding layer 106 provided at another electrical interconnect 303a. The trace 434 can be formed at a separate time as the bonding layer 106 or simultaneously with the bonding layer 106. As shown in FIG. 4A, a sealing medium 432 is provided between the cap and the chip 202 in an area underlying the through hole 436. When a fusible conductive material is placed in through hole 436, as well as through hole 438 and heated, the material forms a solid bonded connection to the bonding layer 107 and forms an electrically conductive connection between the bond pad 208 and the electrical interconnect 303b. Note that during such process, the fusible material does not flow from the through hole 436 onto the chip because of the seal medium 432 which blocks the material from flowing lower than the bottom surface of the cap 102. Alternatively, if the arrangement permits two bond pads of the chip to be at the same potential, e.g., such as for the distribution of power or ground connections, the chip may include a bond pad underlying the through hole 436, and the sealing medium 432 not be disposed under through hole 436, such that the electrical interconnect 303b is also bonded to that bond pad.

FIGS. 4C-4D are a sectional view, and a plan view, respectively, illustrating a variation of the capped chip structure 100 discussed above with reference to FIGS. 4A-4B. With reference to both figures, in this structure, a redistribution trace 440, which may function as a “fan-out” trace, is provided on the side 103 of the cap 102 which faces the chip 202, that is, the underside of the cap, also referred to herein as the “bottom side” of the cap. The redistribution traces can function as a “fan-out” trace for the purpose of providing contacts on the cap which are disposed farther apart and at more convenient locations for higher level packaging than the locations of the bond pads of the chip. Such arrangement permits the size of the chip to be made smaller, which allows more cost-effective chip processing, because more chips are fabricated at a time on a single wafer. The cap 102 is provided of a material such as that described above, and is preferably mounted to the chip as a plurality of attached caps in wafer form to a plurality of attached chips of a chip-containing wafer, after which the joined structure is severed into individual units.

With specific reference to FIG. 4C, the redistribution traces 440 extend along the underside 103 of the cap from the locations of interconnecting masses 442 of conductive material which extends from the bottom side 103 to the top side 105 of the cap 102 by way of through holes 104. The conductive material forming the masses 442 is a flowable conductive material such as a conductively loaded polymer, one or more metals or a fusible conductive medium. Most preferably, the masses 442 are formed of a fusible conductive medium such as solder, tin or eutectic composition, and are formed in contact with a bonding layer 107 disposed on walls of the through holes. At the other end of the conductive traces, protrusions 444, such as stud bumps, are preferably provided. The protrusions 44 provide surfaces to which a bonding medium such as a conductive adhesive 446 adheres to form an electrically conductive path from the bond pads 208 of the chip 202 to the traces 440. Preferably, the adhesive is an anisotropic conductive adhesive, such as that described above with reference to FIGS. 3O-3R. Alternatively, a nonconductive adhesive can be used in place of the conductive adhesive 446, in a manner such as that described above with reference to FIG. 3P. Alternatively, a fusible conductive medium such as solder is used in place of the conductive adhesive. In such case, a mass of fusible material such as solder is preferably applied as a bump to the protrusion 444 or the corresponding location of the trace 440, if the protrusion is not present, before the cap wafer is bonded to the chip wafer. The cap wafer and the chip wafer are then heated to cause the solder to reflow, thus forming a solder mass bonding the two wafers in the place where the conductive adhesive 446 is shown.

In one embodiment, the cap wafer is formed by patterning a layer of metal on the cap wafer to form the redistribution traces 440, after which the through holes are formed by an etching process or other removal process which is endpointed upon reaching the redistribution traces 440. Bonding layers 107 are then formed on walls of the through holes, as needed, and the through holes are then are then filled with the conductive material, that material preferably being a fusible conductive material such as solder.

FIG. 4E is a plan view illustrating an example of a chip 202 which would benefit upon redesign, through use of the redistribution scheme illustrated in FIGS. 4C-4D. As shown in FIG. 4E, the chip 202 is rectangular, such that the chip has a long edge 242, and a short edge 244. The rectangular shape is used because of the rectangular shape of a device area 204 of the chip, which may be, or may not be required to be rectangular. For example, a charge-coupled device (CCD) array is required to be rectangular for capturing images. In such chip 202, interconnection wiring 246 carries signals from points 248 connected to the device area 204 to bond pads 208 of the chip 202. However, the rectangular shape of the chip is not optimum, because a greater number of chips having the same amount of area could be fabricated on a single wafer, and thus, be fabricated more cost-effectively, if the chips had square shape. Moreover, it is more difficult to form interconnections to a package including the chip by way of wire-bonding when the contacts of the package are provided at positions which may vary in two degrees of freedom. For example, as shown in FIG. 4E, the positions of the bond pads 208 of the chip vary vertically along the short edge 244 of the chip 202. Other positions of the bond pads vary horizontally along the long edge 242. These positions of the bond pads 208 of the chip are reflected in corresponding positions of the contacts of a package (not shown), e.g., a capped chip which includes the chip, which are also disposed at different vertical positions along a short edge of the package, and at different horizontal positions along a long edge of the package.

Faster, more effective, and/or higher quality wire bonding can be achieved if the contacts of the package, and thus, the bond pads 208 of the chip are disposed in lines which extend in either horizontal or vertical directions, but not both. In such way, when the wire-bonder forms a bond wire to each location, it is only required to move between respective horizontal locations along each line.

Accordingly, as illustrated in FIG. 4F, in an embodiment of the invention, wiring 252 extends from the connection points 248 to bond pads 254 which are disposed at different horizontal locations along one of the horizontal (long) edges 242 of the chip 256.

The above-described embodiment, showing caps having redistribution traces disposed on the underside of the caps, is desirably employed with chips having a design such as that shown in FIG. 4F, the caps providing any redistribution of signal way that is made necessary by the different layout of the bond pads on the chip.

The flowing on and bonding of a fusible conductive material such as solder in the manner discussed in the foregoing with reference to FIGS. 1-3N and 4A-4B applies to chips which have bond pads that include exposed regions which are wettable by solder or other fusible material. In some types of chips, particularly those having aluminum bond pads, and some types of SAW device chips, the bond pads are not wettable by solder or other such fusible material, in the form that the chips are available when packaged. Aluminum bond pads oxidize under ordinary atmospheric conditions to form a surface layer of alumina which is generally not wettable by a molten mass of solder. On the other hand, some types of wafers, especially III-V compound semiconductor wafers, include bond pads which are formed of or include an outer layer of gold. Here, a different problem exists in that the gold of the bond pad is subject to being dissolved by solder and other fusible materials, which potentially destroys the bond pad to cause an open circuit between the bond pad and the connecting trace.

One way that these concerns is addressed is to specifically form a bonding layer on the bond pads 208 of the wafer prior to joining the cap element to the wafer, the bonding layer being wettable by solder (or other fusible material to be used). Such bonding layer can be formed by a process such as that used for forming an “under bump metallization” (“UBM”) on a chip. However, some types of chips, particularly SAW devices, are very sensitive to contamination and can be degraded by processing used to form bonding layers.

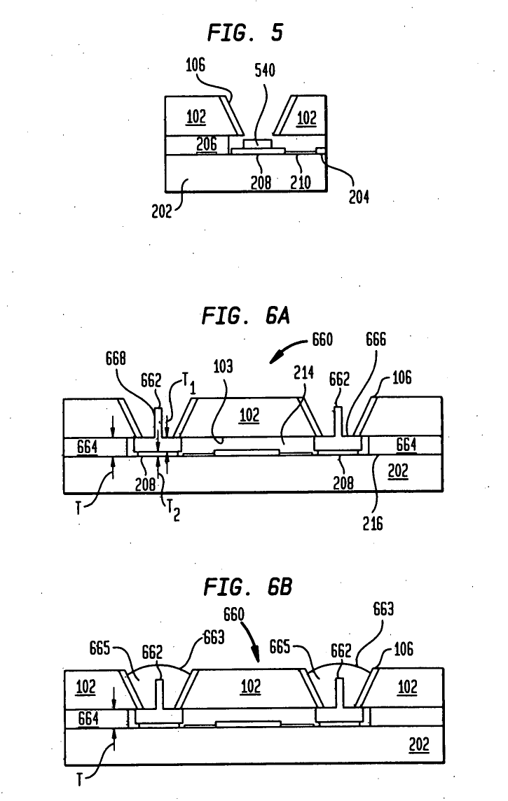

Accordingly, in an embodiment of the invention illustrated in FIG. 5A, such concern is addressed by forming bonding layers on bond pads of a chip or wafer after the cap element has been joined to the wafer. As shown in FIG. 5A, in such embodiment, the joined assembly of the wafer containing the chip 202 and the cap 102 is placed in a chamber in which it is subjected to deposition of one or more materials to form a bonding layer 540, e.g., a UBM on the surface of the bond pad 208. A mask, e.g., a contact mask, may also be positioned over the cap 202 such that only the through holes 104 are exposed during the deposition. Otherwise, the deposited material can be removed from the top surface of the cap 202 after the chip has been joined to the cap and the electrical interconnects 303 have been formed. During such deposition, the cap 202 also functions as a shadow mask to prevent the deposition of the UBM on the device region 204 of the chip 202.

As a result of the deposition, a bonding layer 106 may also be simultaneously formed on the sidewalls 107 of the through holes 104. During such process, dielectric oxide present on the surface of the bond pad 208 is removed.

A limiting factor of the embodiments described above with respect to FIGS. 1-3D is that it requires the solder ball 302 (FIG. 3A) to melt during the reflow process in such way that the meniscus (not shown) of the molten solder ball hangs low enough to touch the UBM coated bond pad 208, and thereby establish a solder bond with the bond pad 208. Whether or not the solder bond is established depends on several factors, including the volume of the molten solder ball, the size of the opening of the through hole 104 which faces the chip, and the height 125 of the spacing between the chip 102 and the cap 101, requiring tolerances on the process to be relatively tight. In addition, such process allows little freedom to choose the height 125 of the spacing between the cap 102 and the chip 202. Desirably, such height is determined by the functionality sought to be obtained by placing the cap over the device area of the chip, such as when the device area includes a SAW device or MEMS device which requires a cavity.

The embodiment, shown in FIGS. 6A-6B addresses this concern. In this embodiment, conductive stud bumps 662 are applied to the bond pads 208 of the chip, which is best performed while the chip is in wafer form. Thereafter, the cap element is aligned to the wafer and sealed thereto. During the alignment step, the stud bumps, particularly if they contain relatively thick shafts, can assist in the process of properly aligning the cap element to the wafer, as the stud bumps 662, when aligned, stick up at least partially through the through holes 106. Stud bumps containing certain metals may be applied directly to bond pads without first applying a bonding layer such as a UBM, thus providing a further alternative way of forming conductive interconnects to bond pads which are not directly wettable by solder. For example stud bumps consisting essentially of one or more of copper, nickel, silver, platinum and gold can be applied this way. When wettable bonding layers are provided on bond pads, stud bumps of solder or other fusible conductive materials can be used.

A process such as that described above relative to FIGS. 3A-3B is then used to form electrical interconnects 663 which include stud bumps and the fusible material so as to extend from the bond pads 208 through the through holes 665. As in the embodiments described above, a sealing medium 664 is provided between the chip 202 and the cap 102. One problem with some sealing media is that it is difficult to control the thickness T of the sealing medium, and thus the thickness of the void 214 between the chip and the cap, simply by controlling the amount of the sealing medium or the amount of pressure applied to locations of the chip after the sealing medium is applied.

This concern is addressed in the embodiment shown in FIG. 6A, in which each conductive stud bump 662 has a shoulder 666, on which the bottom surface 103 of the cap 102 rests, so as to space the bottom surface 103 a distance T from the front surface 216 of the chip. As apparent from FIG. 6A, that distance T includes any thickness T2 of the bond pad 208 which extends above the front surface 216 of the chip, as well as the thickness of the lower ‘ball’ portion of the stud bump from the bond pad 208 to the shoulder 666.

FIG. 7C illustrates a capped chip 748 according to another embodiment of the invention, in which conductive interconnects are provided which include bonding wires 752 which extend from bond pads 208 of the chip 202 through openings 754 in the cap 102 to contacts 750 disposed on the top surface 105 of the cap. The openings 754 can be such as the through holes 104 described above with respect to FIGS. 1-3D, for example, which are sized to accommodate one interconnect per through hole, and to permit the bonding of bonding wires 752 to respective bond pads of the chip. Alternatively, the openings 754 can be bonding windows which are sized and shaped, e.g., extending primarily in one linear direction along the cap, so as to overlie a linearly extending row of bond pads 208 of the chip, and permitting the formation of wire-bonds to each of the bond pads 208 of that row through the opening. While the peripheral edges of the capped chip 748 are sealed by a sealing material 206, in a manner such as that described above with reference to FIGS. 1-3D, an additional sealing material 756 is deposited in contact with the openings 754 of the cap to seal the openings after the bonding wires have been formed. Such sealing material can include, for example, a polymer which hardens to form a nonconductive region for insulating respective bonding wires from each other, while also mechanically supporting the bonding wires. In a particular embodiment, the sealing material 756 is an encapsulant which is disposed as an insulating medium over the top surface 105 of the cap generally, except for the area in which the contacts 750 are located. Alternatively, another insulator such as a glass, e.g., preferably a low-melting point glass, is disposed in each through hole to insulate and support the bonding wire. In a particular embodiment, in which the wire bonds extend through individual through holes 104 which are aligned to the bond pads, a mass of a flowable conductive material such as a conductively loaded polymer or a fusible conductive material is disposed in each opening 754 to seal the opening in place of a polymer. In such manner, enlarged conductive interconnects 758 are formed at the top surface 105 of the cap 102, the interconnects 758 extending across each opening to seal each opening including the area of the contacts 750. In such case, higher level assemblies can be made by forming appropriate electrically conductive bonds to the thus formed interconnects 758.

FIG. 7D illustrates a variation of the embodiment described in FIG. 7C in which bonding wires 762 that are joined to the bond pads 208 of the chip are not bonded to contacts on the cap. Instead, the chip is bonded by bonding wires in a face-up orientation to contacts 764 of a packaging element 760, e.g., any of many types of dielectric elements and substrates which have conductive traces thereon. Advances in the capability of wire bonding machines now permit bonding wires to be formed which have relatively complex profiles, and to be formed reliably and repetitively. Thus, FIG. 7D illustrates an example in which the bonding wire 762 is formed to extend directly between a bond pad of the chip and a secondary packaging element, e.g., a dielectric panel, or circuit board, which is farther away from the bond pad 208 than that shown and described above in FIG. 7C. In this embodiment, the cap 102 is preferably an at least partially optically transmissive element, that term denoting an element which is either somewhat translucent or transparent to light in a range of wavelengths of interest. More preferably, the cap 102 is transparent, consisting essentially of a material such as a glass or a polymer, which can be molded. In a particular embodiment, the cap 102 is molded to contain an optical element, e.g., a lens, such as the caps and optical elements described in commonly assigned, co-pending U.S. patent application Ser. No. 10/928,839, filed Aug. 27, 2004, of which this application is a continuation-in-part.

In this embodiment, the formation of the bonding wires to bond the chip to the packaging element 760 is done after the cap 102 is affixed to the chip 202 by the sealing material 206, and the chip is mounted to the packaging element, such as by an adhesive 766, e.g., an adhesive commonly known as a “die attach” adhesive. Alternatively, a thermal conductor can be mounted between the chip 202 and the cap 102 for conducting heat away from the chip and onto a thermal conductor mount provided in the packaging element, such as described in commonly assigned, co-pending U.S. patent application Ser. No. 10/783,314 filed Feb. 20, 2004, the contents of which are hereby incorporated by reference herein. In a particular embodiment, the chip is bonded, in a “chip-on-board” configuration) to a circuit panel, e.g., a printed circuit board or flexible circuit panel, in place of the packaging element 760.

The above-described embodiment shown in FIG. 7D can be especially advantageous for the packaging of chips which include optically active elements, for example, image sensors. Such sensors are especially vulnerable to dust or other particle contamination which is most likely to occur after the chip has been fabricated. Dust or other particles which settle directly on the imaging are of the chip can obscure a portion of the pixels of the active imaging area, thus rendering the chip unusable. The method provided in this embodiment reduces the risk of such contamination by providing a protective optically transmissive cover over the chip prior to performing subsequent higher-level packaging operations.

In another embodiment, as illustrated in FIG. 7E, bonding wires 774 extend from bond pads 208 of the chip to bonding shelves 772 of a gull-wing package 770. This packaged chip preferably includes an optically active chip and an optically transmissive cover 202, such as that described above with respect to FIG. 7D. An additional package lid 776 is mounted to vertical members 778 of the package, the package lid 776 desirably also being at least partially optically transmissive, and preferably being transparent.

In a particular embodiment, as shown in FIG. 7A, a unit 700 includes a conductive interconnect 703 which include a stud bump 662 and a conductive material 704 that seals the stud bump to the cap 102. In this embodiment, the conductive material 704 is a conductive organic material such as a conductive adhesive or conductive sealant. A conductive organic material which is curable at room temperature or a slightly elevated temperature is advantageously used when the material of which the cap is formed is not CTE matched to the chip. In such manner, conductive interconnects 703 can be made to the unit 700 without inducing strains in the chip or cap due to CTE mismatch.

As further shown in FIG. 7A, and in the plan view in FIG. 7B, the unit 700 may further include a plurality of such conductive interconnects 703, which are connected by redistribution or fan-out traces 706, to respective conductive contacts 708. In such manner, signals coming off of the chip 202 are redistributed through the conductive interconnects 703 and the traces 706 to the contacts 708 which lie at a farther distance away from the device region 710 and closer to the edges 712 of the capped chip 700.

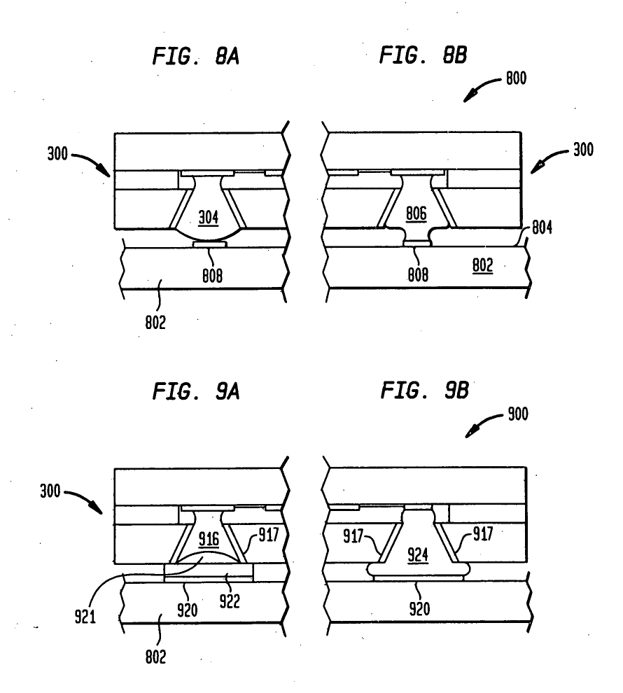

As shown in FIGS. 8A and 8B, once a unit 300 including a capped chip has been formed, it may then be aligned to and surface mounted to a printed circuit board (PCB) or other type of circuit panel 802 to form an assembly 800. FIG. 8A shows the unit 300 having the fusible material 304 of the interconnect aligned to a terminal, e.g., a land 808 of the circuit panel 802. FIG. 8B illustrates the resulting assembly 800 after heating to cause the fusible material to be bonded to the terminal 808 of the circuit panel 802. While flux is generally utilized for the purpose of joining materials in an oxygen-containing environment, the joining process can be performed fluxlessly, under conditions which inhibit contamination, i.e., by joining the unit 300 to the circuit panel 802 in the presence of a non-oxygen containing environment such as nitrogen, argon, or a vacuum, for example.

In accordance with some surface mounting practices, extra solder can be applied to the circuit panel prior to mounting the unit to increase the volume of solder available to make the connection. Such pre-forms of solder can be applied to the terminals of the circuit panel with flux, if needed, prior to mounting the unit. FIGS. 9A and 9B illustrate such technique. As illustrated in FIG. 9A, due to the process used to make the capped chip unit 300, the fusible material 916 provided on the bonding layer 917 of the through hole of the unit 300 does not completely fill the through hole, but leaves a void 921 in a portion of the through hole above the circuit panel 802. By providing a pre-form 922 of additional solder or other fusible material on the terminal 920 of the circuit panel 802, sufficient solder is provided to provide a reliable connection between the unit 300 and the circuit panel. FIG. 9B illustrates the assembly 900 formed by the unit and the circuit after heating to cause the solder contained in the pre-form and in the through hole to melt and join, being drawn into the through hole to form connection 924 to terminal 920. As a result of the added solder from the pre-form, a bulked up solder connection 924 is provided which is sufficient to establish a connection to the terminal.

As an alternative to that described above, the solder pre-form can be provided for use in hierarchically soldering the unit to the circuit panel. Stated another way, the conductive interconnects of the unit 300 can be formed using a solder or other fusible material which melts at a higher temperature than the solder used to join the unit 300 to the circuit panel, such that the original higher temperature material does not melt and reflow during the subsequent joining operation.

FIGS. 10A and 10B illustrate another method for joining the unit 300 to a circuit panel to form an assembly 1000, in which a conductive adhesive 1022 is used to conductively join the unit 300 to a land 1020 of the circuit panel 1019. FIG. 10A illustrates a stage after which the unit 300 has been placed in alignment with the circuit panel 1019, such that the solder 1016 in the through hole is positioned over the land 1020. FIG. 10B illustrates a subsequent stage after the unit has been pressed into contact with the land 1020, causing the conductive adhesive to at least substantially fill the through hole to form a connection 1018. However, as also shown in FIG. 10B, a certain amount of the conductive adhesive 1024 flows off the land 1020 onto other areas of the circuit panel. For this reason, in order to avoid the making of electrical connections in places where they are not desired, the conductive adhesive is desirably an anisotropic conductive adhesive 1024, as shown in FIG. 10B. Such anisotropic conductive adhesive contains discrete conductive particles 1026, such as conductive spheres that are normally spaced from each other by a fluid medium used to carry them. When pressed between two objects at a spacing equal to the width of the sphere, the conductive spheres provide an electrical connection between the two objects. However, due to the lateral spacing between the conductive spheres, no substantial electrical connection is provided in a lateral direction which runs between the surfaces of the two objects.

FIG. 11A illustrates a variation of the embodiment shown above in which the unit 300 includes a bonding layer 1124 which extends from inside the through hole 1104 to have an extension 1126 extending on the mounting face 1107 of the unit 300. The extension 1126 is preferably provided as an annular ring surrounding the through hole 1104. The extension 1126 provides additional surface area for retaining solder 1116, prior to and after the unit 300 is bonded to the circuit panel 1119. The extension 1126 and a larger amount of solder adhering thereto on the unit 300, can mitigate against having to provide additional solder on the terminal 1120 of the circuit panel, as discussed above with respect to FIG. 10A.

FIG. 11B illustrates yet another variation in which unit 300 includes an extension 1128 of the bonding layer 1126 on the surface 1105 of the cap 1106 which faces the chip 1102. During the joining process of the cap to the chip, the extension 1128 draws solder from inside the through hole 1104 onto itself to bring it closer to the bond pad 1114 of the chip 1102. This, in turn, assists in forming the bond between the cap 1106 and the chip 1102.

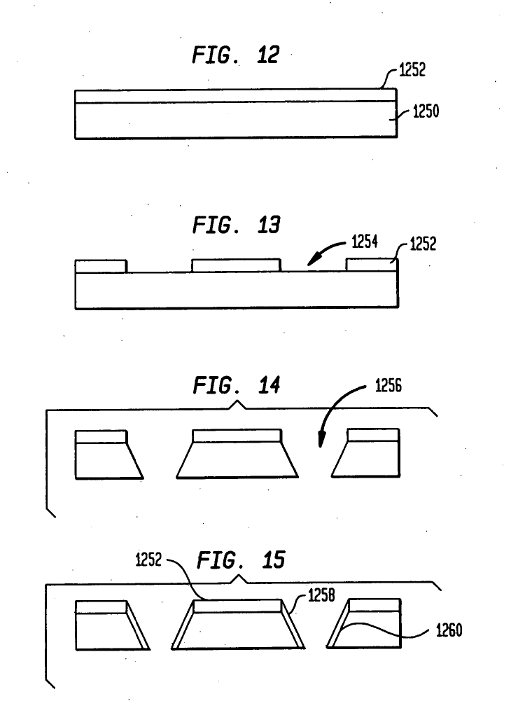

FIGS. 12-17 illustrate a particular variation, of the process described above with respect to FIGS. 1-3D and 8A-8B, or one of the alternatives shown in FIGS. 9A-11B for making a unit and joining it to a circuit panel. A “lid”, like the “cap” described in the foregoing, refers to an article that is mounted as a cover over the front surface of a chip.

Some types of chips, particularly chips which include an electro-optic, device, need to be packaged with a cap which is at least partially optically transmissive. The term “optically transmissive” is used to refer to a material that is either optically transparent or optically translucent in a range of wavelengths of interest, whether such wavelengths of interest are in a visible, infrared or ultraviolet range of the spectrum. For example, electro-optic imaging chips including charge-coupled device (“CCD”) arrays require a lid which includes an optically transmissive package window, in order to prevent dust or other particles from landing on the CCD array, which would optically impair and obscure pixels of the CCD array. Such lid can also be used to protect against damage due to corrosion by atmospheric contaminants, particularly water vapor. The lid can be of any suitable optically transmissive material, including but not limited to glass, polymer and semiconductors. After the chip is joined to the lid, a turret or train assembly containing a lens, and optionally infrared (IR) and/or ultraviolet (UV) filters is joined to the lid, e.g., as by welding, adhesive bonding or use of a fusible material such as solder.

In this variation, a sacrificial coating is applied to a surface of a lid prior to joining the lid to a chip, in order to protect the lid against contamination. The sacrificial coating is then removed later, after steps are performed to join the lid to the chip to form a unit to join that unit to a circuit panel. As above, while the process is described here in terms of joining a lid to a chip, it should also be understood, with appropriate modifications, to apply to the joining of a lid element containing multiple attached lids to a wafer or other substrate which includes multiple attached chips, after which the joined lid element and wafer are severed along dicing lanes to form individually lidded chips.

When a lid is joined to a chip by one of the above-described processes, steps to bond the lid to the chip can introduce contaminating material. Thereafter, steps to join the lidded chip to a circuit panel can introduce further contaminating material. Contamination can result from the environment in which the chip is packaged or, from the nature of the process itself that is used to perform the joining processes. For example, a joining process that involves solder with flux can produce residual material that is undesirable to leave on the surface of the cap. Other methods of bonding a lidded chips

Accordingly, as shown in FIG. 12, a sacrificial coating 1252 is applied to the surface of an optically transmissive lid 1250. The sacrificial coating 1252 is a material which can be applied and remain through the steps of bonding the lid to the chip, but then be removed to leave the surface of the lid in a clean condition without degrading the condition of the joints of the assembly. In the embodiment shown in FIG. 12, the sacrificial coating includes a photosensitive resist film, suitable for use in subsequent photolithographic patterning of the lid. Such resist film is best chosen with regard to the etchant which will be used to pattern the material of the lid, which can vary between inorganic materials such as glasses and organic materials such as polymers. For example, an etchant such as fluorosilicic acid is suitable for patterning a lid which is formed of glass, especially lids which are formed of a glass which has been doped to facilitate chemical etching such as borosilicate glass. In such case, a spin-on photoresist or hot roll laminate photoresist is suitable for use in etching of glass. Such photoresists are also not degraded by temperatures at which solders melt, nor by fluxes used in soldering processes. However, such photoresists are also readily dissolved and cleared from a surface through organic solvents.

FIG. 13 illustrates the patterned photoresist film 1252, after it has been exposed and developed to produce openings 1254 in the photoresist layer 1254. Thereafter, as shown in FIG. 14, the lid is etched, using the patterned photoresist film as a mask to produce through holes 1256.

Thereafter, as shown in FIG. 15, further steps are performed to deposit bonding layers 1258 on the sidewalls 1260 of the through holes. The bonding layers 1258 are provided for the purpose of permitting a fusible material such as solder, tin, etc. to be bonded to the through holes of the lid 1256, in a manner as described above with respect to FIGS. 1-3D. During the deposition, a contact mask may be placed over the photoresist film 1252 as needed, to prevent the photoresist film from being sealed within the bonding material, which might interfere with its later removal depending on the type of resist. Such bonding layer is provided, for example, by deposition including electroless plating or electroless plating followed by electroplating. Alternatively, the bonding layer is provided through vapor phase deposition, i.e., any one of many deposition processes such as physical vapor deposition (PVD), chemical vapor deposition and the like.

A subsequent stage of fabrication is shown in FIG. 16, after the lid 1250 has been joined to a chip 1264 by a set of electrically conductive interconnects 1262, and after the interconnects of the lidded chip have been joined to a circuit panel 1264. The circuit panel 1264 includes an opening 1266 or, alternatively, a window consisting of an optically transmissive material, disposed in alignment with the electro-optic device 1268 of the chip 1264 to provide an optically transmissive path to and from the electro-optic device 1268. The circuit panel 1264 can be of any type, being either rigid, semi-rigid, or flexible. In one embodiment, the circuit panel 1264 is flexible and has a flexible dielectric element on which conductive traces are disposed.

As also shown in FIG. 16, one result of the prior joining processes is unwanted residual matter 1270, e.g., particles, flux or adhesive residue, etc., that remains on the surface of the photoresist film 1252. As illustrated in FIG. 17, the residual matter is then removed in steps used to remove the photoresist film, such as through washing of the assembled circuit panel and the lidded chip in an organic solvent in which the film is soluble. This results in an assembly 1272 in which the contaminating material has been removed, and which is now ready for steps to provide a higher order assembly. Thereafter, a turret, train or other optical element, may be mounted above the opening 1266 in the circuit panel 1264.

The process shown and described above can be modified in several alternative ways. In one alternative process, the lid is patterned by laser drilling rather than chemical etching. The laser drilling is performed after the sacrificial coating is applied, at: which time material ejected from the drilled openings collects on the sacrificial coating. Thereafter, the ejected material is prevented from contaminating the lid when the sacrificial coating is removed from the surface of the lid.

In another embodiment, the sacrificial coating need not be a photoresist film and the coating need not patterned to provide a mask for etching through holes in the lid. Rather, in such embodiment, the sacrificial coating is provided on a face of the lid, and thereafter, the lid is mounted to the chip, such as through a sealing medium or fusible conductive medium as described above. The lidded chip is then mounted to an additional element such as a circuit panel, or alternatively, a turret, or ‘train’, as described above. Thereafter, the sacrificial coating is removed, removing with it residual matter remaining from the prior steps used to mount the lid to the chip and the lidded chip to the additional element.

In a particular form of such embodiment, the sacrificial coating is one that is mechanically releasable from the surface of the lid, such as by peeling. For example, such film can be provided of an adhesively backed plastic, polymeric film capable of withstanding the processes used to join the lid to the chip and that which joins the combined unit to another element. For example, materials such as those used in the adhesive of removable self-stick notepaper and in food-wrap film appear suited for this purpose. Alternatively, the peelable film can be a metal such as molybdenum or other metal or other rigid or semi-rigid polymer.

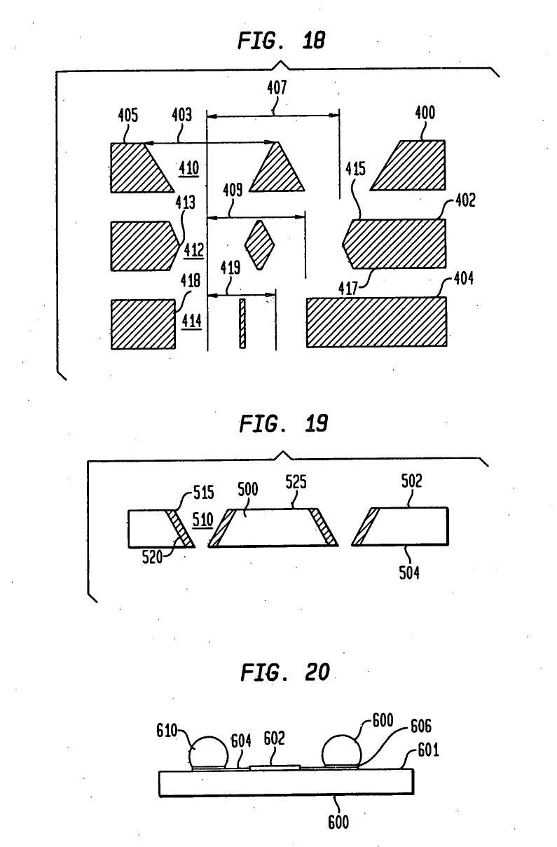

A limiting factor of the embodiments described above with respect to FIGS. 1-3D, for example, is that the lateral spacing between adjacent through holes might not be optimal. Increasing integration density of chips and corresponding decreases in the spacing between adjacent bond pads of a chip demand that a cap to be mounted to the chip have correspondingly decreased spacing between interconnects. Referring to FIG. 3C, the through holes 104 of the cap 102 are shown tapered only from the top surface 105 of the cap, such that a sidewall 107 (FIG. 1) is oriented at an angle typically ranging from about 5 degrees to 70 degrees from the vertical (the vertical being the direction which is normal to the top surface 105). More preferably, the angle of the sidewall (FIG. 1) to the vertical is between 20 degrees to 60 degrees and, most preferably at an angle between 30 degrees and 60 degrees, such that the diameter of the through holes 104 varies between a smaller diameter 330 at the bottom surface 103 and a larger diameter 335 at the top surface 105. Typically, a wet chemical etching process applied to the cap wafer 100 which consists essentially of silicon results in the sidewall 107 making an angle to the vertical of between 20 and 60 degrees. However, laser drilling is another process used to form through holes in a cap wafer which is provided, for example, of silicon, glass, ceramic or other similar material, typically results in an angle of 7 degrees relative to the normal. The angle that the sidewall makes with the top surface 105 is desirably made small, in order to reduce the amount of area occupied by each interconnect, due to the increased pitch of through holes that have a larger angle, as is described in more detail below with reference to FIG. 18. The variation in diameters between the through hole at the top surface 105 with respect to the bottom surface 103 assists the fabrication method as a way of initially holding the solder ball 302 (FIG. 3A) (which is larger than the smaller diameter 330) in place inside the through hole 104; Depending upon the thickness of the cap 102, which, illustratively, ranges between 100 and 300 μm, and the smaller diameter 330 of the through holes, which is typically on the order of 70 to 100 μm, the larger diameter 335 of the through holes may range from twice as large to many times larger than the smaller diameter 330.

When considered in terms of forming interconnects to closely spaced bond pads 208 of a chip 202, it is seen that the larger diameters 335 of the through holes at the top surface 305 of the cap may well limit the spacing at which such interconnects 303 can be made. This concept is best illustrated with respect to. FIG. 18. FIG. 18 illustrates three individual caps 400, 402 and 404, respectively, in which through holes 410, 412, and 414, respectively, have been patterned differently, and in which the pitch between adjacent through holes varies significantly according to the method used to pattern the caps. Thus, cap 400, having through holes 410 which are tapered from only one surface, i.e., the top surface 405, has the largest pitch 407, because of the large diameter 403 of the through holes 410 that exist at the top surface 405. Through holes are ordinarily tapered from one surface of the cap by isotropic etching from that one surface. On the other hand, cap 402 has smaller pitch 409 because its through holes are tapered from both the top surface 415 and the bottom surface 417 of the cap 402, such that the profile of the through holes includes an internal edge 413. Such taper is typically achieved by etching the through holes 412 simultaneously and isotropically from both the top and bottom surfaces of the cap 402. In some cases, depending upon the degree to which the through hole is etched in a lateral direction (being the direction parallel to the diameter 409) the internal edge 413 can acquire the appearance of a “knife edge”. Cap 404 illustrates a case in which through holes 414 are patterned without tapering, having straight, vertical sidewalls. The pitch 419 of through holes 414 of the cap 404 is the smallest of the pitches 407, 409, 419, because of the straight, vertical profile of the through holes 414.

However, the profiles of the through holes of cap 402 and cap 404 are such that they do not permit the same techniques to be used as described above relative to FIGS. 1 through 3D when joining the cap 402 or 404 to a chip. Solderable metallizations cannot be easily provided on sidewalls of the through holes 412 of cap 404 by the patterning processes described above, which are conventionally used in conjunction with vapor phase deposition and wet electrochemical processes to make the tapered through holes as described above relative to FIGS. 1 through 3D. These patterning processes cannot be performed from just the top surface 415 or the bottom surface 417 of the cap, because patterning will be achieved only on surfaces that face up, i.e. only the surface of the through hole above the internal edge 413 and upward, including the top surface 415 of the cap 402. This precludes the portion of the through hole below the internal edge 413, i.e., facing towards the bottom surface 417 from being properly metallized. In the case of cap 404, the vertical, straight profile of the sidewall 418 of the through hole 414 makes it difficult to achieve a suitable metallization. However, in the case of cap 402, the knife-edge through hole profile can still be used to form a capped chip having electrical interconnects which include stud bumps extending from the bond pads, similar to that described above in relation to FIG. 6A. In such case, only the portion of the through hole 412 that is tapered towards the top surface 415 need be metallized. This requires the stud bump (662 in FIG. 6A) to protrude upwardly through the through hole 412 past the knife-edge 413 in the cap 402. On the other hand, the necessity for the through hole 412 to have a bonding layer 106 (FIG. 6A) on the sidewall thereof is diminished if another flowable conductive medium such as an organic medium is used in place of the solder.

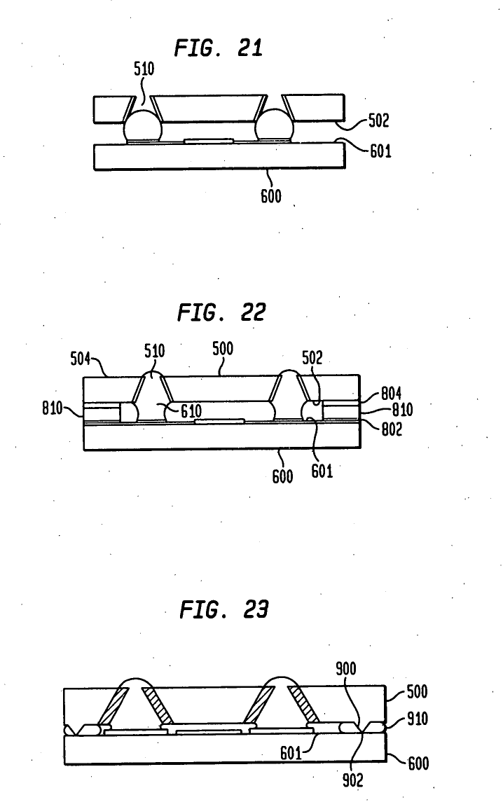

FIGS. 19 through 22 illustrate stages in a method of joining a cap to a chip according to one embodiment of the invention. FIG. 19 shows a cap 500 in an inverted position during fabrication, the cap 500 having a bottom or inner surface 502, a top or outer surface 504, and through holes 510. These designations of the bottom (inner) and top (outer) surfaces refer to the orientation in which the cap will be mounted to the chip, when steps to complete the bonding of the cap to the chip are performed, as shown in FIGS. 21-22. In this embodiment, the through holes are preferably tapered so as to become progressively smaller from the bottom surface toward the top surface. As such, the tapered through holes are substantially frusto-conical in shape. The tapering of the through holes 510 is not absolutely necessary. Tapered through holes assist in achieving some of the potential benefits available by the joining process, as will be apparent from the description below.

In this inverted position, solderable metallizations 515 are formed on the sidewalls 520 of the through holes 510, as by conventional vapor-phase or wet electrochemical processing directed towards the bottom surface of the cap 500, as described above. In one embodiment, the solderable metallizations optionally extend onto a portion 525 of the bottom surface of the cap 500 surrounding each through hole.

FIG. 20 illustrates processing performed to a chip 600 to which cap 500 is to be mounted, the chip having solder-wettable bond pads 606, a device region 602 and wiring 604 interconnecting the device region 602 to the bond pads. A conductive ball 610 is placed on each metallized bond pad, preferably by a fluxless process, in order to avoid flux vapor and residue therefrom from potentially contaminating features at the surface of the chip 600, e.g. the device area 602. A process is then conducted to bond the conductive ball 610 to the chip 600. In a preferred embodiment, the conductive ball is a solder ball, consisting essentially of a solder or other fusible conductive material, e.g., one or more of tin, lead, or eutectic composition or layered arrangement of such metals or other metals, which is adapted to generally soften or liquefy upon being heated to a reflowing temperature, which is relatively low. FIG. 20 illustrates the chip after a solder ball 610 has been placed on each bond pad 606 and bonded thereto by a process which is characterizable as “reflowing”. After reflowing, the solder balls typically retain a shape that is essentially spherical. The temperature of the solder balls is then lowered again for the performance of a subsequent step in which the cap 500 is aligned to the chip 600.

FIG. 21 illustrates such further stage in the process. In this stage, the chip 600 is placed such that the front surface 601 faces up. The cap 500 is turned over, such that the bottom surface 502 of the cap now faces down, toward the front surface 601 of the chip 600. At this stage, the metallized substantially frusto-conical through holes 510 of the cap 500 assist in aligning the cap 500 to the chip 600 in a self-locating manner. This occurs as follows. Rough alignment is achieved between the cap 500 and the chip 600, such that any misalignment is less than the spacing between the centerlines of the through holes. If the cap 500 is then allowed to rest on the chip 600, the through holes 510 will align themselves to the solder balls 610, causing the through holes of the cap 500 to drop down onto the solder balls 610, thus self-locating the through holes 510′ to the solder balls 610. Misalignment between the cap 500 and the chip 600 is subject to variation in two horizontal degrees of freedom (X) and (Y), in three rotational degrees of freedom: turning in the horizontal plane (yaw), forward or backward tilt (pitch) and side-to-side tilt (roll), and in a vertical degree of freedom, i.e. vertical displacement (Z). The self-locating mechanism described herein aligns the cap to the chip with respect to all of these degrees of freedom at the time that the cap 500 is placed on the chip 600.

In the stage shown in FIG. 22, a process is conducted to bond the conductive balls 610 to the metallizations provided in the cap 500. When the conductive balls are solder balls 610, this is preferably conducted as a reflowing process, which causes the material of the solder balls 610 to be drawn further into the through holes 510. As a result of this reflowing process, the solder balls 610 preferably extend somewhat above the top surface 504 of the cap 500. As also shown in FIG. 22, the cap 500 is desirably sealed to the chip 600 by a sealing material 810 which surrounds the device region and the region which includes the bond pads of the chip 600. The sealing material preferably includes a material such as that described above with reference to FIG. 2A.

During such reflowing process, due to the fluid nature of the solder balls 610, means preferably are provided for maintaining a desirable vertical spacing between the opposed surfaces 502, 601 of the cap and the chip. In one embodiment, one or more spacer elements are incorporated into the sealing material. For example, an adhesive sealing material can include spherical or fibrous elements which deform little, thus maintaining a predetermined spacing between the opposed surfaces. In a particular embodiment, a spacer structure is incorporated into one or the other of the cap and the chip. For example, as shown in FIG. 23, a spacer may take the form of a ridge 900 formed as part of the cap 500, the ridge 900 having a knife-edge 902, which is allowed to rest on the front surface 601 of the chip 600. A sealing material 910, such as an adhesive, can be disposed in contact with the ridge 900, as shown in FIG. 23. Otherwise, the sealing material can be displaced from the location of the ridge 900. The ridge 900 allows the cap 500 to be pressed to the chip, e.g., pressure clamped, during the joining process for any of the above-listed sealing materials, while the ridge maintains a desired spacing between the cap 500 and the chip 600. When the above processing is performed simultaneously on an array of attached chips and attached caps, the packaged chips are thereafter diced, i.e., severed into individual packaged chips.

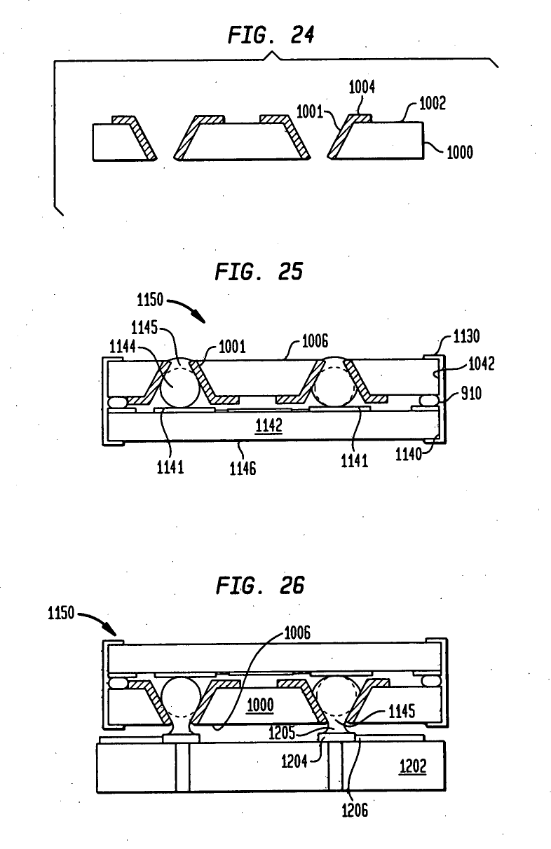

FIG. 24 illustrates a variation of the embodiment described above, in which the metallization of the cap to provide a bonding layer extends as an annular structure 1004 disposed on the bottom surface 1002 of a cap 1000. In one embodiment, an annular structure 1004 is formed by deposition through widened openings of a masking layer (not shown) on the cap through which material is deposited in an additive process to form the metallization, in comparison to those used to form the metallizations shown in FIG. 1. Alternatively, the annular structure 1004 can be formed by decreasing the size of mask patterns disposed between the annular structures, when metallization patterns are formed by a subtractive process following the formation of a metallization layer over the cap. FIG. 25 illustrates a packaged chip 1150 showing a further variation in which the conductive balls 1144 are of a type which remain substantially rigid upon heating to a bonding temperature, or have a core which remains substantially rigid. In such embodiment, the conductive balls 1144 are used to maintain a desirable vertical spacing between the cap 1000 and the chip 1142. A solder bond or diffusion bond can be provided between a metal disposed at an exterior of the conductive ball and the metallization layer 1001 of the cap 1000 and also between such metal and the metallization 1141 of the chip, for example. Joining at this location may also be accomplished using an electrically conductive organic material.

As further shown in FIG. 25, solder or other conductive material 1145 is provided to fill the space between the conductive ball and the top surface 1006 of the cap 1000. In a particular embodiment, an additional seal 1130 can be provided over the peripheral edges 1042, 1140 of the cap and the chip, respectively, by depositing an additional sealing material. The additional seal 1130, which desirably also covers the already provided sealing material 910, may be provided for the purpose of achieving hermeticity, electrical isolation, or other such purpose. The additional seal also preferably extends onto the top surface 1006 of the cap and the rear surface 1146 of the chip.

FIG. 26 illustrates a further embodiment in which the packaged chip 1150 shown in FIG. 25 is mounted to a circuit panel 1202 having one or more terminals 1204 and traces 1206 disposed thereon. The mounting shown in FIG. 26 is through a solder bond between the solder or other conductive material 1145 present at the top surface 1006 of the cap 1000 and masses 1205 of solder disposed on the terminals 1204 of the circuit panel 1202.

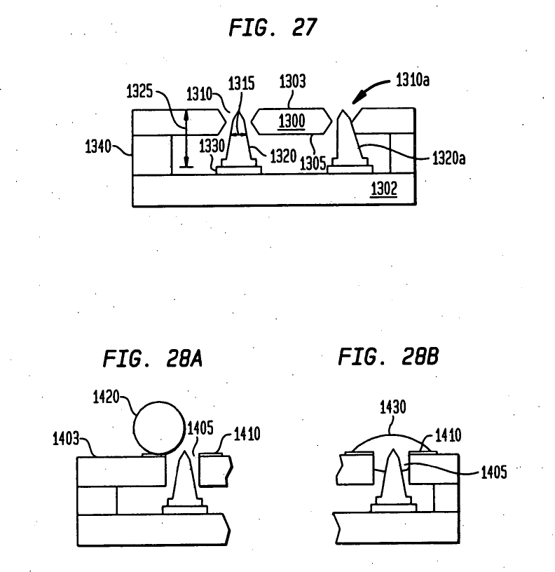

With reference to FIG. 27, another embodiment of a method of making a capped chip having vertical interconnects is shown in which the through holes 1310 of a cap 1300 are not required to have solderable metallizations prior to the cap 1300 being joined to the chip 1302. FIG. 27 illustrates a case in which the through holes 1310 of the cap 1300 are tapered from both the top surface 1303 and the bottom surface 1305, as described above with respect to FIG. 18. In this embodiment, the chip 1302 has stud bumps 1320 disposed on bond pads 1330. The stud bumps 1320 provide a surface for bonding of solder or other conductive material to form a vertical interconnect extending upwardly from a chip 1302. As described in relation to other embodiments above, a “picture frame” ring-seal 1340 seals the gap between the chip and the cap.

The stud bumps 1320 are desirably tapered, as shown in FIG. 27, as can be provided according to several processes known to those skilled in the art. In this embodiment, the stud bump desirably has a shaft diameter 1315 which is close to the mashed ball diameter obtained during the application of the stud bump, and a length 1325 that exceeds the thickness of a sealing material 1340 that seals the cap 1300 to the chip 1302. For example, the stud bumps can be such as those shown and made according to the process described in U.S. Patent Publication No. US 2003/0159276 A1, published Aug. 28, 2003, the disclosure of which is hereby incorporated herein by reference. Tapered stud bumps are more capable of retaining their upwardly extending shape when the cap 1300 is placed over the chip 1302, such that the stud bumps 1320 are more likely to maintain registration with the through holes 1310, than if the stud bumps had a narrow, much more deformable profile. As such, the stud bumps assist the cap 1300 in becoming aligned to the chip 1302 in a self-locating manner, at least on a side-to-side basis, i.e., in at least the X and Y degrees of freedom. However, as shown in FIG. 27, when a through hole 1310a is not in perfect alignment with a stud bump 1320a, the taper of the through hole 1310a allows the stud bump 1320a to deform somewhat, thus allowing it to at least enter the through hole 1310a. Desirably, stud bumps 1320 protrude through the through hole to extend above the top surface 1303 of the cap.

FIG. 28A illustrates a variation of the embodiment shown in FIG. 27, in which the through holes have a straight, vertical profile, rather than being tapered from both sides, as described above with respect to FIG. 27. As shown in FIG. 28A, the top surface 1403 of the cap is optionally provided with a solderable metallization 1410. The solderable metallization is preferably provided as an annular structure surrounding each through hole. FIGS. 28A and 28B illustrate two stages of processing. In an earlier stage of processing, shown in FIG. 28A, a solder ball 1420 is disposed on the metallization 1410, as placed thereon by a prior solder ball stenciling process. A subsequent stage of processing, shown in FIG. 28B, illustrates the reflowed solder ball 1430 as joined to the stud bump 1320 by a subsequent reflowing process. During such reflowing process, the solder ball 1430 is drawn onto the surface of the stud bump 1320 by a solder-wettable metal present at the surface of the stud bump such as gold, tin or platinum. As a result, the solder forms a continuous solid electrically conductive mass connecting the stud bump to the bonding layer 1410 of the cap and sealing the cap at the through hole 1430.

In a variation of the above process, the solder ball 1420 is placed on the metallization 1410 of the cap 1400 and bonded thereto to form a solder bump, prior to the through holes 1405 of the cap being aligned to the stud bumps 1420 provided on a chip 1402.

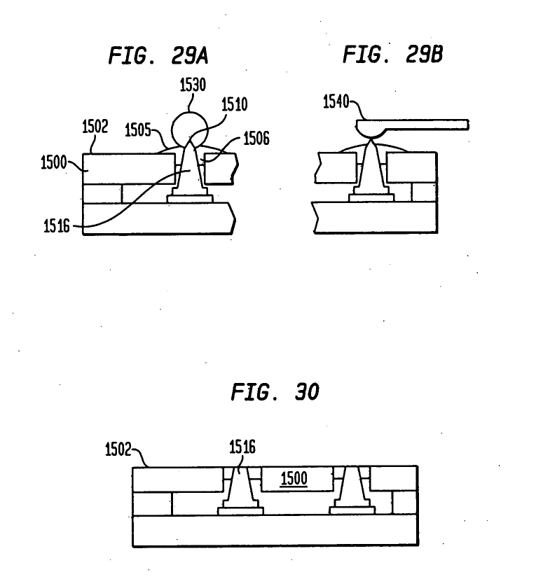

FIG. 29A illustrates a further embodiment; in which external interconnects above the cap 1500 are not soldered to the top surface 1502 of the cap. In this case, a sealing material 1505 such as an organic material which can either be conductive, or nonconductive, e.g. an adhesive material, is applied to the cap 1500 to cover the through holes 1506 at the top surface 1502. After the cap 1500 is placed over the chip 1501 and aligned thereto, the cap 1500 and the chip 1501 are pressed together, causing the peaks 1510 of the stud bumps 1516 to penetrate through the sealing material. In yet another alternative embodiment, the sealing material 1505 can be deposited onto the top surface 1502 of the cap 1500 after the through holes 1506 have been aligned to the stud, bumps 1516 and then the sealing material is etched back, leaving the peaks 1510 of the stud bumps substantially free of the sealing material. In still another alternative, the sealing material 1502 may be applied around the circumference of the stud bump 1516. Thereafter, further steps are taken to complete the interconnections. For example, a solder ball 1530 can be bonded to the stud bump 1516 to provide a surface to form a further interconnection, such as to a circuit panel, e.g., such as shown and described above relative to FIGS. 8A through 11B. Alternatively, the stud bump can be contacted by a sliding or deformable mechanical contact 1540, such as shown in FIG. 29B.

FIG. 30 illustrates yet another variation, in which the stud bumps 1516, which may further include a solder or other joining material applied thereto, are planarized to the top surface 1502 of the cap 1500, after the cap 1500 is aligned and joined thereto. The planarized surfaces of the stud bumps 1516 thus form a land grid array for interconnection of the cap 1500 to further elements such as a circuit panel (not shown).

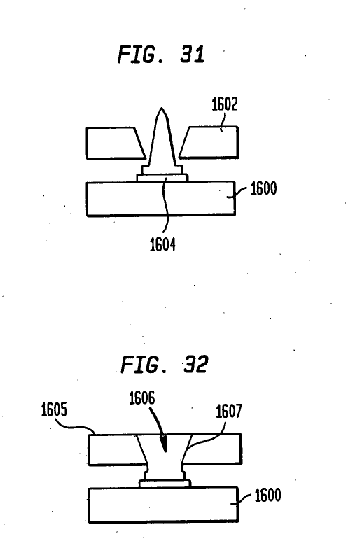

FIGS. 31 and 32 illustrate yet another alternative embodiment in which a cap 1602, is aligned to and placed over a chip 1600 having a stud bump provided on bond pad 1604, and thereafter deformed under pressure until the stud bump engages the sidewall 1607 of the through hole 1606. In such way, the stud bump is ‘coined’ into engagement with the through hole 1606 in a metal forming operation similar to riveting. In this embodiment, the cap 1602 need not have a solder-wettable metallization in the through hole 1606 or on the top surface 1605 of the cap 1602 surrounding the through hole. The stud bump is desirably provided of a highly malleable metal such as gold or alloy thereof, which tends to retain the same shape after being worked in a cold-pressed manner. When such malleable metal is used, the resulting coined stud bump may provide a seal of sufficient integrity to the through hole of the cap. Alternatively, an additional fusible material such as solder or tin can thereafter be deposited and reflowed to seal top surface 1605 of the cap at the through hole, such as when hermeticity is needed. When the stud bump is formed of gold, a fusible material such as solder or tin forms a permanent solid bond.

FIGS. 33-34B illustrate a particular method of simultaneously forming peripheral “picture frame” ring seals between multiple caps of a cap element, e.g., cap wafer, and multiple chips, such as are still attached in wafer form. In this method, the ring seal is formed by aligning the multiple cap element above a wafer containing the chips and providing a flowable sealing material through an opening in a top surface of the cap element. The sealing material is then allowed or caused to flow down onto the surface of the chips below, at which time the sealing material then seals the individual chips to the caps of the cap element. Thereafter, the cap element and the wafer joined thereto are separated into individually capped chips by severing chips along dicing lanes between each chip.

FIG. 33 is a top-down view illustrating a plurality of chips 1700 each having a device region 1702 provided thereon. Chips having sensitive device regions require caps such as those described above in relation to FIGS. 1-3D. Picture frame ring seals 1704 are provided in order to seal the chips to the caps, preferably when the chips are still in wafer form, as one way of protecting against the possibility of degradation to the devices thereon. A method of simultaneously forming seals surrounding a device region of the chips will now be described with reference to FIGS. 34A-B.

FIG. 34A is a top-down view and FIG. 34B is a sectional view illustrating the structure of a cap 1710, such as may be provided as part of a multiple cap element used in this embodiment. The cap 1710 includes ring-like troughs 1712 which are shown overlying a bonding layer 1714 provided on a front surface of a chip which is disposed below the cap 1710. As shown in FIG. 34B, the troughs 1712 extend all the way through the cap 1710 from the top surface 1716 to the bottom surface 1718 of the cap, and is tapered to become smaller in the direction from the top surface towards the bottom surface. A bonding layer 1726, e.g., a solder-wettable metallization, is provided on sidewalls of the trough 1712 as a surface to which a fusible material such as solder wets and fuses to provide a solid bond.

Referring to FIG. 34A, the troughs 1712 extend to almost completely surround a central portion 1720 of the cap which overlies a device region of the chip, the trough being connected to the central portion 1720 by bridges 1722. In a method similar to that described above for making interconnects with reference to FIGS. 1-3D, a fusible material is provided in the trough and then caused to flow along the sidewalls of the trough down onto the bonding layer 1714 of the chip 1700, as best seen in FIG. 34B.

In an alternative embodiment, a low-melting point glass or other suitable material may be placed and flowed downward through the trough to make the seal, in a manner similar to a fusible conductive material. In yet another alternative embodiment, a fluid organic adhesive may be utilized as the sealing material instead of a fusible conductive material.

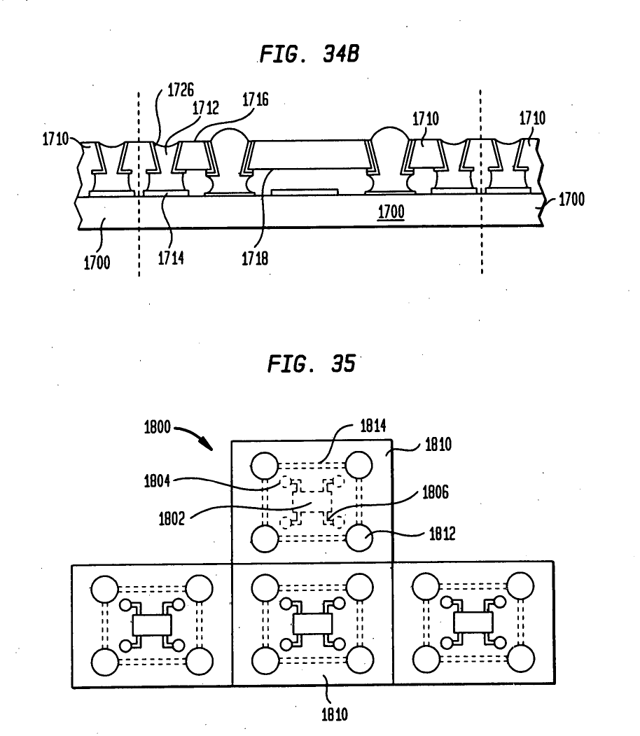

FIG. 35 illustrates a variation of the above-described embodiment in which a set of discrete through holes 1812 are provided in caps 1810 of a cap element 1800, rather than a trough as described above. As shown therein, the cap 1810 is disposed overlying a chip having a central device region 1802, bond pads 1806 and wiring 1806 connecting the device region 1802 to the bond pads 1806, as shown in dotted outline form. The chip includes a bonding layer 1814 disposed in an annular pattern surrounding the bond pads 1806 and device region 1802 of the chip. In this embodiment, the discrete through holes 1812 facilitate the delivery of a more precisely controlled amount of solder to the bonding layer 1814 of the chip, by way of solder balls which are sized to be placed at or within the through holes, in a manner such as described above in relation to FIG. 3B. To achieve a good ring seal between the chip and the cap, neither too little solder nor too much solder should be provided to the bonding layer. Too little solder can cause the seal between the chip and the cap to have voids and possible gaps which would permit air or other fluids, e.g., water vapor to reach the device region 1802 of the chip. On the other hand, too much solder could cause the solder to spread beyond the boundaries of the bonding layer to cause a short circuit.

Accordingly, in this embodiment, solder balls are placed in the through holes and heated to cause the fusible material to flow laterally along the bonding layer 1814 of the chip and a corresponding bonding layer snot shown) of the cap to form a seal which at least substantially surrounds the bond pads 1804 and the device region 1802 of the chip. By judicious choice of the dimensions of the bonding layer and the size of the solder balls, a precisely metered amount of solder can be distributed to the bonding surfaces. The steps used to form the seal are similar to those described above in relation to FIGS. 1-3D or 6A-B for forming electrical interconnects through holes in a chip. Thus, in one embodiment, the solder balls used to form the ring seal are placed in the through holes 1812 at or near the time that solder balls used to form the interconnects are placed in the through holes overlying the bond pads 1802, and then all of the solder balls are melted together by one heating-operation to form the ring seal at the same time as conductive interconnects are formed.

FIGS. 36A-B illustrate yet another alternative in which fewer through holes 1912 are provided in caps 1902 of a multiple cap element 1900. The through holes 1912 are also provided at boundaries between respective chips, thereby greatly decreasing the number of through holes 1912 necessary to form the seal of each chip covered by the cap element. The bonding ring layer 1914 of each chip is provided on the front surface along the periphery of the chip 1902 so as to permit the flow of solder from within a given through hole 1912 onto the bonding layer 1914 to seal the respective chip, thus forming a structure as shown in the sectional view of FIG. 36B. Note, that as illustrated in FIG. 36B, a bonding ring layer 1920 is disposed on the bottom surface 1922 of the cap, as a corresponding wettable metallization onto which the molten solder spreads during the process of reflowing the solder from the solder balls to form the seal. The bond pads 1802 and the conductive interconnects 1924 joined thereto are desirably formed simultaneously with the formation of the ring seal by placing the solder balls in the through holes 1912 at or near the same time that solder balls are placed in through holes 1932 used to form the interconnects. Thereafter, a simultaneous heating step can be used to form the electrical interconnects and the ring seal.

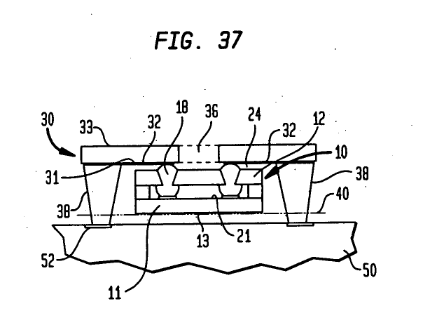

With reference to FIG. 37, a packaged microelectronic device according to another embodiment of the invention incorporates a package structure including a dielectric interposer 30 having electrically conductive traces 32 extending along the bottom surface 31 of the dielectric element. In the embodiment depicted in FIG. 37, the dielectric element incorporates an aperture or window 36. Terminals in the form of electrically conductive posts 38 project downwardly from the bottom surface 31 of the dielectric element, and are electrically connected to traces 32. A dielectric element with posts thereon can be formed, for example, by assembling a metallic sheet or plate having projecting posts thereon with a dielectric layer, and etching the sheet or plate to form the traces. The traces may be disposed on either the bottom surface 31 or the top surface 33 of the dielectric element, or within the dielectric element.

A unit 10 as discussed above is assembled with the package structure so that the top surface 24 of the cover faces upwardly toward the bottom surface 31 of the interposer 30. The unit connections 18 are electrically connected to the traces 31, and hence to terminals or posts 38. The active area 21 of the chip is aligned with the window 36 in the interposer. For example, where active area 21 is an optical detector or emitter, the active area can accept or send light through window 36. In other embodiments, as, for example, where the active area is a MEMS structure, window 36 may be omitted. The bottom surface 13 of the chip incorporated in unit 10 faces downwardly, and defines a theoretical horizontal bottom plane 40 at the level of such bottom surface. The height of posts 38 desirably is greater than the thickness or vertical extent of unit 10, so that posts 38 project downwardly beyond bottom plane 40. Thus, the unit connections 18, and hence the electrical connections to chip 11, are effectively routed to a plane below unit 10.

The package can be mounted on a circuit panel 50 having contact pads 52 thereon, as, for example, by soldering the tips of the posts 38 to the contact pads using conventional surface-mounting soldering techniques. In the completed assembly, unit 10 is positioned with its top surface (the top surface 24 of lid 12) facing upwardly away from circuit panel 50. Because the interposer 30 is larger in plan area than the package, this affords the possibility of the metal posts having a diameter and pitch that is suited for attachment of the structure to a PCB (printed circuit board). Preferably, the interposer 30 or the posts 38 have some degree of mechanical compliance, so that the structure is able to accommodate differences in the height of individual pins or nonplanarity of the circuit panel during assembly and/or testing. The mechanical compliance desirably accommodates thermal expansion mismatch between the circuit panel and the unit 10.

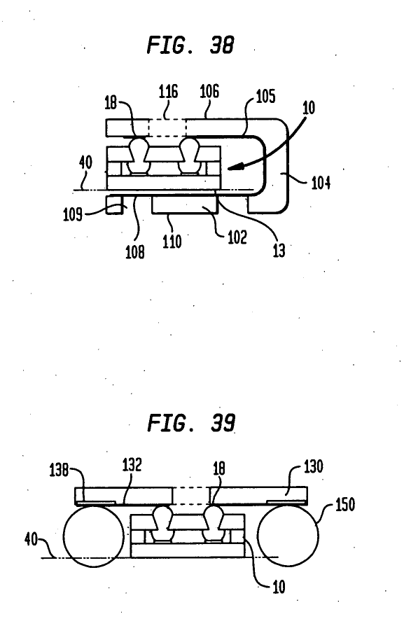

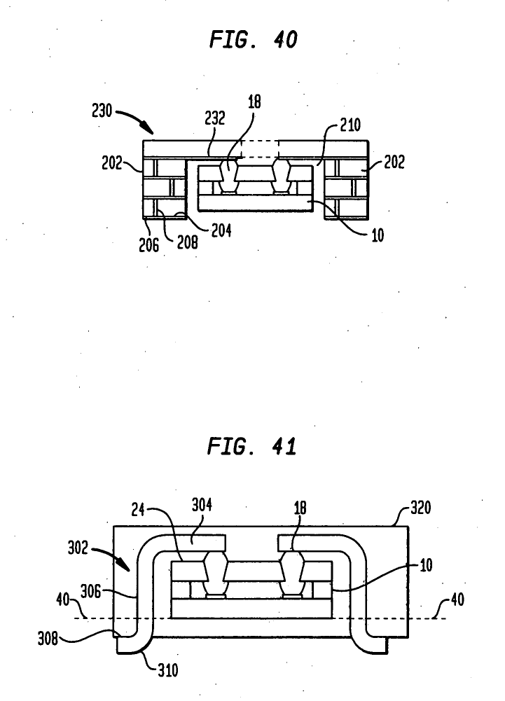

A packaged device according to a further embodiment of the invention (FIG. 38) includes a unit 10 as discussed above, together with a package structure including a dielectric element having a bottom run 102 extending beneath the rear surface 13 of the chip incorporated in the unit and hence extending beneath the bottom plane 40 defined by the unit. The dielectric element further includes a fold region 104 projecting upwardly from the bottom run and a top run 106 extending from the fold region. The dielectric element preferably is a flexible dielectric film having one or more layers of electrically conductive traces 105 extending along the film. The traces extend from the bottom run, along the fold region to the top run. Unit 10 is disposed between the top run 106 and bottom run 102 of the folded dielectric element. Bottom run 102 has terminals 108 connected to traces 105. Terminals 108 are exposed through holes 109 at the bottom surface 110 of the bottom run, which defines the bottom surface of the packaged device. The unit connections 18 of the unit 10 are bonded to traces 105 on the top run 106, and hence are electrically connected to terminals 108. The bond between the unit connections and the traces mechanically secures unit 10 to the top run. Additional elements such as an adhesive between the top surface of the unit and top run 106 may be provided for further securing the unit. Alternatively or additionally, the bottom surface of the unit may be secured to the bottom run. An encapsulant (not shown) may be provided in the space between the runs of the dielectric element, around the unit. Folded package elements for conventional semiconductor chips are described in U.S. Pat. No. 6,225,688 and in commonly assigned U.S. patent application Ser. Nos. 10/077,388, filed Feb. 15, 2002; 10/640,177, filed Aug. 13, 2003; 60/515,313, filed Oct. 29, 2003; and 10/654,375, filed Sep. 3, 2003 the disclosures of which are hereby incorporated by reference herein. Similar structures and techniques can be used in the folded package for a chip and lid unit. Here again, package terminals 108 may have a different layout in plan than the unit connections 18, and the package terminals may have a larger pitch than the unit connections. The packaged device may be secured to a printed circuit panel as, for example, by solder-bonding the terminals 108 to the contact pads of the circuit panel. The terminals 108 may be arranged in a layout which facilitates surface mounting, with adequate terminal size and pitch. A wide range of dimensions and pitches may be used to suit any desired application as, for example, to fit a standard pad layout. Furthermore the package structure desirably provides mechanical compliance such that it is able to safely absorb the differential strain mismatch between the circuit panel and the unit arising from the differential thermal expansion during manufacture and during service. Here again, the unit can be mounted readily with the top surface 24 of the unit facing upwardly away from the circuit panel. A window 116 optionally may be provided in the top run 106 of the dielectric element to permit reception of light or other energy through the top run and through the lid of the unit. As described in the aforementioned incorporated applications, a folded package structure may also define top package terminals (not shown) exposed at the upwardly-facing surface of top run 106. Some or all of the top package terminals are connected to some or all of the traces 105 and, hence, to some or all of the unit connections 18, to some or all of the bottom package terminals 108, or both. The top package terminals can be used for testing or for attaching a further microelectronic element as further discussed below, as for example, to stack several packaged devices. The packages of FIG. 37, discussed above, and of FIGS. 39 and 40 can also be provided with top package terminals.

The packaged device of FIG. 39 is generally similar to that discussed above in connection with FIG. 37, except that the package terminals 138 exposed at the bottom surface 132 of the interposer 130 are in the form of flat pads rather than downwardly-projecting posts. Thus, the terminals themselves do not project downwardly beyond the bottom plane 40 of unit 10. In the embodiment of FIG. 39, additional elements in the form of masses 150 of a bonding material such as, for example, conventional solder balls are provided in contact with the terminals. These additional elements or masses 105 project downwardly beyond the bottom plane. The additional elements or masses 150 can be provided as part of the packaged device, or may be added during assembly to a circuit panel as, for example, by providing the masses on the contact pads of the circuit panel prior to mounting the packaged device. The additional elements or masses desirably have a height or vertical extent greater than the thickness of unit 10. The additional elements or masses 150 desirably provide substantial mechanical compliance. Elements other than solder conventional solder spheres may be used. For example, elements commonly referred to as solid-core solder balls, having a core formed from a relatively high-melting point metal such as copper covered by a layer of solder may be used. In a further variant, the core of such a ball may be hollow or may include a polymeric or other non-metallic material covered by a thin layer of metal, which in turn may be covered by a solder. In yet another variant, the additional elements or masses 150 may be masses of a polymer-based conductive material as, for example, a metal-filled solder. In yet another variant, the additional elements may be provided as pins (not shown) projecting upwardly from the circuit panel or as contacts on a socket which, in turn, is surface-mounted to the circuit panel.

The interposer 130 may be rigid, in the case of a direct-bonded copper (DBC) ceramic substrate, semi flexible, for example a PCB, or fully flexible, as typified by a dielectric film. The choice of material for the planar interposer will depend on the application. For example, a flexible dielectric film will help absorb thermal expansion mismatch between the PCB and the wafer scale package, while a DBC substrate will be mechanically robust and facilitate the removal of heat from the package. The planar interposer is larger in plan area than the unit 10, and hence trace 132 routes unit connections 18 to a layout which is different from, and larger than, the layout of the unit connections. Traces 132 may be provided on either or both sides of interposer 130, or within the thickness of the interposer. Where the terminals are disposed above plane of the interposer bottom surface 132, the terminals are exposed at the bottom surface of the interposer through holes (not shown) extending partially or fully through the interposer. Here again, the interposer may have an aperture in the region of the unit to facilitate assembly of the structure or provide a passageway for radiation between the unit and the environment.

In the embodiment of FIG. 40, the package structure includes a planar interposer 230 similar to those used in the embodiments of FIGS. 37 and 39, discussed above, and also includes a spacer 202 disposed beneath a peripheral region of the interposer, outside of the area occupied by unit 10. The spacer projects downwardly from the interposer, and downwardly beyond the bottom plane 40 defined by unit 10. The bottom surface 204 of the spacer defines a part of the bottom surface of the packaged device. Spacer 202 is formed from a dielectric material, and has package terminals 206 disposed on spacer bottom surface 204. Package terminals 206 are electrically connected by vertical conductors 208 carried on spacer 202 to traces 232 on the interposer. Thus, the package terminals 206 are electrically connected to unit connections 18. For example, spacer 202 may include one or more layers of a dielectric material such as a ceramic or polymeric circuit board having through vias formed therein and partially or completely filled by a conductive material forming the vertical conductors 208. In this arrangement, the package structure including interposer 230 and spacer 202 defines a cavity to accommodate unit 10.

In another arrangement (FIG. 41), the package structure incorporates a lead frame having generally ‘S’-shaped leads 302. Leads 302 have portions 304 overlying the top surface 24 of the unit, these portions being connected to unit connections 18. The leads 302 also have downwardly-extending portions 306, and terminal portions 308. The terminal portions have exposed surfaces 310 forming the package terminals. These package terminals are disposed below the bottom plane 40 of unit 10, and are exposed at the bottom surface of the package defined by the bottom surface of the unit. In the embodiment illustrated, the terminal portions project outwardly in horizontal directions. The downwardly-extending portions 306 also may slope outwardly. The package structure optionally may include an overmold or encapsulant 320 surrounding the leads and unit and further securing the leads in place. The overmold or encapsulant 320 should not cover the surfaces 310 of the terminal portions, so that these surfaces remain exposed for mounting. The overmold may terminate at or above the bottom plane 40 of the unit, or may extend below the unit. In a further variant, the downwardly-extending portions 306 of the leads can be attached to the sides of unit 10 as, for example, by a dielectric adhesive, where additional mechanical support is required. In the embodiment depicted in FIG. 41, the lead portions 304 are shown as directly connected to unit connections 18 so that these connections physically attach the lead frame to the unit. However, the lead portions 304 may be connected to the unit connections by intermediate elements as, for example, by wire bonds. The techniques commonly employed to join a lead frame with a chip may be used to join the lead frame with unit 10.

In the embodiment of FIG. 41, the leads route and fan out the electrical connections to or below the bottom plane of the unit, provided the lead frame height exceeds the package thickness. The lead frame can be made to possess a certain degree of compliancy and thereby accommodate thermal expansion mismatch between the wafer scale package and the circuit panel. Also, it is possible to extend the lead frame in plan area to provide fan out and achieve connection to the circuit panel at a coarser pitch than the interconnects to the wafer scale package.

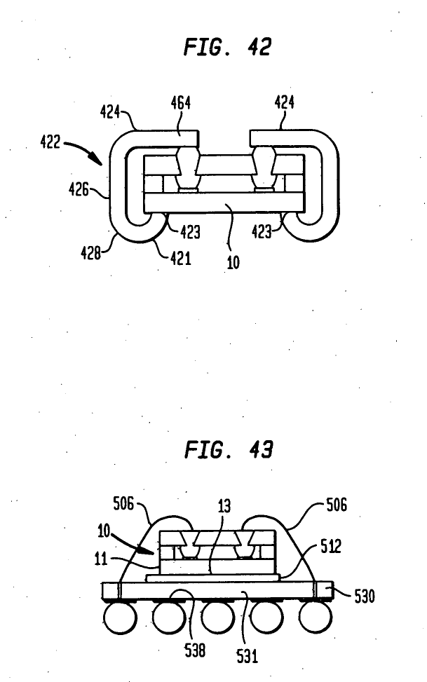

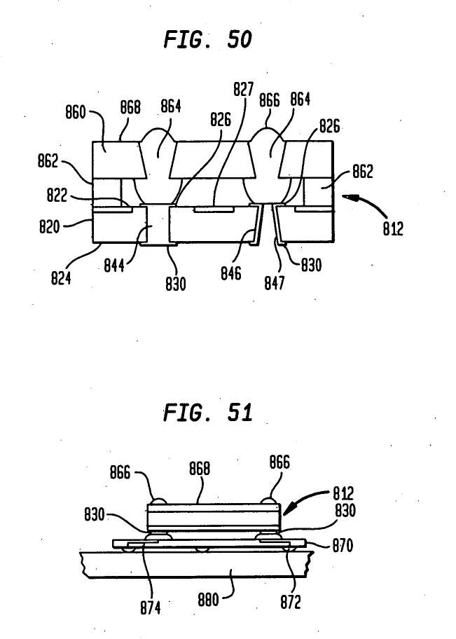

The embodiment depicted in FIG. 42 is generally similar to the embodiment of FIG. 41, except that the terminal portions 428 of the leads constituting lead frame 422 extend inwardly from the downwardly-extending portions 426, so that the terminal portions 428, and hence the exposed portions 421 constituting the package terminals, are disposed within the area occupied by unit 10. Thus, the packaged device as a whole may occupy an area which is approximately the same as, or only slightly larger than, that occupied by unit 10. The leads of lead frame 422 may be resilient, and may be held in place on unit 10 in whole or in part by resilient engagement with the unit. The unit is resiliently engaged between the terminal portions 428 and the top portions 424 of the leads. Alternatively or additionally, the leads can be affixed by solder, glass or an organic adhesive on any or all of the faces of the package that they touch. A similar structure can be made using a flexible tape with traces thereon wrapped around the edges of the unit. A structure with a flexible tape wrapped around edges of a chip is disclosed in certain embodiments of U.S. Pat. No. 5,347,159, the disclosure of which is incorporated by reference herein. For applications where fan-out is required, the metal leads or tape can be provided with extensions than protrude outside of the plan area of the package. In a further variant, an overmold or encapsulant (not shown) may cover the leads and the unit, but desirably does not cover the exposed surfaces 421 of terminal portions 428 of the leads. In a further variant, the terminal portions 428, at the innermost extremities 423, may be free of the overmold or encapsulant, to increase flexibility and hence mechanical compliance of the leads. In yet another variant, whether or not an overmold is employed, upwardly facing surfaces 424 on the upper portions 424 of the leads may remain exposed, so as to provide exposed package terminals at the top of the packaged device as well as at the bottom. As explained further below with reference to FIGS. 50-52, the terminals at the top of the packaged device can be used as test terminals, or for the mounting of additional microelectronic devices. An additional microelectronic device mounted on the top package terminals may be connected to the unit 10, to the circuit panel upon which the bottom package terminals 428 are mounted, or both by leads 422. Packages of this type may be mounted in a stacked arrangement, with the top terminals of one device connected to the bottom package terminals of the next higher device in the stack.

In the structure depicted in FIG. 43, the bottom surface of 13 unit 10 (defined by the rear surface of chip 11) is mechanically attached to a planar interposer 530 by a mounting structure 502 which may include a layer of a die attach material. As discussed above, a wide variety of materials can be used for the interposer. Preferably, the interposer 530 is flexible and the mounting structure 502 has appreciable mechanical compliance. For example, mounting structure 502 may include a layer of a compliant material. In this embodiment, the bottom surface 531 of interposer 530 defines the bottom surface of the packaged device. Terminals 538 are exposed at this bottom surface. Electrical connection between the terminals 538 and the unit connections 18 on the top surface of unit 10 are made by leads 506 which may be wire bonds, metallic ribbons or the like. The connections between the unit-connections 18 and terminals 538 may include other conductive elements such as traces (not shown) extending along the interposer and vias extending through the interposer. The connections, such as wire bonds 506, desirably are flexible, so that terminals 538 remain movable with respect to unit 10 as permitted, by the compliance of mounting structure 502. Interposer 530 can carry a relatively compact array of terminals 538, at any desired pitch. Some or all of these terminals may be disposed in the region of interposer 530 disposed below unit 10. Arrangements of this type can provide a high density and space efficient interconnect to the circuit panel.

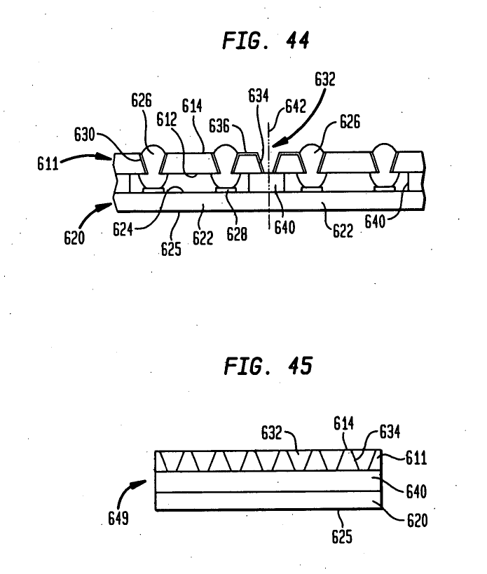

As shown in FIGS. 44 and 45, units can be provided with additional unit connections. In a process according to one embodiment of the invention, a lid element 611 is united with a unitary wafer element 620, such as an entire wafer or a portion of a wafer, incorporating a plurality of semiconductor chips 622, so that a bottom surface 612 of the lid element faces toward a front surface 624 of the wafer element. A top surface 614 of the lid element faces upwardly away from the wafer element. Vertical interconnect structures 626 are formed so that the vertical interconnect structures extend upwardly through lid 611 from contacts 628 on the chip so as to provide unit connections exposed at the top surface 614 of the lid element 611. As described in the aforementioned commonly owned incorporated applications Ser. Nos. 60/506,600; 60/515,615; 60/532,341; and 60/568,041, the lid element may have through vias lined with a thin layer 630 of a metal. The metallic via liners 630 can be provided, for example, by depositing the metal on the lid element and selectively etching the metal prior to assembly with the wafer element. A solder or other electrically conductive bonding material is provided on the lid element, on the wafer element or both and reflowed so that the bonding material wets the metal lining in the vias and wets contacts 628 on the wafer element to form the vertical interconnect structures. In the process of FIG. 44, the lid element is provided with additional rows of vias 632 at locations corresponding to the boundaries between chips in the wafer element. These additional vias may extend partially through the lid or entirely through the lid element as depicted in FIG. 44. Additional vias 632 are lined with metal or other conductive material 634, and electrically conductive redistribution traces 636 are provided on a surface of the lid so that the traces interconnect the liners in some or all of the additional vias 632 with the via liners 630 in some or all of the other vias used to form the vertical interconnect structures. The additional liners 634 and traces 636 may be formed during the same process steps used to make the via liners 630. Thus, the conductive liners 634 in the additional vias will be electrically connected to at least some of the vertical interconnect structures 626 when the vertical interconnect structures are formed. As described in the co-pending applications, a sealant 640 is provided between the lid element and the wafer element at boundaries between adjacent chips, so that the sealant extends around the periphery of each chip.

After assembly of the lid element, wafer element and sealant, and desirably after formation of the vertical interconnect structures, the lid element, wafer element and sealant are severed along lines of severance 642, also referred to as dicing lanes, one of which is visible in FIG. 44. The severing step forms individual units, each including one or more chips and a lid with vertical interconnect elements extending through it. As best seen in the elevational view of FIG. 45, each such unit has vertically-extensive edge surfaces 649 extending between the top surface 614 of the lid and the bottom surface 625 of the chip. The severing process cuts the additional vias 632, leaving partial vias exposed at the edge surfaces of the units. As shown in FIG. 45, an elevational view showing one such edge surface 649, the conductive liners 634 within the severed vias form edge connections exposed at the edge surfaces of the units. At least some of these edge connections are electrically connected to at least some of the vertical interconnect structures 626 and hence to at least some of the contacts 628 on the chip. Edge connections can be provided in this manner on one, some or all of the edge surfaces of the unit. In a variant of this process, the redistribution traces 636 may be formed of the bottom surface 612 of the lid element, rather than on the top surface of such element.

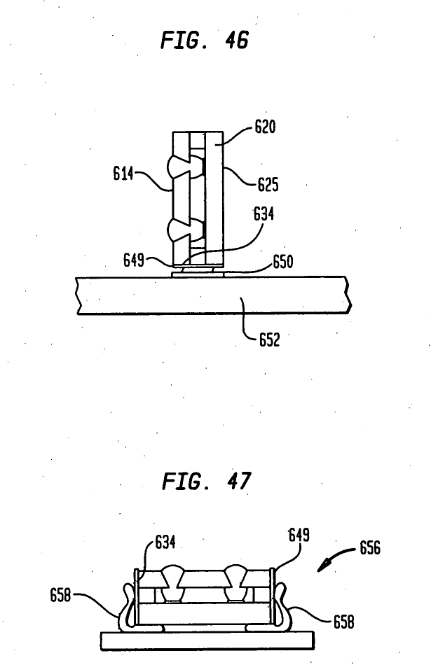

As seen in FIG. 46, the edge connections 634 may be bonded to contact pads 650 of a circuit panel 652 or other substrate so that the unit can be mounted with the top surface 614 and, bottom surface 625 of the unit extending transverse to the plane of the substrate, and with an edge surface 649 bearing the edge connections facing downwardly toward the substrate. Alternatively, the unit can be mounted in a socket 656 (FIG. 47) with elements of the socket such as resilient fingers 658 engaging the edge connections 634 on the edge surfaces 649. The unit also can be mounted as discussed above, with connections made through top unit connections made by vertical interconnect structures 626.

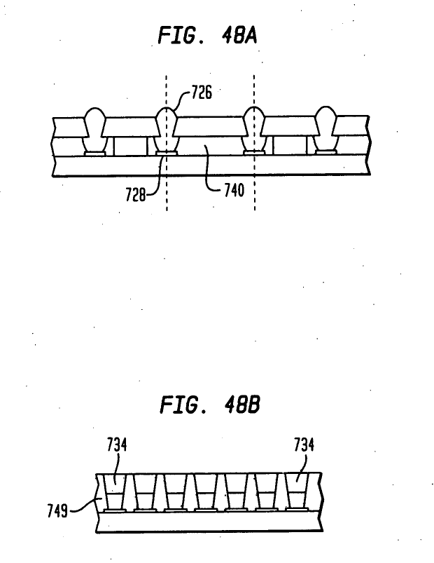

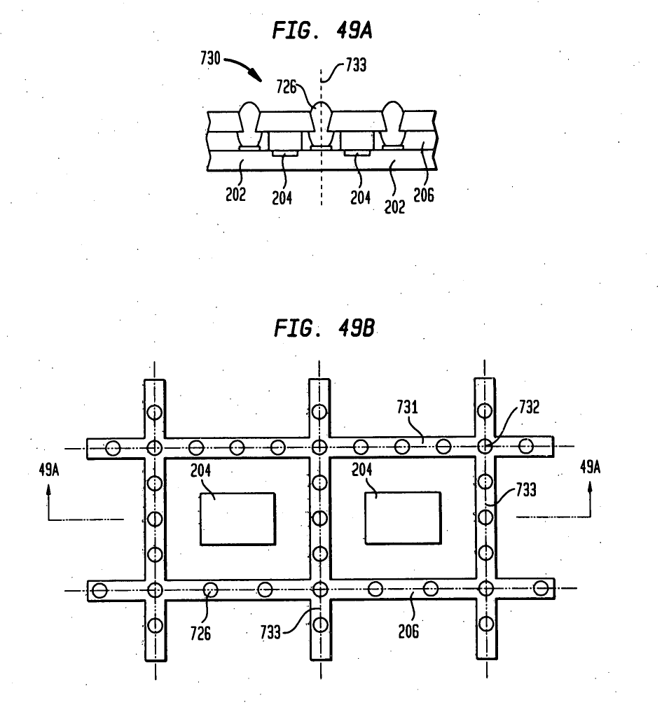

The embodiment of FIGS. 48A-48B is generally similar to the embodiment discussed above with reference to FIGS. 44-47. However, in the embodiment of FIGS. 48 and 49, the sealant 740 extends inwardly from the boundaries of the chips beyond at least some of the vertical interconnect structures 726. The severance operation is conducted so as to cut through these interconnect structures and thus form these vertical interconnect structures 726 into edge contacts 734 at edge surfaces 749. The inwardly-extending sealant 740 remains as a continuous seal between the chip and lid in each unit. The severing operation depicted in FIG. 48A uses two cuts, along two parallel lines of severance, at each boundary between adjacent chips. In a variant, some or all of the contacts 728 and the associated vertical interconnect structures 726 may lie at the boundary between adjacent chips, so that a single cut will form a single row of vertical interconnect structures into edge contacts on two units. Some or all of the vertical interconnect structures in each unit may be converted to edge contacts. A unit formed in this manner can be mounted as discussed above with reference to FIGS. 46 and 47. In a further variant (not shown) a unit having unit connections on the top surface of the lid can be provided with edge connections by affixing the edge connections onto the unit as, for example, by adhesively bonding a dielectric carrier with conductive connections thereon to the edge surfaces of the unit, or by affixing discrete edge connection elements to the edge surfaces of the unit. The affixed edge connections can be electrically connected to the unit connections on the top surface of the lid by any suitable connection technique. For example, if the dielectric carrier is a flexible dielectric element with traces thereon, the same can be folded over the edge of the lid so that portions of the traces extend along the lid top surface to the unit connections. Alternatively, the edge connections can be connected to the unit connections by wire bonding.

A variation of the capped chip structure described above is illustrated in FIGS. 49A-49B. FIG. 49A is a sectional view of the capped chip structure 730 shown in FIG. 49B through line 49A-49A. In such structure 730, the vertical interconnect structures 726, some of which are disposed along peripheral edges 731 of the chip, are oriented in a first direction, as shown in FIG. 49B. Some others of the interconnect structures are disposed along other peripheral edges 733 of the chip, which are oriented in a second direction which lies at an angle to the first direction. For example, the edges 733 are oriented at a right angle to the edges 731. In a preferred embodiment, some of the interconnect structures 726 are also disposed at corners 732 between the two edges. Providing the interconnect structures along the peripheral edges 731, 733 of the chip, and/or the corners 732 may permit further improvements to reduce the area of the wafer occupied by the chip, because fewer interconnect structures 726 are needed, which consequently occupy less of the chip area. In some cases, the interconnect structures 726 are placed as far apart or farther from the device area 204 of the chip, as they are in the embodiments described above with reference to FIGS. 1-3D, for example. This assists in the manufacturability of the structure and the ability to interconnect the structure 730 in the next higher level assembly. Interconnects that are spaced at intervals farther apart assist in manufacturability of the higher level assembly, because the tolerances for making such connections of the assembly are not as tight as they tend to be when fabricating the chip. Interconnection of the structure 730 to the higher level assembly, e.g., a circuit panel, is preferably by way of mechanical attachment, e.g., socketing, or electrical connection, such as shown and described above with reference to FIGS. 44-47.

A unit 812 (FIG. 50) according, to a further embodiment of the invention incorporates a chip 820 which, like the chips discussed above, has a front face 822 and a rear face 824. Chip 820 has contacts 826 exposed at the front face 822. Here again, the chip has an active element 827 such as a micro-electromechanical element, an electroacoustic element such as a SAW element, or an optoelectronic element such as an array of sensing pixels, the active element being disposed at or adjacent to the front face 822. However, in this embodiment, the chip has rear contacts 830 exposed at the rear face of the chip. Some or all of the rear-face contacts 830 are electrically connected to the front-face contacts 826 and to the circuit elements of the chip, including the active element 827. The electrical connections to the rear-face contacts 830 include electrically conductive structures extending partially or completely through the thickness of the chip. These conductive structures should not compromise the physical integrity of the unit, and thus should not provide leakage paths extending between the front and rear surfaces of the chip. These connections typically are formed while the chip is being processed as a part of a wafer. One method of forming conductive structures through the thickness of semiconductor wafers is by ion implantation, or other techniques, to create a highly doped column 844 of semiconductor material in the chip that is sufficiently low resistivity for the application. Alternatively, a hollow via or “pipe” 846 may be carved through the thickness of the semiconductor, so that the pipe extends from the rear face 824 to the contact 826 on the front face. The pipe is sealed at the front surface by the metallic material of the front-face contact. The walls of the pipe may be made conductive by coating with a metal film 847. In a variant, the pipe can be completely filled with metal (not shown).

A wafer element incorporating numerous chips 820 as shown in FIG. 50 is assembled with a lid element including lids 860, one of which is shown in FIG. 50, and with a sealant 862 at the boundaries between adjacent chips in the wafer element, and provided with vertical interconnect structures 864 extending from at least some of the top face contacts 826 on the chip through lid 860 to form top unit connections 866 exposed at the top surface 868 of the lid. The units are severed from the wafer element, leaving the individual units in the configuration depicted in FIG. 50. In this configuration, the rear face contacts 830 of the chip form bottom unit connections exposed on the bottom surface 824 of the chip, which constitutes the bottom surface of the unit, whereas top unit connections 866 are exposed at the top surface 868 of the lid, which constitutes the top surface of the unit. At least some of the top unit connections 866 are electrically connected to at least some of the bottom unit connections 830, to the internal circuitry of the chip or both. The unit provides continuous electrical paths between at least some, and preferably all, of the top unit connections 866 and at least some, and preferably all, of the bottom unit connections 830.

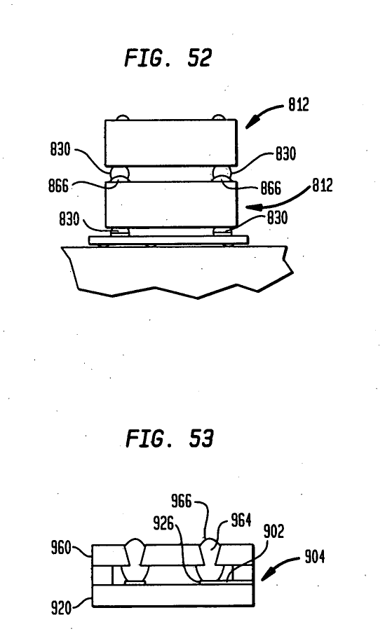

The completed unit 812 can be directly mounted on a circuit panel by bonding the bottom unit connections 830 to contact pads on the circuit panel using techniques similar to those used in flip-chip direct chip mounting. This leaves the unit in a face-up orientation, with the lid and unit top surface 868 facing upwardly away from the circuit panel. Alternatively, the unit 802 can be packaged on an intermediate substrate or interposer 870 (FIG. 51) with the top surface 868 facing away from the interposer, and then the interposer be bonded to a circuit panel 880. The interposer has package terminals 872 exposed at its bottom surface, and traces 874′ electrically connecting the bottom unit connections 830 to the terminals. The interposer typically provides redistribution so that the terminals 872 are disposed at a larger pitch than the bottom terminals 830. The interposer may also provide mechanical compliance between the unit and the circuit panel 880. The interposer may be generally similar to those used in manufacture of chip-scale packages.

The top unit connections 866 can be used as test connections to allow engagement of a test probe either before or after mounting the unit to a circuit panel. The top unit connections provide probe points advantageously situated on the top surface of the unit. Moreover, the probing process will not damage the bottom unit connections that will be connected to the circuit panel. An additional microelectronic element may be connected to the top unit connections 866 to form part of the circuit in the completed assembly. The additional microelectronic element may be another unit 812 of similar configuration, so that the units are stacked vertically as shown in FIG. 52. Top unit connections 866 of one unit are connected to the bottom unit connections 830 of the next higher unit in the stack. The units thus form common vertical busses disposed inside of the plan area of the units.

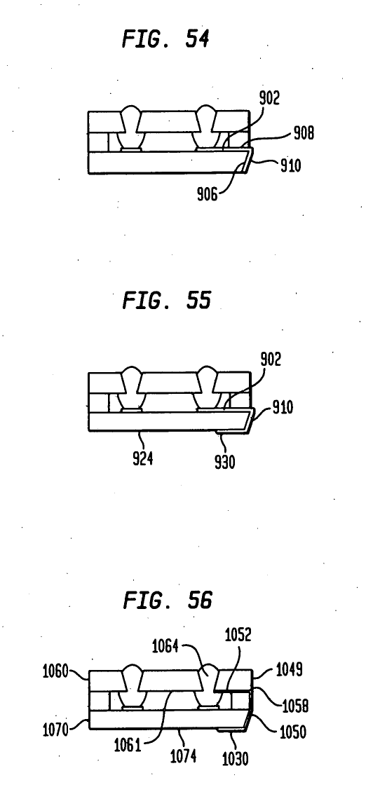

In a further embodiment (FIGS. 53-55), bottom unit connections are provided by forming conductive traces along the edge surfaces of the chip, rather than by providing connections through the chip. As shown in FIG. 53, the wafer element has top surface traces 902 extending from at least some of the top surface contacts 926 on the chips to the boundaries between chips. A lid element 960 and vertical interconnect structures 964 forming top unit connections 966 are provided, as discussed above. Here again, the wafer element and lid element are severed by cutting along the boundaries between chips to form individual units. Thus, after severance, the top surface traces 902 extend to the edge surfaces 904 of the unit. The severing process may be conducted so as to form a trench with sloping edges at the boundaries between units, before severance of the lid element. The sloping trench surfaces provide sloping edge surfaces 906 on the chips, as shown in FIG. 54. A further trace 910 is formed along this sloping edge surface, typically before severance of the lid element. As shown in FIG. 55, further conductive traces are formed along the bottom surface 924 of the chip, so as to provide bottom unit connections 930. Here again, some or all of the bottom unit connections 930 are connected to the circuitry of the chip and to the top unit connections 966. A unit made in this manner can be used as discussed above with reference to FIGS. 50 and 51.

In a further embodiment of the invention (FIG. 56), traces 1002 are provided on the bottom surface 1061 of the lid element 1060 prior to assembly of the lid element with the wafer element. The traces extend from the vias used to form the vertical interconnect structures 1064 to the areas corresponding to the boundaries between chips. During formation of vertical interconnect structures 1064, the solder used to form the vertical interconnect structures makes contact with the interior ends of traces 1002. After severance of the wafer element 1020 and lid element 1060, the ends 1008 of traces 1002 are exposed at the edge surfaces 1049 of the unit. Traces 1010 extending along the edge surfaces connect traces 1002 with bottom unit contacts 1030 provided on the bottom surface 1024 of the chip. This arrangement avoids the need for special processing of the wafer element to form traces 902 as discussed above with reference to FIGS. 53-55.

Numerous variations and combinations of the features discussed above can be used. For example, units having bottom unit connections in addition to top unit connections can be used with package structures connected to the top unit connections as discussed above, for example, those discussed with reference to FIGS. 37 and 39. In such an arrangement, both the terminals of the package structure and the bottom unit connections are exposed at the bottom of the packaged device for connection to a circuit panel. In a further variant, units can be provided with both edge unit connections as discussed with reference to FIGS. 44-49 and bottom unit connections as discussed above with reference to FIGS. 50-56.

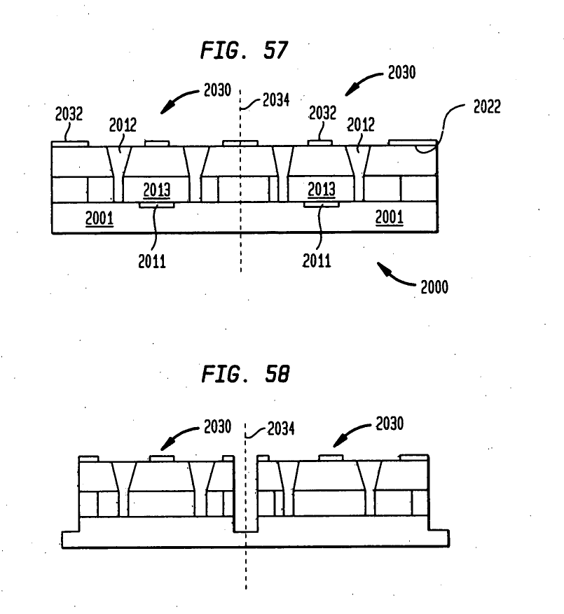

FIGS. 57-6.0 illustrate an embodiment of the invention in which an additional seal is formed to seal peripheral edges of units, i.e., capped or lidded chips, that are produced by one or the various embodiments of wafer-scale processes such as described above with reference to FIGS. 1-6B, FIGS. 18-28B, and FIGS. 30-32. FIG. 60 illustrates the structure of two such units 2030 that are provided according to this embodiment of the invention.

Among many alternatives discussed in the foregoing, an organic material is a preferred material for use in forming a “picture frame” seal 2002 to enclose the active region of a chip, due to the ability of at least some such materials to be applied and form bonds at an ambient temperature to only slightly elevated temperatures. Use of such materials helps to avoid the above-described CTE mismatch problems, particularly when the chip-containing wafer and the lid-containing wafer are of different materials. The use of such organic sealing material is particularly advantageous in conjunction with the low-temperature processes described above for forming interconnects, such as those in which stud bumps are mounted to the chips which remain in wafer form, and a lid or cap-containing wafer is then aligned and sealed with a conductive or nonconductive organic material to form interconnects (e.g., as shown and described above relative to FIGS. 29A and 30). Certain types of chips, particularly those containing SAW devices, are especially sensitive to strain. SAW devices typically operate to provide a narrow bandpass filter function in which the center frequency of the passband is subject to change due to a strain in the device. The low modulus of elasticity of organic materials helps the organic material to mitigate the effects of differential strain which occurs between the chip-containing wafer and the lid wafer due to CTE mismatch.

However, despite the foregoing benefits, an organic material may not provide a sufficiently hermetic seal for some devices. A tighter seal is generally achieved through inorganic materials such as a metal or glass rather than organic materials, but is subject to the above-described difficulties.

Hence, in the embodiment illustrated in FIG. 60, an additional layer 2004 is deposited and patterned to overlie peripheral edges 2020 of the unit, as an impermeable medium to seal edges 2006 of the chip 2001, the edges 2008 of the lid, as well as the organic seal material 2002. As also shown in FIG. 60, the same layer 2004, when provided of a conductive material, is also desirably patterned to form metal contacts 2010 connected to respective ones of the conductive interconnects 2012 on each chip 2001.

FIGS. 57-59 show stages in an illustrative method of fabricating the units 2030 shown in FIG. 60. As shown in FIG. 57, a pair of units 2030 are shown, each remaining attached at boundary 2034 as portions of a wafer. For ease of reference, only two such units are shown. However, a substantial number of such units can be simultaneously processed in wafer form according to the method described herein. Each chip includes a device 2011, e.g., illustratively, a SAW or MEMs device, a void 2013 disposed above the device and conductive interconnects 2012 extending upwardly from the chips 2001.

A photosensitive resist film is patterned by photolithography to form resist patterns 2032 on the surface 2022 of the lid portion of the units. Illustratively, the resist film is a lift-off film, in that any material coating applied onto the resist film will also be removed when the resist film is subsequently removed. The resist patterns 2032 are formed as islands surrounding each of the pre-existing interconnects 2012, so as to maintain the interconnects isolated from each other upon the subsequent removal of the resist patterns with metal coating applied thereto.

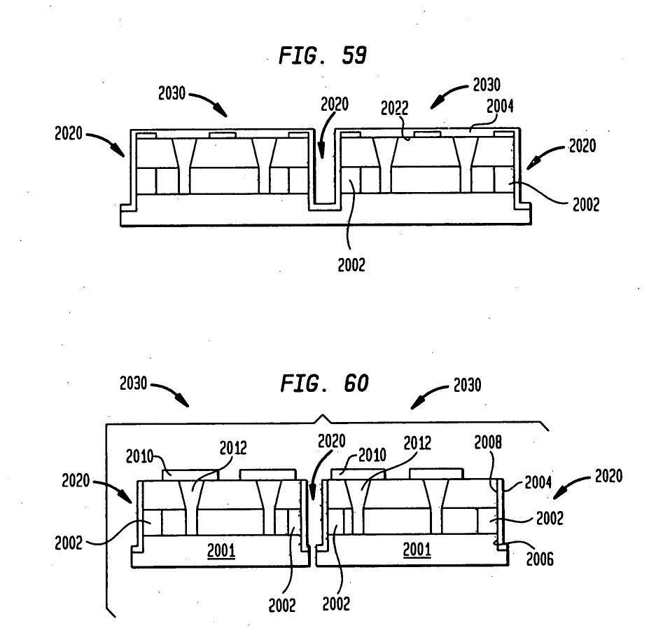

Thereafter, as shown in FIG. 58, the individual units 2030 are partially severed along boundary 2034, which preferably coincides with the dicing lane of the chips, to produce the structure shown. In a further step illustrated in FIG. 59, one or more metals is deposited to produce the structure shown in which both the peripheral edges 2020 and the top surfaces 2022 of the units are covered by metal. The metal is preferably chosen for its qualities in functioning as a barrier to contaminants including moisture, and its ability to conduct electricity. Metals which do not corrode easily are preferred for this purpose. The metal layer 2004 should preferably be selected so as to form a coating which adheres strongly to the surfaces of the unit, as well as adhering to the sealing material 2002 and to provide good conductivity in both a direction across the major surface of the layer and the direction through its thickness. For these reasons, the metal layer 2004 is preferably formed of a stack of deposited metals, such as are used in the semiconductor and MEMs fabrication industries. Common examples of metals which may be used to form such stacks include combinations of titanium, platinum and gold, as well as combinations of chromium, copper and gold, combinations of zinc, nickel and palladium, as well as various permutations and combinations of the above-listed metals. Nickel can be included in the metal layer stack to increase the ability of the patterned metal to provide magnetic screening. The thickness of each patterned metal layer of the stack is illustratively on the order of about 0.1 μm when the metal layer is applied by vapor phase deposition and up to about 1 μm when the metal layer is applied by aqueous processing. A conductive non-metal, for example, a conductive nitride such as titanium nitride or other nitride of a metal, can be utilized as a portion or all of a coating in place of a metal, provided that the material provides a requisite barrier function to moisture or contamination and has sufficient conductivity.

Thereafter, referring again to FIG. 60, steps are performed to remove the resist patterns 2032 together with the unwanted portions of the metal layer, to produce the structure shown as described above. The units 2030 are also severed at this time into individual units along dicing lanes at the boundary 2034 (FIG. 58).

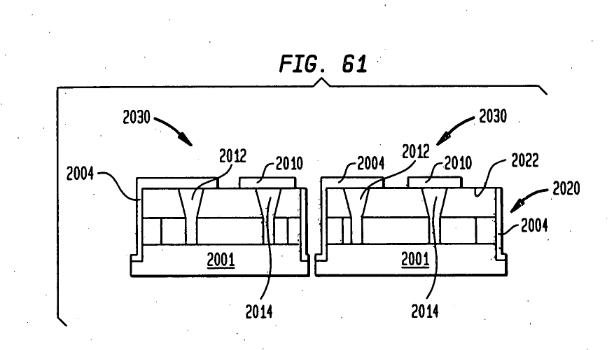

In addition to the foregoing described embodiment shown in FIG. 60, the above-described process can be modified to provide several alternative structures. FIG. 61 illustrates one such alternative structure. As shown therein, an electrical connection can be established between respective ones of the interconnects 2012 and a peripheral metal sealing layer 2004, to maintain the sealing layer and one interconnect of the chip at the same potential, such as to provide a ground contact. Other ones 2014 of the interconnects can connect to contacts 2010 patterned from the metal layer as described above. In such embodiment, the peripheral metal sealing layer 2004 preferably extends over most of the exterior peripheral 2020 and top surfaces 2022 of the unit 2030. In such case, the sealing layer 2004 can be used to provide an electromagnetic shielding function for the unit 2030.

With continued reference to FIG. 61, in a variation of the above embodiment, the metal layer 2004 is patterned to provide conductive traces which extend laterally over the top surface 2022 of the lid. Such conductive trace can be used for redistribution of contacts, e.g., in a manner similar to that described above with reference to FIGS. 4A-B and 7B, to convert, for example, between the pitch and lateral dimensions of the interconnects 2012 of the unit and those of an industry standard and grid array.

In a particular embodiment, the patterned metal layer 2004 can be used for additional functions, such as the provision of conductive elements on the surface 2022 of the unit for use as resistive, inductive or capacitive devices, e.g., for the purpose of providing impedance matching between the device of the chip 2001 and an external network to which the unit is attached in later assembly steps. To form certain ones of such conductive elements, prior to the final step of severing the chips, a dielectric layer can be deposited and patterned to overlie the patterned metal layer 2004, followed by the deposition and patterning of one or more additional patterned metal layers, as described above with reference to FIGS. 57-59.

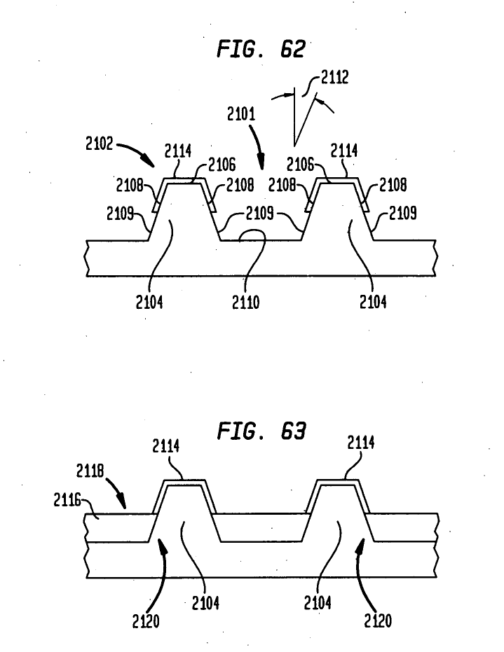

In one of the processes described above with respect to FIGS. 1-3C for forming capped or lidded chips, a metal cap element containing a plurality of insulated through holes is joined to a device wafer containing a plurality of chips and conductive interconnects are formed which extend through the insulated through holes to an outer or “top” surface of the cap element. FIGS. 62 through 66 illustrate a method of fabricating lidded chips in which the lids consist essentially of one or more metals. In this method, an electroformed technique is used to form the lid element which will be joined to the wafer element containing a plurality of chips. Subsequently, conductive interconnects are formed therein, after which lid element and the wafer element are severed to provide individual lidded chips.

FIG. 62 is a sectional view illustrating a mandrel 2102 on which the lid element will be formed. The mandrel, constructed as either a reusable or sacrificial element, is fabricated preferably by photolithographic techniques from a mass of metal or alloy or metal, or mass of doped semiconductor material which is sufficiently conductive to permit electroplating thereon. An initial release layer preferably is provided at a surface of the mandrel, the layer including a metal such as chromium, for example, which tends to release more readily from certain metals. The mandrel preferably has an upper surface having and essentially flat portion 2110 which preferably defines a plane. A plurality of protrusions 2104 extend above the plane of the major surface 2110. The protrusions 2104 have walls including lower portions 2109 extending from the flat portion 2110 of the major surface and upper portions 2108 extending from the lower portions. The protrusions extend in a direction at an angle to the plane defined by the flat portion 2110. The angle 2112 preferably is between about 10 degrees to about a normal angle (90 degrees) to the plane of the flat surface 2110. More preferably, the angle is between about 20 degrees and about 70 degrees with respect to the plane, of the flat portion. A conductive material, e.g., metal or doped semiconductor is exposed at the surface of the flat portion 2110 and lower portions 2109 of the walls of the protrusions. Preferably, a dielectric coating 2114 is provided on the top surfaces 2106 and upper portions 2108 of the walls.

Next, as illustrated in FIG. 63, the mandrel undergoes an electroplating process to form a lid element 2116 thereon having a plurality of through holes therein which correspond to the protrusions of the mandrel. Preferably, the mandrel is tied to a particular electric, potential and immersed in an electroplating bath containing ions of the metal to be plated thereon. At that time, the dielectric coating 2114 prevents the metal from being plated onto the top surface and upper portions of the protrusions. A variety of metals, including aluminum can be used for the plating metal. However, due to specialized procedures and safety equipment required to perform aluminum electroplating, aluminum is not widely used in electroplating processes. More preferably, another metal is electroplated onto the mandrel to form the lid element. Either nickel, copper or both metals can be electroplated onto the mandrel to form the lid having holes which are precisely positioned and have a desirable tapered shape.

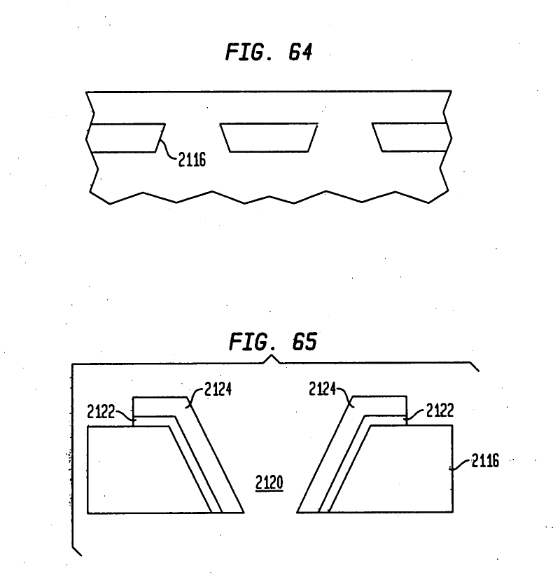

As illustrated in FIG. 63, the lid element 2116 has an essentially planar exposed surface 2118. Because the metal is not electroplated onto the top surfaces and upper wall portions of the protrusions, the lid element has openings 2120 which coincide with the locations of the protrusions. Thereafter, once the lid element has been removed from the mandrel, it appears as illustrated in FIG. 64, the lid element including openings, i.e. through holes 2120 which appear as mirror images of the protrusions 2104 of the mandrel.

Next, processing, is performed to conductively isolate the inner walls of the through holes 2120 in the lid element. Conductive isolation is needed in order to prevent conductive interconnects which extend through the through holes from shorting to the lid element. When the lid element includes or consists essentially of a metal such as aluminum, the metal can be anodized to form an insulating oxide film of sufficient thickness to conductively isolate the through hole. However, when the metal includes or consists essentially of copper or nickel, the growth of the surface oxide thereon is self-limited to a thickness of a few-hundred nanometers at most. That thickness is insufficient to provide adequate robustness of handling and for withstanding subsequent processes. In addition, the thickness of the grown oxide does not provide sufficient protection against dielectric breakdown from high voltages. Another concern is that the conductive interconnects not have excessive capacitance. Thus, a thicker dielectric layer is needed to achieve low feed through capacitance on the inside walls of the through holes.

Thus, in accordance with one embodiment of the invention, a coating of aluminum is applied to the inner walls of the through holes. The aluminum coating supplies a metal at the surface of the lid element which can be anodized to provide an oxide of sufficient thickness to conductively isolate the through holes. In such process, the exposed surfaces of the lid element can be either locally or globally coated with aluminum. By anodizing the aluminum coating, aluminum oxide films can be grown which are about 1 micron in thickness, which is about 300 to 500 times thicker than ambient native oxides that are found on aluminum, nickel or copper. Through anodization, aluminum oxide films can be grown which have “vertical” pores (extending in a direction normal to the surface) having a depth from the surface of up to about 100 microns. For additional protection, preferably the pores in the surface are sealed with a barrier oxide material. An advantage of the aluminum deposition and anodization process is that the total thickness of the original aluminum film need only be sufficient to provide sufficient metal for the anodization process to form the oxide.

FIG. 65 illustrates a portion of a lid element 2116 in which an aluminum coating 2122 has been applied within and immediately surrounding a through hole 2120 therein. As mentioned above, although it is possible to electrolytically plate aluminum onto other metals under certain conditions, it is not preferable to do so. The aluminum coating can be applied by sputtering or, more preferably by vapor deposition into areas exposed by a photo-imageable film, such as, for example, a patterned solder mask, after which the solder mask is preferably removed. Alternatively, the aluminum coating can be blanket deposited onto the lid element, preferably by sputtering or vapor deposition. Then, the surface of the entire aluminum coating can be anodized, or, some surfaces are covered with a protective coating and only other surfaces within the through holes are anodized to form the aluminum oxide dielectric wall coatings 2124 of the through holes.

Another particular advantage of aluminum oxide films is that a color can be imparted to the film as part of the process of anodizing the underlying aluminum metal. Coloring the aluminum oxide film can aid in an operator's ability to identify particular parts, such as lidded chips, which have the colored aluminum oxide film.

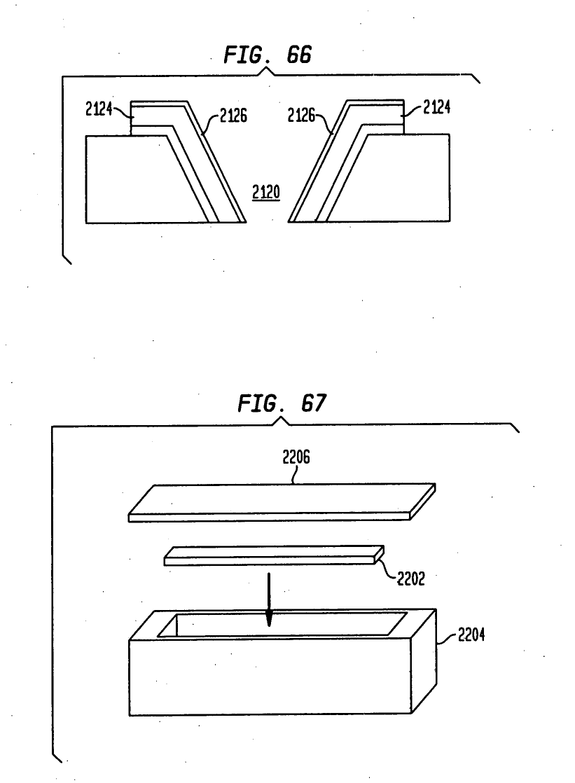

After forming the dielectric wall coatings 2124 within the through holes 2120 of the lid element 2116, preferably, further processing is performed to apply a wettable metal layer 2126 (FIG. 66) to the inner surface of the through holes. It is desirable for a wettable metal layer to exist at exposed surfaces of the through holes as a layer wettable by a fusible conductive material such as solder, tin or a eutectic composition. In such way, when conductive interconnects are formed by the process described above relative to FIGS. 1 through 3C, the fusible conductive material bonds to the wettable metal layer and forms a mechanically robust connection. In addition, in lidded chips which require a degree of hermeticity, the wettable metal layer forms a solid metallic seal with the fusible conductive material disposed thereon.

Particular combinations of metals which can be used to provide a wettable structure on the aluminum oxide walls 2124 include a layered structure of titanium deposited in contact with the aluminum oxide, followed by deposition of platinum and then gold, such as by sputter deposition or “sputtering”. Alternatively, a layered structure can be formed by depositing chromium, followed by copper and then gold, all using vapor deposition. In another process, layers of palladium, nickel, copper and then gold can be applied in succession to the oxide wall coatings 2122 by electroplating. Such wettable metal structure applied to a non-wettable surface is frequently referred to as an “under bump metal.”

As an alternative to depositing and anodizing an aluminum film, an organic dielectric material can be deposited to cover the walls of the through holes. Polymers and other organic materials provide can provide conductive isolation but are generally not as good as oxides of metals as a barrier to the diffusion of water vapor and other gaseous species. Therefore, organic dielectric coatings can be used in lidded chips which house imaging sensors and the like which do not require hermeticity. However, for applications such as SAW devices which do require hermeticity, through holes are best coated with inorganic materials which allow little passage of water vapor and other gaseous species to the device area of the chip.

Advantageously, the herein-described process of forming dielectric walls of aluminum oxide 2124 on inner surfaces of the lid element forms a quality inorganic dielectric layer while avoiding slower, more expensive processes of depositing an inorganic coating directly onto the lid element. The formation of thick non-metallic inorganic films tends to be expensive, because the rate of deposition is invariably slow. As a general rule of thumb, the rate of deposition of a material using a vapor phase process is inversely proportional to the melting point of the material. Non-metallic inorganic materials which have electrically insulating properties predominantly have high melting temperatures.

Among the types of devices which advantageously can be packaged with lids are devices which include magnetoresistive memories including magnetoresistive random access memories known as “MRAMs.” The basic element of such memories is a magnetoresistive (“MR”) storage element. The MR storage element has both a permanently magnetized element and a reversibly magnetized element. When the reversibly magnetized element is magnetized by a current in one direction, the MR storage element is significantly more resistive than when it is not magnetized. MRAMs have a particular constraint in that they require substantial isolation from external magnetic fields. The individual storage elements of the MRAM can be magnetized by fields much weaker than that commonly used to record audio tapes.

Unwanted magnetic fields can be generated under a variety of conditions. Often, magnetic fields are the mere consequence of a current flowing along a conductor. Stronger currents generate stronger magnetic fields. Power supplies, amplifiers and transducers including loudspeakers and microphones of audio equipment and cathode ray tubes of video equipment can generate strong magnetic fields. Shielding is needed to prevent undesired magnetic fields due to nearby currents and other sources of magnetic fields from destroying the data stored in the MRAM.

Therefore, conceptually, an MRAM chip 2202 is best shielded within a magnetically shielded enclosure 2204 (FIG. 67) which encloses the chip from all sides. Once the chip has been positioned within the enclosure as illustrated in FIG. 67, a cover element 2206 incorporating a magnetic shield is attached to the enclosure 2204 overlying the chip 2202 to complete the shielded enclosure.

To be most effective, a magnetically shielded enclosure best includes a material which has high magnetic permeability to provide a low-reluctance path to guide magnetic flux around the exterior of the enclosure. Commonly used magnetic shielding materials, commonly known as “mu-metals,” have permeabilities ranging between about 300 to well over 1 million. Magnetic shielding alloys known as mu-metals include nickel-iron. Examples of mu-metals include the material sold under the name “Permalloy,” and those conforming to one or more of the following standards: HYMU-80, MAG-7904, MIL-N-14411-C and ASTM A753-78. Rapidly solidified cobalt-based alloys achieve high permeabilities, enabling thinner foils of such material to be used as shielding layers.

Shielding should aim to protect the MRAM device against both high frequency and low frequency magnetic fields. At low frequency, the effectiveness of the shield is directly proportional to the thickness of the shield. This results because the reluctance of materials to magnetic flux is inversely proportional to the thickness of the materials. The degree of shielding achieved by a given total thickness of material can be increased by dividing it into two or more concentric shields separated by at least the thickness of the material. In such case, a medium permeability material should be used for one layer and a high permeability material should be used for the other layer of the shield. The lower (medium) permeability layer should be located closest to the field (unwanted) source of the magnetic field. In such case, the medium permeability material acts as a buffer that sufficiently diverts the magnetic field to enable the higher permeability material to attain the required attenuation with respect to the attenuated magnetic field which penetrates the outer lower permeability material.

When magnetic fields having higher frequencies are incident upon the outer surfaces of the shield, an enhanced skin effect mechanism offers greater shielding effectiveness with a thin shielding layer than might be expected. As long as the thickness of the shielding layer is greater than the skin depth calculated from the frequency of the source, effective shielding can be obtained even against pulse-type interference. Attenuation values between 300 dB and 1000 dB can be obtained with such material.

The strategy for shielding the MRAM must not neglect openings in the shielding layer, such as needed to permit passage of electrical signals to and from the MRAM chip. The closer the MRAM chip is to an opening in the shield, the greater the magnitude of magnetic field that can reach the chip. As a rule of thumb, magnetic fields can travel into any opening a distance equal to five times the diameter of that opening. Thus, if a shield is to be placed in close proximity to the MRAC chip, it must contain only few and very small diameter openings. However, if a foil of a magnetically shielding alloy is placed on the front face of a semiconductor die, it must contain openings to allow access to bond pads to facilitate electrical connection to them.

FIG. 68 illustrates a magnetically shielded MRAM chip in accordance with an embodiment of the invention. In the embodiment shown in FIG. 68, a foil 2210 of a magnetic shielding metal alloy is mounted with an adhesive 2211 to overlie a front surface 2212 of an MRAM chip 2202. A similar second foil 2220 is mounted by an adhesive 2221 to a rear surface 2222 of the MRAM chip. When the MRAM chip is relatively thin and the wavelength of the magnetic field is long, i.e., the magnetic field is not at a very high frequency, shielding foils can be omitted from the peripheral edges 2224 of the MRAM chip. The magnetic field is not likely to affect the MRAM chip under such conditions.

A plurality of through holes 2214 in the foil preferably are tapered to become smaller in a direction towards the chip 2202. Walls of the through holes are lined with a dielectric layer 2216 adjacent to the metal shielding alloy, for example, including a polymer and/or glass, over which a wettable metal layer 2218 preferably is provided. As further shown in FIG. 68, a conductive interconnect 2232 can be formed within each through hole by flowing a fusible conductive medium such as solder, tin or eutectic composition into the through holes and onto a bond pad 2234 of the chip. Optionally, a conductive stud bump 2236, e.g., a gold stud bump, can be bonded to the bond pad 2234 prior to flowing the fusible material therein. This will be especially useful if the exposed surface of the bond pad is not wettable by the conductive material, e.g., as when the bond pad has an exposed layer of aluminum.

An advantage of the structure illustrated in FIG. 68 is that the through holes provided through the shielding layer can be made small. As illustrated in FIG. 68, the through holes need only expose a portion of individual bond pads of the MRAM chip. Thus, the main device region 2230 of the chip is protected by the shielding layer except to the extent of the through holes that are spread around the perimeter of the device region. The through holes, similar to those shown and described above in the top-down plan view of FIG. 3D, are small and do not provide a large or continuous opening for magnetic fields to pass.

The above lidded chip structure is well-suited to wafer-scale fabrication processes in which shielding foils are mounted to the front and rear faces of a wafer element containing a plurality of MRAM chips, after which the shielded wafer element is severed along lines of severance to provide the lidded MRAM chip illustrated in FIG. 68. For efficiency, conductive interconnects preferably are formed prior to the wafer element being severed into individual chips.

The embodiment illustrated in FIG. 68 shows only single layer foils 2210 and 2220 overlying each of the front and rear faces of the MRAM chip. However, it will be apparent that a plurality of foils can be mounted in a stacked arrangement overlying each face of the chip. In such way, a multi-layer structure can be achieved which can be used to shield the chip from intense magnetic fields.

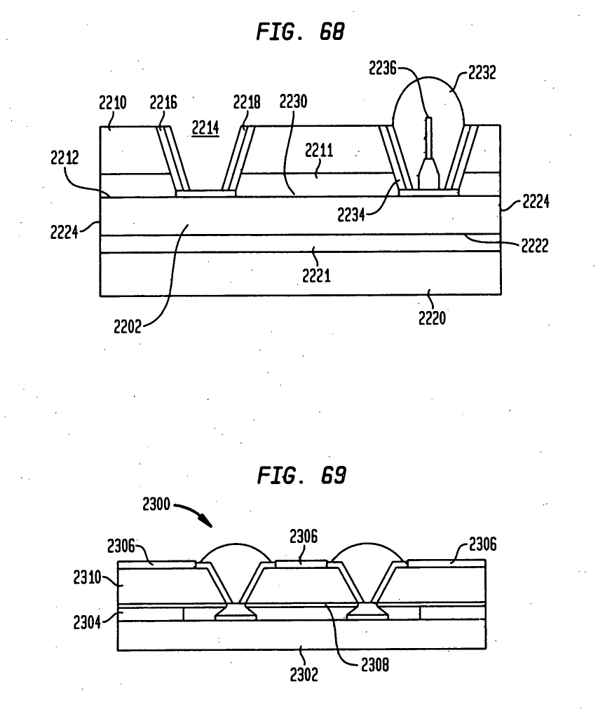

FIG. 69 illustrates a lidded chip 2300 according to another embodiment of the invention in which a transparent or light-transmissive lid 2310 of inorganic material, e.g., glass is mounted above a device region the chip 2302 using an adhesive or sealing medium as described above with reference to FIGS. 1-3C. In addition, the lidded chip includes at least one of a first optical layer 2306 overlying an outer surface of the lid 2310, or a second optical layer 2308 overlying an inner surface of the lid 2310. The first and/or second optical layers include a coating of organic material which has an optical function, or which has an optical function related purpose. For example, the optical function can be to operate as a filter for controlling the wavelengths of light which can pass the lid in directions to and/or from the chip 2302. In other examples, the first or second optical layers or both layers can provide an anti-reflective function, anti-static function, anti-fogging function or anti-scratch function. Such layer can be referred to as “active” coatings because it alters the optical characteristics, as compared to the uncoated lid.

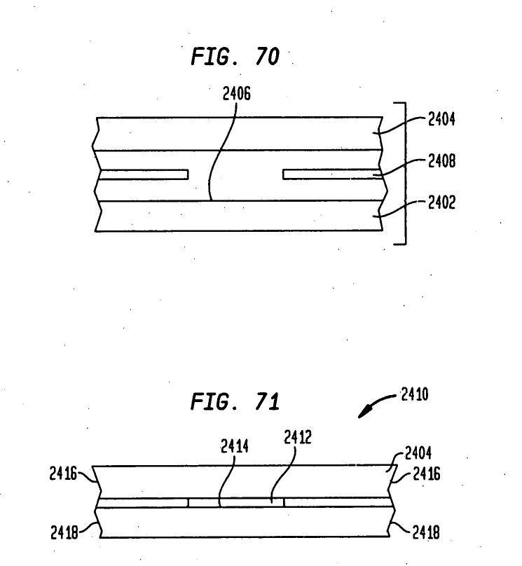

FIGS. 70 through 74 illustrate a method of forming a plurality of lidded chips in accordance with another embodiment of the invention. This embodiment represents a variation of the embodiment described and shown above with reference to FIGS. 3G and 3H. This embodiment is preferably performed to simultaneously fabricate a plurality of lidded chips by processing performed on a scale of a wafer element containing a plurality of chips. Unlike the lid shown in FIG. 3G, fabrication of the lidded chip in this embodiment begins with a lid element which is yet to be patterned with through holes for forming conductive interconnects to the bond pads of the chip. Thus, as shown in FIG. 70; a substantially planar lid element 2404, which preferably lacks holes, is mounted to overlie the front surface 2406 of a wafer element 2402, such as through a sealing medium, e.g., an adhesive 2408. The resulting lidded wafer element 2410, illustrated in FIG. 71, has a lid which covers a void 2412 overlying a device region 2414 of the chip. However, as in the embodiment described above with reference to FIGS. 67-68, it is not always necessary for a void or cavity to be provided between the device region 2414 and the lid 2404. Edges 2416, 2418 of the lid and wafer element depicted in FIG. 71 represent peripheral edges of the lidded chip which result from later processing. Specifically, in later processing the lidded wafer element is severed along lines of severance coinciding with the edges 2416, 2418 shown into an individual lidded chip.

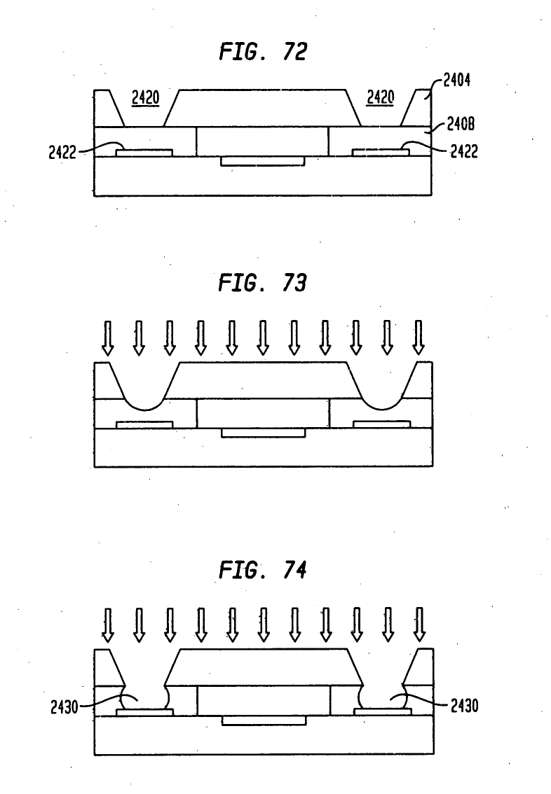

Referring to FIG. 72, prior to the lid element and wafer element being severed into individual chips, through holes 2420 are now formed in the lid element 2404 which overlie individual bond pads 2422 of the chip. The through holes 2420 preferably are formed by machining or drilling of the lid element. In a particular embodiment, the lid element includes a wafer consisting essentially of a glass or other inorganic transparent medium. In such case, the machining or drilling operation preferably is performed ultrasonically. An ultrasonic drilling tool operates with a vibrating head to hammer an abrasive grit into the outer surface 2424 of the lid element to machine it away. The abrasive grit is preferably provided in liquid form such as in slurry to the surface being machined. The hammer can be made to strike the surface thousands or millions of times per second. Thus, ultrasonic drilling can be used to drill holes at a rate of millimeters per second.

The ultrasonic drilling can be used to produce through holes having a tapered profile, as shown in FIG. 72. A rod used as the hammer element in ultrasonic drilling tends to wear in a radial direction as well as in a direction of the length of the rod. Accordingly, the normally worn shape of a rod used in ultrasonic drilling produces through holes having the tapered shape shown in which the holes become smaller in the direction closer to the bond pads 2422 of the chip.

Ultrasonic drilling works best on rigid materials such as glass, which tend not to flex when struck by the ultrasonic, drilling tool. Because of this, ultrasonic drilling stops when the tool head reaches a material having a relatively low modulus of elasticity. Thus, ultrasonic drilling stops when the tool head reaches an adhesive 2408 underlying the through holes in the lid element 2404. These characteristics of ultrasonic drilling are advantageous, because bond pads have very small thickness, typically 0.5 microns or less. Thus, bond pads could easily be destroyed if the ultrasonically drilling head were to contact them while drilling the holes in the lid element.

After forming the holes 2420 in the lid element, one or more various processes can be used to form holes in the adhesive layer 2408 in registration with the holes 2420. For example, plasma ashing and/or a chemical etching process can be used to form holes 2430 in the adhesive and expose the bond pads 2422, as shown in FIGS. 73 and 74. In another embodiment, holes are formed by laser drilling.

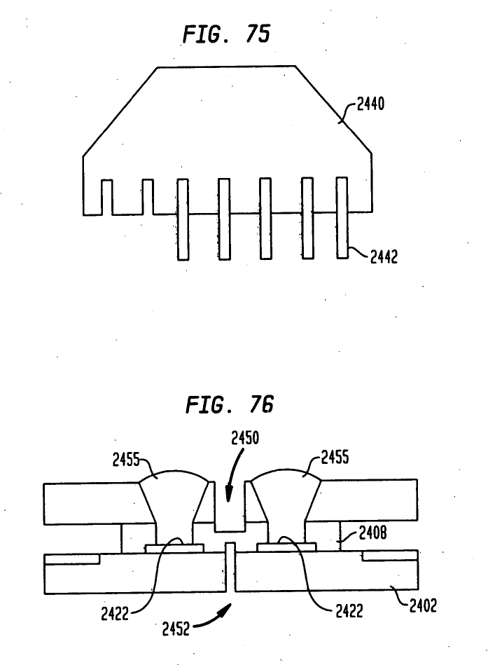

FIG. 75 is an elevational view illustrating an ultrasonic drilling tool head 2440 to which a plurality of metal rods are attached for use in drilling the individual holes in the lid element. As discussed above, the metal rods are removable and detachable hammer elements of the tool head. The rods are used to form individual holes in the lid element. Ultrasonic drilling tools do not normally include removable hammer elements because joints between separate pieces tend not to transmit ultrasonic vibrations well. However, the fine feature size and small depth required for the through holes keeps these from being a limitation in this instance. Thus, in the tool illustrated in FIG. 75, individual metal rods 2442 are removably attached to, e.g., inserted in slots or blind holes within a solid metal element of the tool head. Then, in such instance, when worn, metal rods can be removed from the slots of the tool head and replaced with other new rods. Rod material is readily available as individual metal rods can be cut to length and inserted in the blind holes.

As further illustrated in FIG. 76, another purpose to which ultrasonic machining can be put to use is in severing the lid element into individual lids which overlie the respective chips of the wafer element. In this case, ultrasonic machining using linearly extending hammer can be used to form slots 2450 in the lid element at boundaries between individual lid portions which cover respective chips. As mentioned above, processes in which the lid element and the wafer element are cut by separate blades or separate processes are usually more efficient than processes in which a single blade is used. In one embodiment, the ultrasonic machining process can be performed simultaneously with the above-described process used to drill the through holes in the lid element. In another embodiment, the slot-forming process can be performed using the ultrasonic tool immediately after the through holes are formed. In still another embodiment, the slots are formed later, after the conductive interconnects 2455 have been formed extending upward from the bond pads of the chip.

FIG. 76 further shows the location of the cut 2452 made in the wafer element 2402 by the relatively narrow blade used for cutting that. As also illustrated in FIG. 76, both the process used to machine the slots 2450 and the saw cut 2452 in the wafer element can be effectively stopped in the adhesive layer. Afterwards, the severing operation can be completed by tearing or cutting the remaining adhesive between the lid element and the wafer element with a knife.

It will be appreciated that when the above-described process (FIG. 76) is used to singulate the chips, telltale signs remain that that process was used. These signs are similar to those described above with respect to FIGS. 3T through 3V, with a difference being that the slots in the lid element may show signs of having been ultrasonically machined, rather than having been cut with a saw.

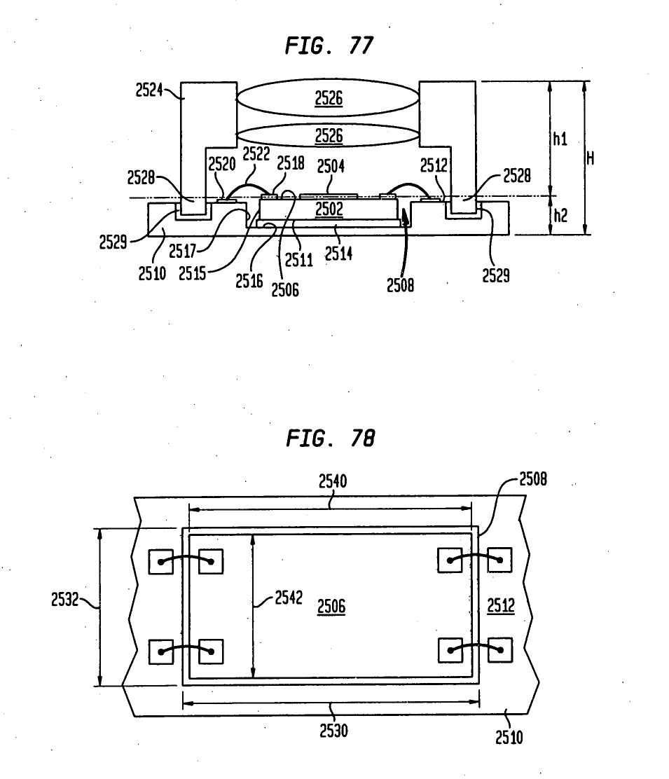

FIG. 77 is a sectional diagram illustrating a structure of a chip-on-board assembly in accordance with another embodiment of the invention. In the assembly illustrated in FIG. 77, a chip 2502 having an optoelectronic device 2504 exposed at a front face 2506 of the chip is mounted within a recess 2508 of a circuit panel 2510, e.g., circuit board, and a turret 2524 is mounted to the circuit board 2510 in alignment with the optoelectronic device 2504. The body of the circuit board 2510 has a major surface 2512 which preferably is essentially smooth and planar. The recess 2508 preferably is a blind cavity which extends inwardly from the major surface into the body of the circuit board, the recess including a recessed surface 2516, which is preferably parallel or substantially parallel to major surface 2512. Walls 2517 extend downwardly from the major surface 2512 to the recessed surface, the walls being either sloped at an angle of less than 90 degrees from the major surface, or more preferably, at a normal angle to the major surface. Preferably, a rear face 2511 of the chip 2502 is mounted to a recessed surface 2516 within the recess via an adhesive such as a die attach adhesive 2514. As shown in the partial top-down plan view of FIG. 78, the lateral dimensions, i.e., the length 2530 and width 2532, of the recess 2508 preferably are sized just slightly larger than the length 2540 and width 2542 of the chip. In this way, the just slightly larger dimensions of the recess align the chip within the recess 2508. Specifically, in such arrangement, the dimensions of the recess align the chip to the turret with respect to both translation and rotation.

In a particular embodiment, the die attach adhesive is disposed wholly below the rear surface 2511 of the chip such that it does not interfere with the placement of the chip within the recess. In another embodiment, at least some portion of the die attach adhesive is disposed between the peripheral edges 2515 of the chip and the walls 2517 of the recess 2508.

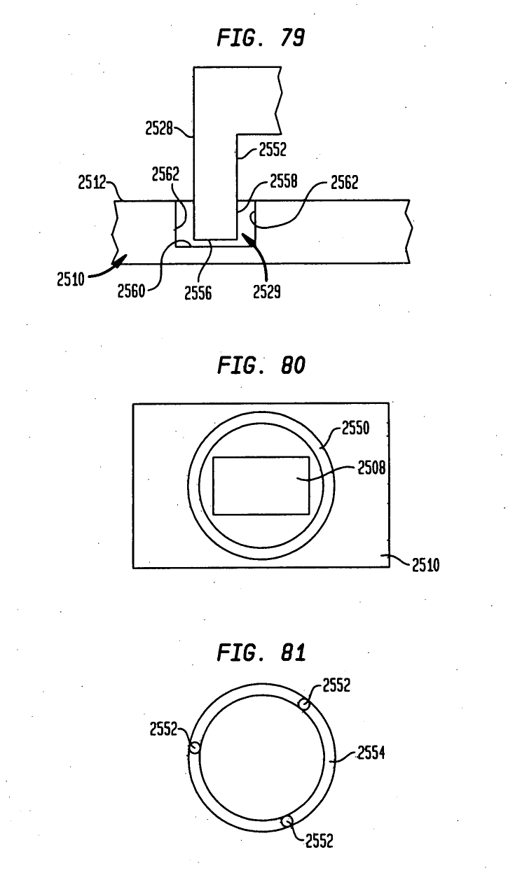

Bond pads 2518 of the chip are conductively connected to terminals 2520 of the circuit board, preferably by bond wires 2522. The turret 2524 mounted above the device 2504 on the chip supports one or more optical elements 2526 such as lenses or other elements in an optical path to and from the optical device 2504. Preferably, one or more members 2528 of the turret are mounted within one or more second recesses 2529 of the circuit board, as shown in FIG. 77, and as best shown in FIG. 79. In one embodiment, as shown in the top-down plan view of FIG. 80, the second recess is in form of an annular ring-like trench 2550 cut into the circuit board 2510, the ring surrounding the first recess 2508. In such case, walls 2552 (FIG. 79) of the turret are mounted within the trench 2550, thereby aligning the turret and the lenses supported thereby to the optical device of the chip with respect to translation and with respect to pitch and roll. Alignment of the height of the lenses above the optical device on the chip can be achieved by way of a typical focusing procedure in which the height of a lens-bearing portion of the turret is moved vertically relative to a fixed portion of the turret. For that purpose, lens turrets are sometimes provided with a lens-bearing portion which can be screwed in or out of a fixed portion of the turret to properly focus the lenses with respect to the chip.

In a variation of the embodiment described above, the members 2528 illustrated in FIGS. 77 and 79 are relatively small post-like protrusions 2552 which protrude from a bottom mounting ring 2554 of the lens turret, as shown in the bottom-up plan view of the turret illustrated in FIG. 81. In such case, the second recesses in the circuit board are blind holes having diameter somewhat larger than the protrusions 2552 of the lens turret. In such case, alignment is achieved by mounting the protrusions of the turret within the second recesses and sealing the mounting ring to the circuit board. In order to assure that the lens plane is parallel to the plane of the optoelectronic device, the individual posts can be moved up or down within the second recesses in the process of aligning the turret to the board. In this way, the mounting of the protrusions within the recesses assist in achieving proper alignment with respect to translation and rotation, e.g., pitch and roll.

Finally, as best seen in FIG. 79, mounting of each member 2528 of the lens turret within a recess places more surfaces of the member in contact with an adhesive 2529. Thus, a bottom surface 2556 is bonded by the adhesive to a bottom surface 2560 of the recess and the exposed wall 2558 or walls of the member are bonded by the adhesive to the inner walls 2562 of the recess. In this way, the adhesive bonds the interior surfaces of the recess to the bottom surface and the walls of the member, providing greater bond strength than if only the bottom surface of the member had been bonded to an external, e.g., major surface 2512 of the circuit board.

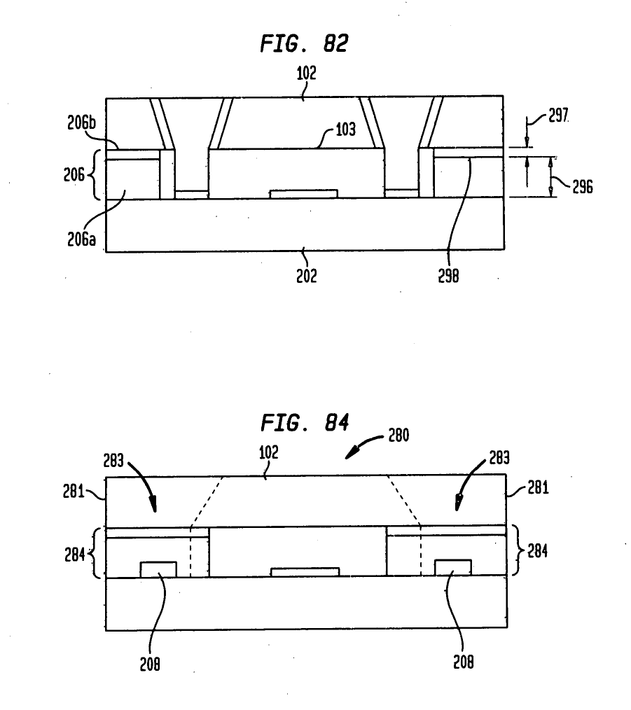

FIG. 82 illustrates a variation of the embodiment of a lidded chip also referred to as a “capped chip” that is described and illustrated above with respect to FIG. 3C. As shown in FIG. 82, in this variation, the sealing medium 206 is a dual structure which includes a first layer 206a adjacent to the front surface of the chip 202 and a second layer 206b disposed between the first layer 206a and the inner surface or lower surface 103 of the cap 102. In one embodiment, the first layer 206a is a relatively thick layer and the second layer 206b is thinner than the first layer. In a particular embodiment, the thickness 296 of the first layer 206a is substantially greater than the thickness 297 of the second layer 206b. Preferably, the thickness 296 of the first layer is about equal to or greater than 1.0 times the thickness 297 of the second layer. An exemplary value for the thickness 297 is about 1 micron (μm). In such embodiment, the first layer 206a can be considered a structure for supporting the cap above the chip and the second layer 206b be used to bond the cap to the supporting structure 206a below.

In one embodiment, the two layers 206a, 206b differ in composition. The first layer 206a can include, for example, a relatively rigid polymeric dielectric material and the second layer 206b include an adhesive material for bonding the first layer 206a to the lower surface 103 of the cap 102. In one example, the first layer 206a is formed by electrophoretic deposition of a dielectric material onto an exposed region of a device wafer which incorporates the chip at the time of forming the layer. An adhesive can then be applied as a second layer 206b onto the first layer 206a for bonding the cap to the first layer. In one example, the adhesive can be applied by a roller coating process onto the exposed surface 298 of the first layer 206a.

In another embodiment, the first layer 206a and the second layer 206b can both include a polymer having the same or similar compositions, but the two layers being processed differently or at different times. For example, the first layer 206a can be formed on the device wafer and then cured, after which the second polymeric layer is applied to the exposed surface of the first layer in an uncured state. Alternatively, the second layer is applied directly to the inner surface of the cap wafer. Thereafter, the device wafer is mounted to the cap wafer with the first and second layers facing the inner surface 103 of the cap wafer under heat and pressure. Preferably, the conditions including heat and pressure at the time are sufficient to cure the second layer.

In another variation of the structure shown in FIG. 82, the first and second layers can include one or more metals. Specifically, the first layer 206a can be formed by depositing and/or plating a metal over an area of the front surface of a device wafer or wafer element that incorporates the chip. For example, the first layer can be formed by a combination of vapor deposition, e.g., sputtering and/or chemical vapor deposition followed by electroplating. Alternatively, the first layer 2406a can be formed by electroless plating followed by electroplating. The second layer 206b can be formed in like manner by deposition and/or plating onto a portion of the inner surface of a cap wafer which includes the cap. After the two layers have been fully formed, metal layers on the respective cap wafer and the device wafer are bonded together by heating and pressing the cap wafer and the device wafer against each other to form an intermetallic bond, e.g., diffusion bond between the two layers.

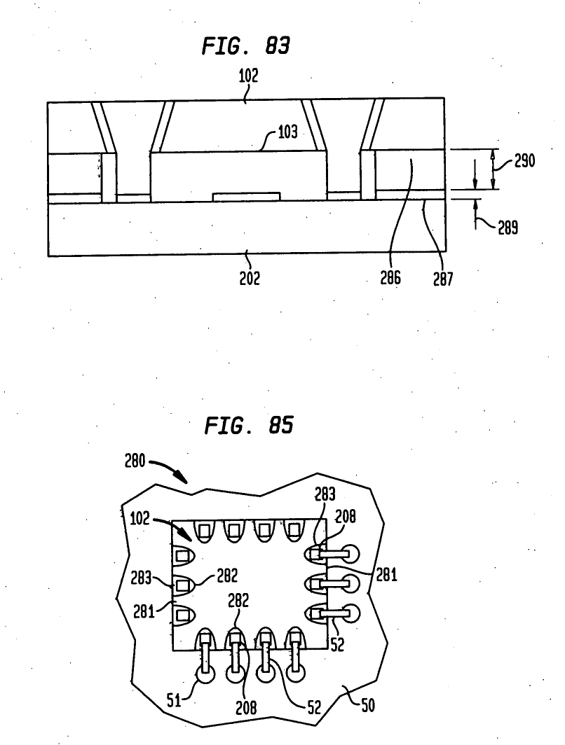

FIG. 83 illustrates another variation of the embodiment shown in FIG. 82. In this variation, the thicker layer 286 is disposed adjacent to the inner surface 103 of the cap 102 and the comparatively thin layer 287 is disposed between the thicker layer and the front surface of the chip 202. Similar to that described above, in one embodiment, the thicker layer 286 can be formed by electrophoretic deposition onto the inner surface 103 of the cap wafer and the thinner layer 287 can be an adhesive layer. In another embodiment, the two layers 286 and 287 can be metallic layers formed by processing similar to that described above relative to FIG. 82. In a particular embodiment, the thicker layer 286 has a thickness 290 of about ten times or more the thickness 289 of the thinner layer 287.

In another embodiment illustrated in FIG. 84, the two layer seal structure 284 is incorporated into an alternative lidded chip structure 280. In this lidded chip structure 280 and as best seen in the plan view of FIG. 85, portions 283 of the lid 102 are recessed back from the peripheral edges 281 of the lid to locations 282 distanced from the peripheral edges. The bond pads 208 are exposed by these open areas of the lid which can be referred to as recesses 283. Similar lidded chip structures are disclosed in commonly owned U.S. patent application Ser. No. 11/322,617 filed Dec. 30, 2005 which is hereby incorporated by reference herein. Within the recesses 283, the bond pads 208 of the chip are exposed to permit contact to be made to the bond pads. Elsewhere, the dual layer structure 284 preferably extends to the peripheral edges 281 of the lid 102 to mechanically support the lid. As further shown in FIG. 85, in a particular embodiment, the exposed bond pads of the lidded chip 280 are conductively connected to terminals 51 of a circuit panel 50 through bond wires 52.

A particular embodiment for fabricating the lidded chip structure is similar to that described in the incorporated U.S. patent application Ser. No. 11/322,617. In such embodiment, the first layer is deposited onto peripheral portions of each chip in a device wafer which incorporates the chip, such that the first layer is formed to overlie the bond pads of the chip. Later, an adhesive is applied as a second layer overlying the first layer and a lid wafer is joined to the device wafer through the adhesive second layer and the first layer. Subsequently, the recesses 283 are formed in the lid wafer by one or more of a variety of processes, e.g., etching, milling, micromachining, ultrasonic machining, laser drilling, etc. Then, portions of the two layer structure are removed within the recesses, e.g., via etching, laser drilling, etc. to expose the bond pads of each chip.

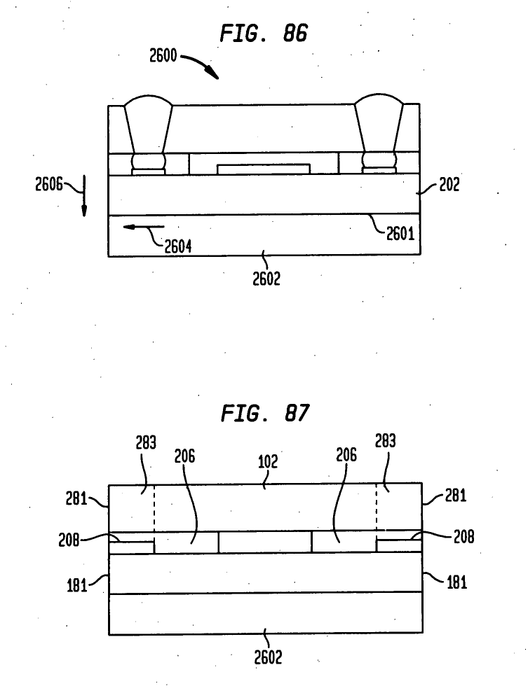

FIG. 86 illustrates a capped chip structure 2600 in accordance with another variation of the above-described embodiments of the invention such as shown in FIG. 3C or FIG. 3E. As depicted in FIG. 86, the capped chip structure 2600 includes an additional thermal layer 2602 overlying the rear face 2601 of the device chip 202. The thermal layer preferably has thermal characteristics which provide good transport of heat in a first direction 2604 parallel to a plane defined by the rear face 2601 of the chip 202, as well as in a second direction 2606 perpendicular to the rear face 2601. In this way, the thermal layer carries and spreads heat uniformly in directions away from the chip 202. In addition, with the thermal layer acting as a heat spreader, heat can be removed from the chip more effectively than without the thermal layer. In addition, the thermal layer can in some cases reduce the effects of non-uniform heating within the chip. In some cases, performance of the chip 202 itself can be improved through the presence of the heat spreader. In particular, improvement in the performance of the chip can be significant when multiple types of devices which dissipate different amounts of heat are incorporated together on one chip. For example, with the presence of the thermal layer it may be possible to significantly improve performance of a chip which includes both an imaging device and a processing device such as a digital signal processor.

The thermal layer preferably consists essentially of one or more thermally conductive metals and/or metallic compounds. An exemplary material for inclusion in the thermal layer is one or more of copper, aluminum, and aluminum nitride. In one embodiment, the thermal layer 2602 is formed by steps including electroless plating of one or more metals onto the rear (device wafer) face of a capped wafer assembly which includes a plurality of capped chips 300 as depicted in FIG. 3C. This process preferably is followed by electroplating a metal onto the electroless plated layer until the thermal layer reaches a desired thickness. In another embodiment, a metal foil having a desired composition such as one or more of the above-enumerated metals or metallic compound is bonded to the rear face of such device wafer, preferably through use of a conductive adhesive. After these plating or bonding steps have been performed, the capped wafer assembly with the thermal layer attached is then severed into individual capped chips.

In addition to spreading heat, it is desirable that the thermal layer provide mechanical support for the chip and for the cap which overlies the chip. For this purpose, it is desirable that the thermal layer be made of a robust material that has good conductivity and low expansivity. Examples are molybdenum, iron-cobalt alloys and various composite materials such as aluminium-silicon carbide and tungsten-copper. The thermal layer should have a thickness greater than 50 microns and preferably greater than 300 microns to provide adequate lateral spreading of heat from a point source and mechanical support to the die.

A capped chip according to variation, of this embodiment is illustrated in FIG. 87. This embodiment is similar to the capped chip 280 shown in FIGS. 84 and 85 in that bond pads 208 of the chip 202 are exposed within recesses 283 of the cap 102. Between the bond pads, peripheral edges 281 of the cap preferably coincide with the edges 181 of the chip. The sealing medium 206 between the cap 102 and the chip 202 can have either a single-layer structure as described above relative to FIGS. 1-3C or a dual layer structure as described with reference to FIG. 84. In this embodiment, the thermal layer 2602 provides additional mechanical support for portions of the chip which include the bond pads 208 and which are exposed within the recesses of the cap.

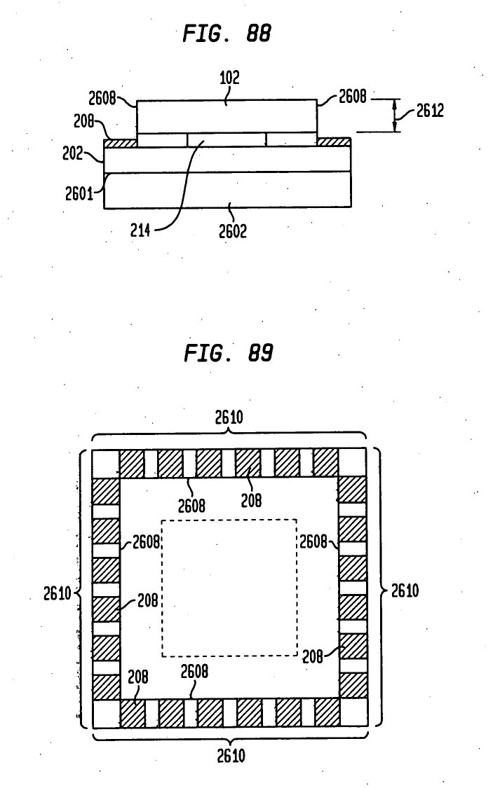

In another variation illustrated in, the sectional view of FIG. 88, with the thermal layer 2602 in place to provide mechanical support to the capped chip from below the rear face 2601 of the chip 202, the peripheral edges 2608 of the cap 102 need not coincide with the peripheral edges 181 of the chip. Instead, the edges 2608 of the cap are sufficiently set back to expose whole rows 2610 of bond pads 208. The additional mechanical support provided by the thermal layer reduces the tendency of the chip 202 to be chipped or cracked by handling during fabrication and processes to conductively interconnect the capped chip to other, elements. By removing portions of the cap 102 sufficiently to expose entire rows 2610 of bond pads, the bond pads can be placed at tighter pitches within each row.

In addition to the advantages that the thermal layer can provide in terms of mechanical support, the thermal layer may also include materials which provide superior performance during the process of singulating a capped wafer assembly into individual capped chips. For example, the particular material properties of the thermal layer may allow the capped wafer assembly to be diced (sawn) into individual capped chips at a higher speed than if the thermal layer were not present. In addition, in a particular embodiment, the mechanical properties of the thermal layer may allow the width of the dicing lanes to be reduced in relation to the width of such dicing lanes in capped wafers which do not include such thermal layer.

Another advantage that may be achieved in capped chips which include the thermal layer is to permit the thickness 2612 of the cap to be reduced. In such case, the additional mechanical support provided to the chip by the thermal layer makes up for the reduced mechanical support provided by a thinner cap.

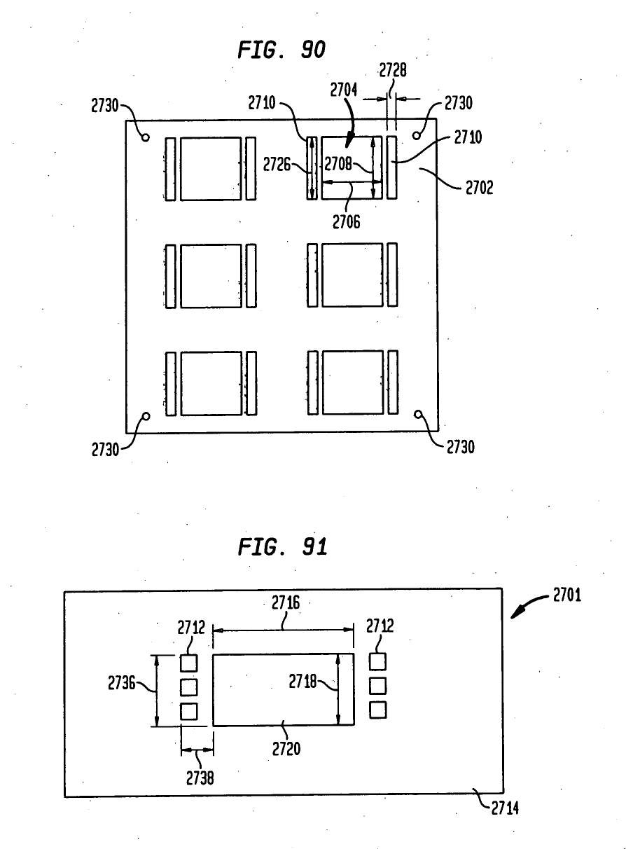

A method of fabricating a module including a set of vertically stacked packaged microelectronic elements will now be described with reference to FIGS. 90 through 93. In this method, removable, e.g., disposable or soluble cutout sheets are used to align a set of packaged microelectronic elements together. Once aligned by the cutout sheets, the contacts of the packaged chip are conductively connected together, such as by reflowing solder bumps which are disposed between each of the packages. After forming these interconnections, the cutout sheets are then removed, for example, as by washing the resulting interconnected assembly in a solvent which dissolves the cutout sheets.

Referring to FIG. 90, in one embodiment, a cutout sheet 2702 is shown in plan view. The cutout sheet consists essentially of one or more materials which are soluble by a solvent or class of solvents that does not harm the packaged microelectronic elements. Specifically, the cutout sheet can consist essentially of paper or other soluble material which is soluble by solvents which do not dissolve or attack chips and interconnection elements, e.g., patterned wiring containing elements to which the chips are interconnected in packages. The cutout sheet 2702 includes at least one chip opening, and each such chip opening has dimensions including length 2706 and width 2708, which are just slightly larger than the length 2716 and width 2718 of a chip 2720 (FIG. 91) that is to be interconnected within the vertically stacked package. In addition to the chip opening, the cutout sheet contains one or more contact openings 2710 which have length 2726 and width 2728 sufficient to accommodate the length 2726 and width 2728 of one or more rows or one or more columns of contacts 2712 of a package element 2714 to which the chip is interconnected as a packaged chip 2701. In the particular embodiment illustrated in FIG. 90, the cutout sheet includes six chip openings 2704 and sets of contact openings 2710 corresponding to each of the chip openings. In such case, the cutout sheet illustrated in FIG. 90 is capable of aligning up to six packaged chips simultaneously within up to six separate vertically stacked packages.

In addition to the chip openings and contact openings, the cutout sheet also includes a set of openings 2730 sized for aligning the cutout sheet within a fixture. In particular, the openings 2730 illustrated in FIG. 90 are sized to accommodate a set of pins which rise in a vertical direction, the direction perpendicular to the plane defined by the area of the cutout sheet.

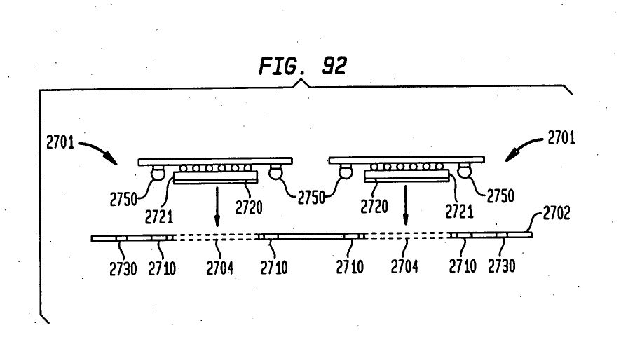

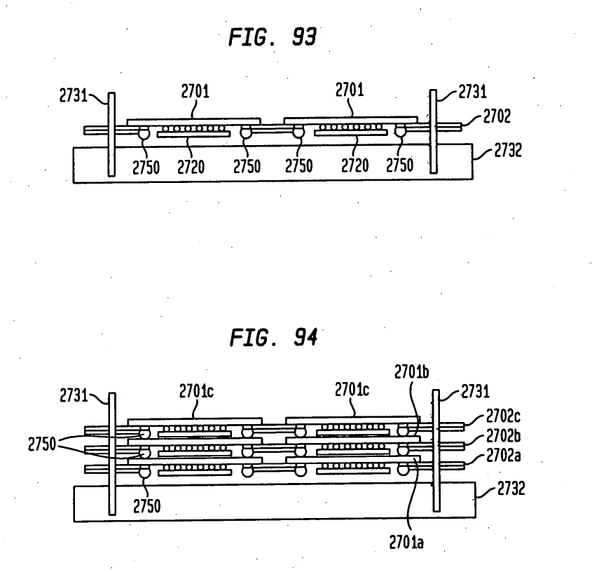

FIG. 92 is a sectional view illustrating an alignment procedure by which packaged chips 2701 are aligned to a cutout sheet 2702. As illustrated therein, chips 2720 are mounted to interconnection elements 2714 as packaged chips 2701. The alignment procedure aligns the outer edges 2721 of the chips 2720 within the chip openings 2704 of the cutout sheet. Specifically, as illustrated in FIG. 93, a cutout sheet 2702 preferably is first aligned to a fixture 2732 by inserting pins 2731 through the alignment openings 2730 of the cutout sheet. Thereafter, the packaged chips 2701 are aligned to the cutout sheet 2702 and the chips 2720 therein inserted within the chip openings of the cutout sheet. During this process, interconnect features 2750 such as conductive bumps, conductive posts or pins, etc. attached to the packaged chips are inserted within the contact openings provided in the cutout sheet once these operations have been performed, the packaged chips 2701 are fully aligned to a fixed frame of reference defined by the fixture 2732 and the pins 2731 attached thereto. In addition, the interconnect features 2750 extend through the contact openings.

FIG. 94 illustrates the results of further steps taken to fabricate vertically stacked packages using the above-described alignment procedure. In this case, a second cutout sheet 2702b is inserted onto the pins 2731 to align the second cutout sheet to the fixture 2732. Additional packaged chips 2701b are then aligned to the cutout sheet 2702b with the chips thereon inserted within the chip openings of the cutout sheet 2702b, using the procedure described above with respect to FIGS. 92-93. These steps are then repeated again another time to align further packaged chips 2701c within another cutout sheet 2702c which overlies cutout sheet 2702b.

After aligning chips in this manner to the stacked cutout sheets held by the fixture, a reflow process is used to reflow fusible material included within the interconnect features 2750 to conductively join a packaged chip 2701a at a lowest position of the fixture to a packaged chip 2701b which lies above the packaged chip 2701a. Simultaneously, a packaged chip 2701c is conductively joined to the packaged chip 2701b which lies below it. In such manner vertically interconnected stacked assemblies are formed by this process, each including a vertical stack having a plurality of packaged chips.

After joining and interconnecting the chips together by such reflow process, the cutout sheets are now removed, as they are no longer needed. In a particular embodiment, the cutout sheets are removed by washing, which may involve chemical processing such as dissolving in a solvent, or mechanical processing such as tearing and abrasion or a combination of chemical and mechanical processing.

As described above, optical image sensors are particularly sensitive to contamination by particles such as dust. Many of the particular capped chip and lidded chip structures described herein are suited to provide protection against to duct to chips which include optoelectronic devices such as optical image sensors. In addition, protection against dust contamination can also be provided by enclosing the chip within a chip-on-board (“COB”) structure, such as that described with reference to FIG. 77 above. When a chip includes both optoelectronic devices such as image sensors for example, and transistor-based circuitry such as complementary metal oxide semiconductor (“CMOS”) circuitry both types of circuitry are usually fabricated by similar processes. Specifically, characteristics of p-n junctions and transistors within the CMOS circuitry can be similar to those included in the optoelectronic devices. For that reason, operation of the CMOS circuitry tends to be influenced by wavelengths of light to which the optoelectronic devices are designed to respond. An effort is required to protect the CMOS circuitry from malfunctioning due to light which strikes the circuitry. One way to address the problem would be to add additional circuitry to prevent, detect, or correct malfunctions in the CMOS circuitry which occur due to stray light falling on the circuitry. However, significant design effort and cost could be required to do so, which may require testing of completed hardware and redesign in order to reach an acceptable solution.

Another way to address this problem is provided in accordance with the embodiment of the invention illustrated in FIG. 95. In this embodiment, certain portions 2806 of a chip 2802 which includes an optoelectronic device 2804 such as an optical image sensor are covered by a film 2803 designed to prevent light having a certain range of wavelengths from striking the surface of the chip. Under such film 2803, harmful, potentially malfunction-causing light is impeded from striking those portions 2806 of the chip. With such film, other circuitry of the chip such as circuit portions 2808, 2810 that do not require light to operate are protected from the effects of such light by the film. In one example, the film overlies all areas of the chip except for the optoelectronic device or image sensor and except for conductive contacts 2812 exposed at a face of the chip.

Such chip 2802 having the film 2803 thereon can be incorporated into a COB structure such as, for example, that shown and described above with reference to FIG. 77, in which a turret included lenses protect the image sensor from contamination such as from dust. Alternatively, the chip 2802 can be incorporated in a conventional COB structure.

Characteristics of the film 2803 are such that light which may cause the circuitry within circuit portions 2808, 2810 to malfunction is prevented from reaching that circuitry. The film can have properties resulting in absorption, reflection or refraction of the light that strikes the film from above the surface of the chip. In such manner, the film preferably results in the light that reaches the chip being severely attenuated relative to the light that would have originally struck the circuitry if the film had not been present. These characteristics make the film overlying portions 2808, 2810 of the chip act as effectively “opaque” to light traveling in a direction towards those portions.

Desirably, the image sensor of the chip is coated with a material that acts as a bandpass filter for wavelengths of interest to the image sensor. In a particular embodiment, the film 2803 disposed over other portions 2808, 2810 of the chip acts as a band-stop filter for at least a portion, if not all of the same wavelengths of interest. In this way, light is allowed to reach the image sensor 2804 and in the process stray light which reaches the film 2803 overlying those other portions 2808, 281.0 of the chip does not reach those portions 2808, 2810. Preferably, the film is formed directly on the chip by depositing a material onto the chip. In another example, the film can be formed separately from the chip and then laminated to the front surface of the chip, if the process can be performed to sufficient cleanroom standards to avoid contaminating the chip.

Alternatively, a similar band-stop result can be achieved when the film 2803 is selected to have high pass filter characteristics and when one or more lenses in the optical path to the chip have a low pass filter characteristic. Typically, lenses made of polymeric material have a relatively sharp cut-off in transmissivity at a wavelength of about 400 nanometers (nm). Therefore, a bandstop function is achieved when the chip is coated with a film 2803 having a high pass characteristic with passband above a wavelength L₁ and the chip is mounted in a COB structure in which optical elements ahead of the chip have a low pass characteristic with a passband below wavelength L₁.

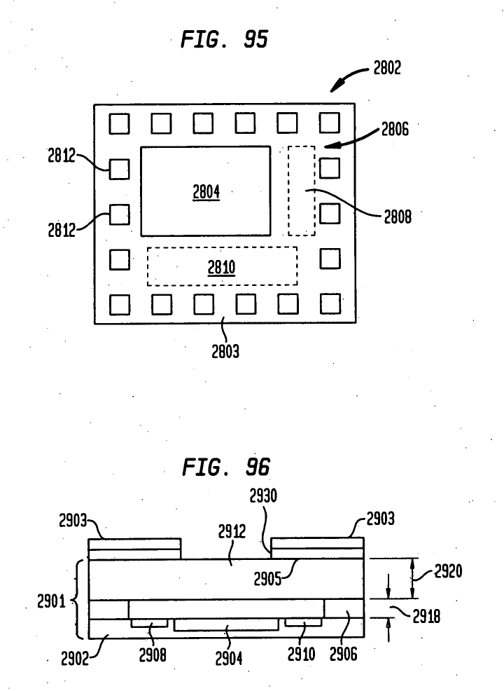

In another embodiment illustrated in FIG. 96, a chip 2902 which includes an image sensor 2904 is packaged in a unit 2901 which includes an optically transmissive lid 2912 overlying a front face of the chip. Such lid is also referred to variously as a “cover” or “cap” herein. Unit 2901 can be any of various units having a lid, cover or cap overlying a front surface of the chip, for example, as described in particular embodiments of the invention herein or as described elsewhere. Circuit portions 2908, 2910 of the chip include circuitry which is subject to malfunction in the presence of wavelengths of interest to the image sensor. To reduce an amount of unwanted light from striking those portions 2908, 2910 of the chip, a film 2903 is disposed on an outer face of the lid 2912. Placement of such film should be made in consideration of its effect upon the light striking the image sensor. At a distance from the image sensor determined by the thickness 2920 of the sealing medium 2906 and the thickness 2918 of the lid, the film 2903 does not block any particular pixels of the image sensor from receiving light. However, at such distance, it might occur that the film casts a penumbric shadow that diminishes the light which reaches a portion of the image sensor. Software correction and/or particular attention to the placement of the film relative to the image sensor can be used to correct for such shadowing effect.

In one embodiment, film 2903 has characteristics which cause it to absorb light at wavelengths of interest to the image sensor. For example, a film 2903 having an opaque black appearance satisfies this criterion when the image sensor is sensitive to wavelengths within a range visible to the human eye. The black film 2903 can be mounted to an outer face 2905, e.g., “front face” of the lid by an adhesive layer 2916. A unit 2901 with such film 2903 attached thereto can be mounted to receive focused light through lenses (not shown) mounted above the unit. An absorptive film is preferable over a reflective, e.g., “mirror-like” film in this instance because it helps prevent light from reflecting off the film, striking a face of a lens above the unit and then being reflected again back onto the image sensor, giving rise to glare and other unwanted image effects.

In a particular embodiment, the lid can include or consist essentially of a material such as glass. Since glass typically is transmissive to light over a somewhat broad range of wavelengths, the absorptive film 2903 acts as a bandstop for light at the wavelengths of interest which could affect circuitry within portions 2908, 2910.

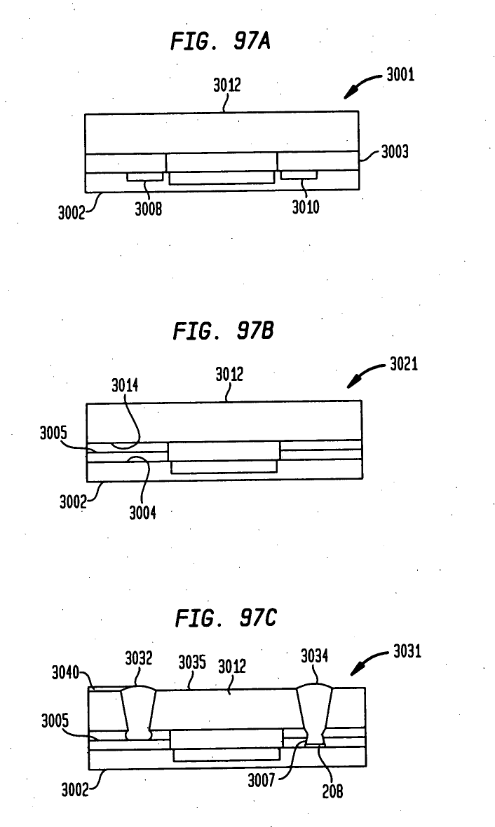

FIG. 97A illustrates a unit 3001 in accordance with a variation of the embodiment described above with respect to FIG. 96. In such unit, an adhesive 3003 or other sealing material disposed between the chip 3002 and the lid 3012 has characteristics which cause it to absorb light at the wavelengths of interest. In such embodiment, light transmission towards unit 3001 through the lid 3012 is intercepted when it reaches the sealing material 3003 disposed between the lid and circuit portions 3008, 301.0 which need protection from the light. Sealing materials including adhesives are available which have light absorbing characteristics. For this purpose, the sealing material can include a filled adhesive, i.e., one which includes light-absorbing particles. Such particles can include metal particles which can be used to improve thermal characteristics and/or electrical characteristics (e.g., provide electromagnetic shielding). Alternatively or in addition thereto, the particles can include ceramic particles which control thermal expansivity and can also increase thermal conductivity. Preferably, the filler includes a material that absorbs light over a wide portion of the spectrum including the wavelengths of interest such that it has a truly black appearance. Such materials are known, such as those used to apply coatings on the surfaces of solar water heating panels, for example.

In a variation of this embodiment (FIG. 97B), the film 3003 disposed between the lid 3012 and the chip 3002 is designed to reflect light rather than to absorb it. For example, a metal foil 3005 can be incorporated into the unit 3021, as a layer disposed between the front face 3004 of the chip 3002 and the inner face 3014 of the lid 3012, e.g., as “bisecting” an adhesive film 3003. Reflecting the light has an advantage in that it tends not to heat the chip 3002 in a way that an absorptive layer adjacent to the chip 3002 does. When a reflective layer is used, provision should be made for managing possible secondary reflected light within a camera module including the unit from impinging upon the image sensor after reflecting off the film.

In a unit 3031 according to a further variation of the above embodiment (FIG. 97C), a metallic layer 3005, being for example, a metal foil, metallic mesh or grid of wires is incorporated into the adhesive. Such metallic layer provides electromagnetic shielding for the chip 3002 as well as operating as a ground plane for the unit 3031. For example, the unit 3031 illustrated in FIG. 97C includes two types of conductive interconnects 3032, 3034 which can be formed in accordance with any of the processes described in this specification, including the process described above with reference to FIGS. 1 through 3C. One of the conductive interconnects 3034 is similar to that described above in relation to FIGS. 1 through 3C in that a conductive material occupies a volume extending from a bond pad 208 of the chip through a through hole in the lid 3012 and is exposed at the outer surface 3035 of the lid. This interconnect extends through an opening 3007 in the metal foil 3005 and does not contact the metallic layer, such that the interconnect 3034 and the metallic layer 3005 can be at different potentials.

A second conductive interconnect 3032 extends from the metallic layer through a second through hole of the lid, this second interconnect being used to connect features at an exterior of the unit to the ground plane provided by the metallic layer 3005. For example, features of a circuit panel to which the unit 3031 is connected or a trace 3040 disposed at the outer surface of the unit 3031 can be interconnected to the ground plane through the interconnect structure 3032.

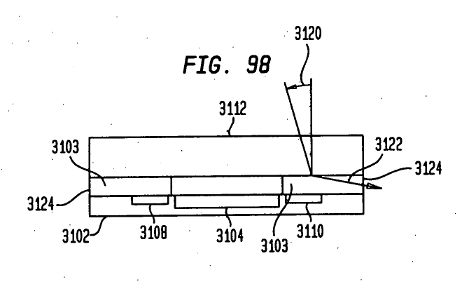

FIG. 98 illustrates a unit 3101 according to another variation of the embodiment illustrated in FIG. 97. In this instance, the sealing material disposed 3103 disposed between the lid 3112 and the chip 3102 is designed to refract light away from the circuit portions 3108, 3110 of the chip. Refraction redirects the light away from the unit entirely in a way that neither contributes to additional heating of the chip while reducing the possibility that the redirected light will be reflected back onto the image sensor 3104. Light refracts at an interface between two media when the light strikes the interface at an angle 3120 to a normal angle and the indexes of refraction of the two media are different. In this case, by selecting the materials of the lid 3112 and the sealing material 3103 to have substantially different indexes of refraction, light refracts at the interface 3122 causing it to be re-directed beyond edges 3124 of the unit. Examples of a sealing material structure 3103 designed to produce sufficient refraction include a multi-layer structure in which layers have different refractive indexes. In another example, the sealing material structure can include a single material layer which has a graded index.

In a particular embodiment, the effects similar to refraction are produced through use of physical structures incorporated in the sealing material. For example, micro-prisms can be incorporated into the sealing material, such micro-prisms reflecting light at angle controlled by the number of faces of the prism that the light beam reflects off of before exiting the prism. Alternatively, such microprism structures can be formed on one or both faces of the lid by etching, stamping or other similar methods.

In another alternative method, a set of polarizing filters are used to restrict the transmission of light onto the portions of the circuit which are sensitive. Such polarizing filters can be incorporated into the sealing material layer or, alternatively, attached to faces of the lid. When a polarizing filter having one polarization, i.e., top-bottom is used in combination with another polarizing filter having a different polarization, i.e., left-right, for example, the light that exits from the first polarizing filter is blocked from exiting the second polarizing filter such that substantially no light exits the second polarizing filter. In such case, an effect similar to an absorptive filter occurs even though neither filter has 100% opacity.

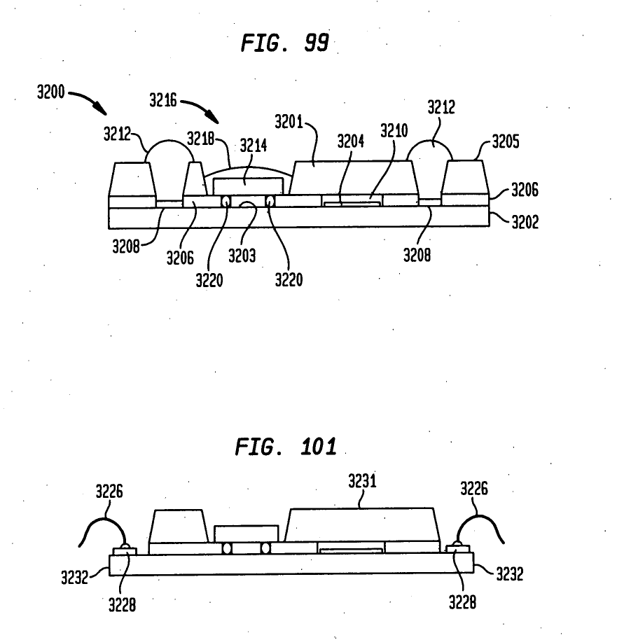

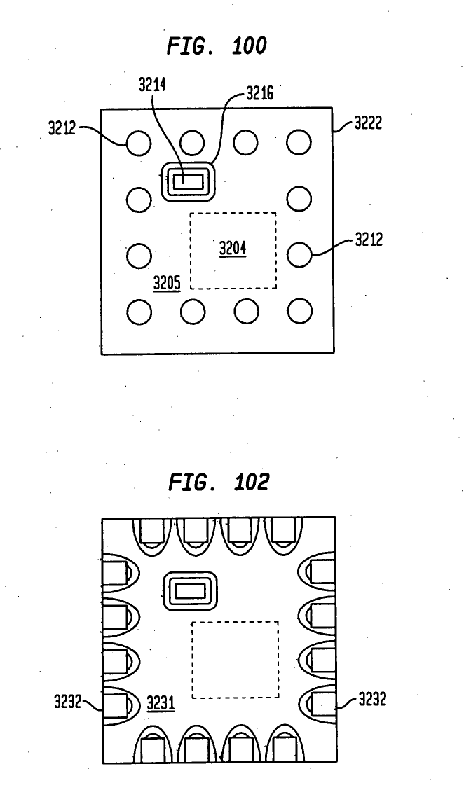

A lidded unit 3200 according, to another embodiment of the invention will now be described with reference to FIGS. 99 and 100. FIG. 99 is a sectional view of the lidded unit and FIG. 100 is a corresponding plan view looking downward onto the lidded unit from a point above the outer surface 3205 of the unit.

In this embodiment, the lidded unit 3200 includes a mother chip 3202 which has a device region 3204 at a front face 3203 of the chip. As in the embodiment described above with reference to FIG. 3C, the device region 3204 is covered by a lid 3201 mounted thereto through a medium 3206 to protect it from dust, moisture or other exposure. In a particular embodiment, the device region includes an optoelectronic device, e.g., image sensor, and the lid is composed of one or more materials which are transparent to wavelengths of interest to operation of the optoelectronic device. Alternatively, the lid 3201 may enclose a cavity 3210 necessary to protection of the device region or to its operation, such as when the device region includes a micro-electromechanical device such as a surface acoustic wave (“SAW”) device. Conductive interconnects 3212 extend upward from bond pads of the chip 3202 through through holes in the lid to permit conductive interconnection to elements external to the lidded unit 3200.

As illustrated in FIG. 99, lidded unit 3200 also includes a daughter microelectronic element 3214 such as an active device chip, a passive chip or other microelectronic element such as a discrete active or passive microelectronic element. For example, a passive element can be included such as an inductor, resistor or capacitor, such as may be used in close connection to a mother chip which includes radio frequency circuitry. In another example, the daughter chip can include a different type of circuitry from that of the mother chip, such as when the circuitry included on the daughter chip cannot be manufactured by the same process as the mother chip. Specifically, the daughter chip may include a memory chip for mounting to a mother chip which includes an image sensor for a camera. In another example, the daughter chip can include a digital signal processor (“DSP”) which is mounted to a mother chip which includes an image sensor for a camera.

The daughter microelectronic element 3214 is mounted to the mother chip 3202 within an opening 3216 in the lid 3201. Thus, although lid 3201 covers a particular device region 3204 at the front face 3203 of the mother chip, it does not hinder the mounting of a second microelectronic element, e.g., chip, to the front face 3203 of the chip. In the particular embodiment illustrated in FIG. 99, bumps 3220, e.g., solder bumps or other interconnect structures such as stud bumps, leads, posts, bond wires, anisotropic conductive polymer films or isotropic conductive polymer films, among others provide conductive interconnection between the daughter chip 3214 and the mother chip 3202. These structures interconnecting the daughter chip to the mother chip may be surrounded by the sealing medium 3206, e.g., adhesive disposed between the daughter chip and the mother chip. Alternatively, the sealing medium may not be present between the opposed faces of the mother and daughter chips. Optionally, an encapsulant 3218 covers the daughter chip within the opening 3216.

In the particular embodiment illustrated in FIG. 100, the daughter chip 3214 is joined to the mother chip at a location between the device region 3204 and the conductive interconnects 3212. However, the daughter chip need not be mounted only as shown in FIG. 100. For example, in a variation (not shown) of the embodiment illustrated in FIG. 100, the daughter chip is mounted to the mother chip at a location between the conductive interconnects and an edge 3222 of the chip.

In a variation of the embodiment illustration in FIGS. 99 and 100, the lid 3231 (FIGS. 101, 102) is recessed from edges 3232 of the chip 3202, similar to that shown and described above with reference to FIGS. 84 through 89. In such way, conductive interconnection to the chip can be provided through bond wires 3226 attached to bond pads 3228 of the chip.

In a further variation of the embodiment described above with reference to FIGS. 99 and 100, the lid 3241 (FIG. 103) includes a cavity 3236 provided in the inner surface 3233. The cavity 3236 is sufficiently large to accommodate the dimensions of the daughter chip such that the lid 3241 overlies the daughter chip 3214 as well. FIG. 104 illustrates a variation of the foregoing embodiment similar to that shown in FIGS. 101, 102 in which bond pads 3228 are exposed for interconnection through bond wires.

FIG. 105 illustrates another variation of the above embodiment, similar to that shown in FIGS. 99 and 100. In this case, conductive interconnection between the mother chip 3202′ and the daughter chip 3214 is provided through conductive traces disposed within the sealing medium 3206. In particular, conductive traces 3250, 3252 can be provided between a lower layer 3242 and an upper layer 3244 of an adhesive used to join the mother chip 3202 to the lid 3201. The traces within the sealing medium can have different interconnect functions. For example, trace 3252 conductively connects the daughter chip 3214 to a bond pad 3254 on the front face 3203 of the mother chip 3202. On the other hand, trace 3250 conductively connects the daughter chip 3214 to an interconnect feature 3246 exposed at an outer surface 3205 of the lid 3201.

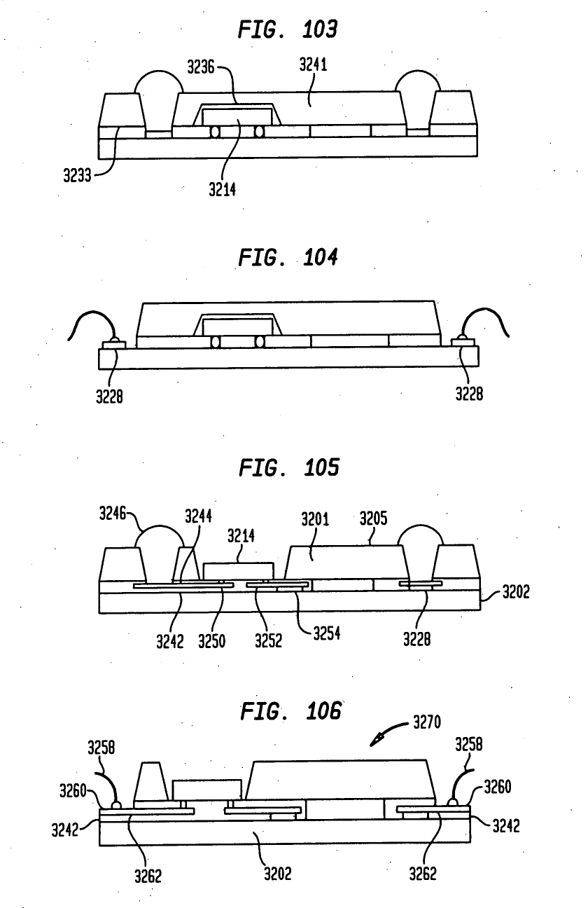

FIG. 106 illustrates a variation of the embodiment illustrated in FIG. 105 in which external interconnection to the mother chip 3202 is provided through bond wires 3258 that are attached to contacts 3260 of the lidded chip structure 3270. In this embodiment, the contacts 3260 are provided as features of a metal layer which are formed integrally with traces 3262, the contacts and features overlying a lower adhesive layer 3242 attached to the mother chip 3202.

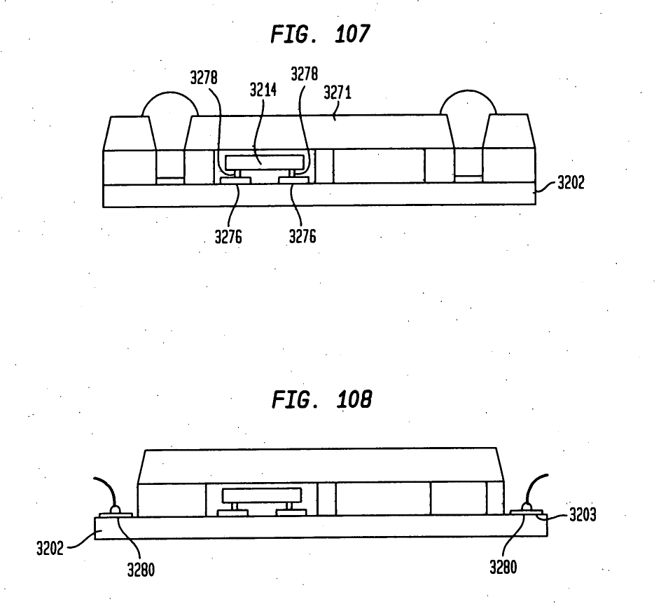

FIG. 107 illustrates a further variation of the embodiment described above with respect to FIGS. 99 and 100 in which the lid 3271 is mounted at a height above the mother chip 3202 sufficient to accommodate the daughter chip 3214 between the lid and the mother chip. Here, the inner surface 3273 of the lid 3271 is spaced from the front face 3203 of the mother chip sufficiently to accommodate the vertical thickness of the chip as well as the height of interconnect structures between the mother and daughter chips, including bond pads 3276 and mounting structures 3278 on the daughter chip. In this case, the sealing medium can include a single layer, or have a dual or multiple layer structure as described above with reference to FIGS. 84 through 89.

FIG. 108 illustrates a variation of the embodiment shown in FIG. 107, in which conductive interconnection to the mother chip is provided through bond pads 3280 which are exposed at the front face 3203 of the mother chip 3202.

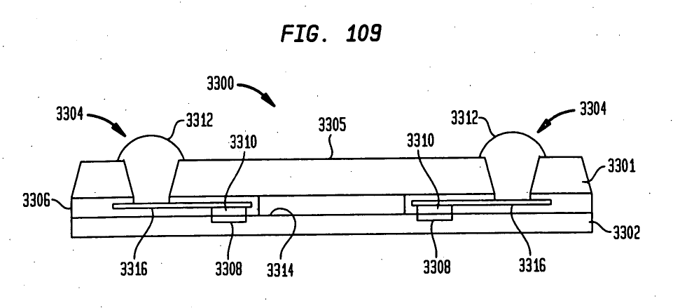

A lidded chip structure according to another embodiment of the invention will now be described with reference to FIGS. 109, 110 and 111. Referring to FIG. 109, in this embodiment, similar to that described above with reference to FIG. 3C, external interconnection to a chip 3302 is provided by way of conductive interconnects 3312 which extend through through holes in a lid which overlies a front surface 3314 of the chip. However, the conductive interconnects do not rise vertically and directly from bond pads 3308 of the chip. Instead, conductive traces 3316 embedded in an adhesive or sealing material layer 3306 extend laterally from the bond pads 3308 as connected thereto by an interconnect metal 3310 disposed thereon.

The interconnection arrangement illustrated in FIG. 109 enables the conductive interconnects at the outer surface 3305 of the lid to be arranged differently from the bond pads disposed at the front surface 3314 of the chip. In addition, the provision of conductive traces within an adhesive layer 3306 between the chip and the lid enables the conductive traces 3316 to be routed over conductive features of the chip, e.g., other bond pads without the traces electrically contacting them. Thus, the arrangement illustrated in FIG. 109 can be advantageously used to redistribute the external interconnects 3304 of the lidded chip structure 3300 in relation to the bond pads 3308 of the chip.

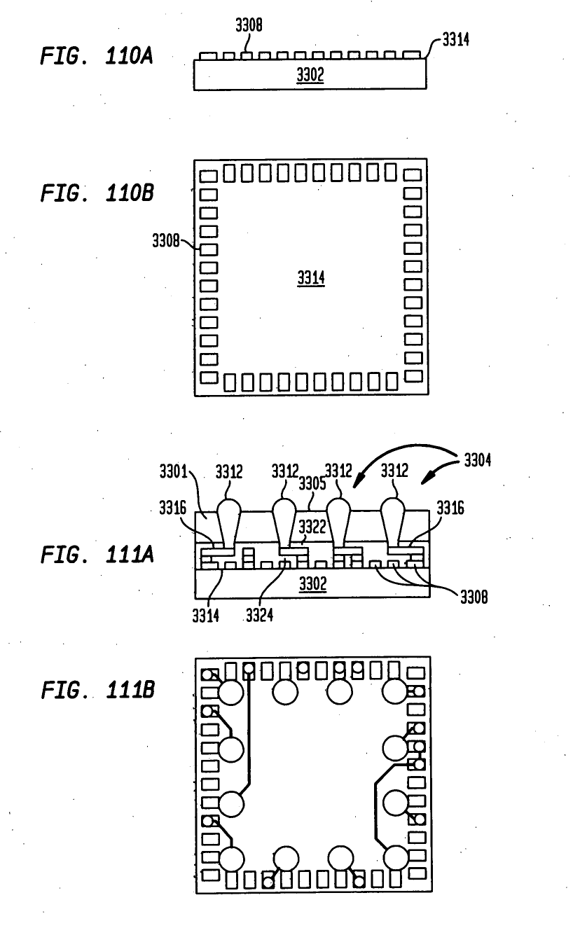

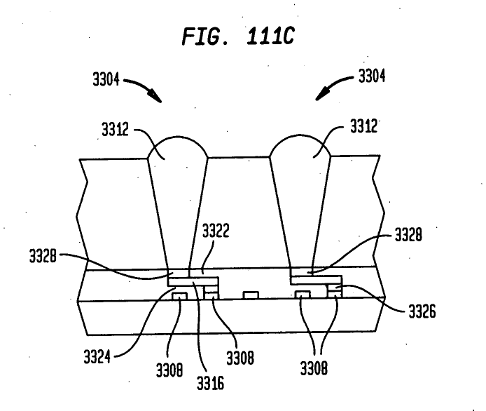

FIGS. 110A, 110B, 111A and 111B illustrate this concept. The layout of bond pads on the front face 3314 of a chip 3302 is illustrated in FIG. 111A (sectional view) and FIG. 110B, which is a plan view from above the front face 3314. Typically, only some of the external contacts of a chip carry signals or provide power or ground contacts which are essential to the operation of the chip as installed for its end use application. Others of the contacts are typically used only during production testing and/or pre-production testing and are not used in normal operation. This embodiment of the invention takes recognition that contacts at the exterior of a lidded chip package need only connect to those bond pads of a chip needed to interconnect the chip when installed for its end use application. No attempt is made to provide connectibility to all bond pads of a chip through the external contacts of the package.

Thus, a set of external contacts 3312 are exposed above an outer surface 3305 of the lid 3301 (FIG. 111A). In a particular embodiment as illustrated in the sectional view of FIG. 111A and in a top-down plan view in FIG. 111B, the external contacts are fewer in number than the bond pads 3308 at the front surface 3314 of the chip 3302. In the example illustrated in FIGS. 111A and 111B, there are about one quarter as many external contacts 3312 as there are bond pads on the chip. Conductive traces 3316 within the sealing medium between the lid and the chip conductively connect the bond pads 3308 to the external contacts 3312. Preferably, as shown in FIG. 111A and as best seen in FIG. 111C, the conductive traces 3316 are embedded within the sealing medium, such that at least portions of the conductive traces 3316 are disposed between a lower layer 3324 and a higher layer 3322 of the sealing medium. Conductive vias extend in vertical directions of the sealing medium for interconnecting the horizontally extending conductive traces with features of the chip and for interconnecting the conductive traces with the external contacts. Specifically, vias 3326 extend through a portion of the thickness of the sealing medium to interconnect the contacts 3308 of the chip to the conductive traces. Vias 3328 extend through another portion of the thickness of the sealing medium to interconnect the conductive traces 3316 to the external contacts 3312 of the chip.

Preferably, the external contacts 3312 are formed by any of the techniques described in the foregoing for forming conductive interconnects within through holes 3304 of a lid, including as described with respect to FIGS. 1 through 3C. In forming the external contacts 3312, a conductive material, e.g., a fusible conductive material such as solder, tin, or a eutectic material, or alternatively, a conductive polymeric material can be flowed into such through hole to contact a conductive via 3328 to conductively communicate with a portion of a conductive trace 3316 aligned to such through hole 3304. Alternatively, the conductive material can be flowed into an opening in the sealing medium aligned to the conductive trace 3316 and be allowed to solidify therein to form the conductive via 3328 and the external contact.

In another variation of the above embodiment, the external contacts can be fabricated by any one or more of the above-described techniques. For example, stud bumps can be formed on an exposed conductive surface of a via 3328 or conductive trace 3316 followed by the flowing on of a material to seal the through hole. In accordance with another variation, the external contacts are formed by a metal plating process, especially electroless plating, as electroless plating processes do not require the surface being plated to be maintained at a constant electric potential.

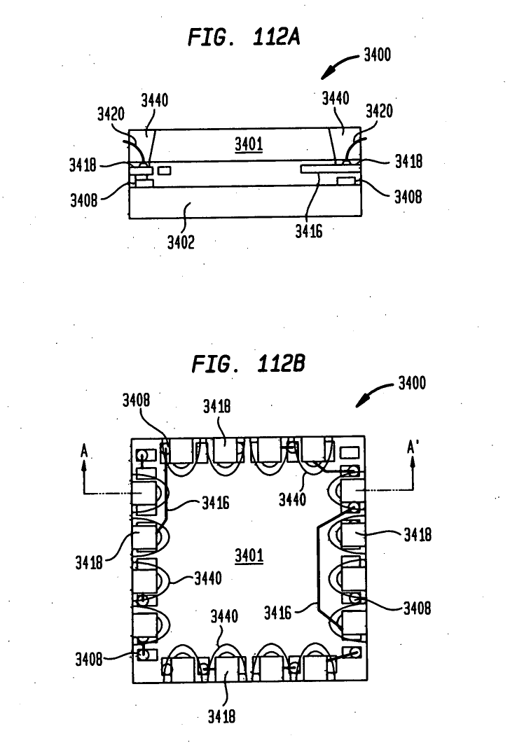

FIGS. 112A and 112B illustrate a variation of the embodiment shown in FIGS. 112A through 112C, in which the lid 3401 is similar to that shown in FIG. 85. In this variation, the external contacts 3412 of the packaged chip are exposed within recesses of the lid 3401. Here, the external contacts include upper bonding pads 3418 which extend over a layer of adhesive included within unit 3400, the upper bonding pads being connected to traces 3416. In turn, the traces 3416 are connected to bond pads 3408 provided at a front surface of the chip 3402. In the particular embodiment depicted in FIG. 112A, bond wires are metallurgically bonded to the upper bonding pads.

As these and other variations and combinations of the features discussed above can be utilized without departing from the present invention as defined by the claims, the foregoing description of the preferred embodiments should be taken by way of illustration rather than by way of limitation of the invention as defined by the claims.

1. A method of manufacturing a metal-containing lid for use in protectively covering a device region of a chip, comprising electro-forming a first metal layer on a mandrel having a first major surface, a second major surface opposite the first major surface, and a plurality of projections extending from at least one surface of the mandrel to form a plurality of through holes in the first metal layer corresponding to the projections and walls of the plurality of through holes are aligned at defined angles to the first major surface.

2. A method as claimed in claim 1, wherein the metal layer consists essentially of at least one of copper or nickel, the method further comprising depositing a layer including aluminum to overlie at least portions of the through holes.

3. A method as claimed in claim 2, wherein the layer of aluminum overlies a portion of at least one of the first and major surfaces of the metal layer.

4. A method as claimed in claim 2, further comprising anodizing the layer including aluminum to form an insulating layer including anodized aluminum overlying at least a portion of the first metal layer.

5. A method as claimed in claim 1, further comprising depositing an insulating material over the first metal to form an insulating layer overlying at least a portion of the first metal layer.

6. A method as claimed in claim 5, wherein the insulating material includes a polymer.

7. A method as claimed in claim 5, wherein the insulating material has a thickness of at least one micron.

8. A method as claimed in claim 4, wherein the anodized aluminum layer has a pore height from between about 10 microns and about 100 microns.

9. A method as claimed in claim 8, wherein the anodized aluminum layer has a thickness at least about one micron.

10. A method as claimed in claim 4, wherein the step of anodizing the layer includes imparting one of a plurality of selectable colors to the anodized layer.

11. A method as claimed in claim 1, further comprising interconnecting at least some bond pads of the chip to the first metal layer of the lid, such that the lid functions as a ground plane.

12. A packaged magnetically shielded memory including magnetoresistive (“MR”) storage cells, comprising:
a chip including a memory with a plurality of MR storage cells, the chip having a front face, a rear face remote from the front face and a plurality of bond pads exposed at the front face;
a first layer of material having a relatively high magnetic permeability underlying the rear face of the chip;
a second layer of material having a relatively high magnetic permeability overlying the front face of the chip and having a plurality of through holes aligned with the bond pads at the front face; and
a plurality of conductive interconnections extending from the bond pads at least partially through the through holes.

13. A packaged memory as claimed in claim 12, further comprising dielectric layers lining said through holes in said second layer and wettable metal layers overlying said dielectric layers, wherein the conductive interconnections include a fusible material overlying said wettable metal layers.

14. A packaged memory as claimed in claim 13, wherein the wettable metal layers overlie intermediate metal layers and the intermediate metal layers overlie contact metal layers contacting the dielectric layers.

15. A packaged memory as claimed in claim 14, wherein the memory includes a magnetoresistive random access memory (“MRAM”).

16. A packaged memory as claimed in claim 12, wherein the first and second layers include mu-metals.

17. A packaged memory as claimed in claim 12, wherein the through holes have a first widths at an inner surface of said second layer and have second widths wider than said first widths at an outer surface of said second layer, wherein walls of the through holes are inclined outwardly between the inner surface and the outer surface.

18. A method of fabricating a plurality of packaged magnetically shielded memory chips each including magnetoresistive (“MR”) storage cells, comprising:
providing a wafer element including a plurality of the chips with the first layer having a high magnetic permeability underlying the rear face of the wafer element and a second layer having a high magnetic permeability overlying the front face of the wafer and having a plurality of through holes aligned to bond pads of chips within the wafer element; and
forming a plurality of conductive interconnections extending from the bond pads at least partially through the through holes.

19. A lidded optical chip, comprising:
a chip having a device region and bond pads exposed at a front surface of the chip;
a lid including a light transmissive inorganic material mounted above the front surface of the chip, the lid having an inner surface disposed adjacent to the front surface of the chip and an outer surface remote from the front surface;
at least one optical layer at least one of overlying the outer surface or underlying the inner surface of the lid, the at least one optical layer including an organic material operable to perform at least one of altering an optical characteristic of light incident on the optical layer, or to impart a property to the lid.

20. A lidded chip as claimed in claim 19, wherein the optical layer is operable to perform at least one of filtering the light incident on the optical layer or to impart at least one of an anti-reflective, anti-static, anti-fogging, or anti-scratch property to the lid.

21. A lidded chip as claimed in claim 20, wherein the at least one optical layer includes a first optical layer overlying the outer surface and a second optical layer underlying the inner surface.

22. A method of making a microelectronic device comprising:
(a) assembling a lid element with a wafer element, the wafer element having a front surface including a plurality of regions, each such region including an active area and a plurality of contacts exposed at said front surface outside of said active area, said lid element overlying said front surface of said wafer element; then
(b) forming holes in said lid element so as to expose individual ones of said contacts; and
(c) severing said wafer element and said lid element along severance lines intersecting said holes to thereby form a plurality of units, each such unit including a lid having one or more holes aligned to individual ones of said contacts.

23. A method of making a microelectronic device comprising:
(a) assembling a lid element with a wafer element, the wafer element having a front surface including a plurality of regions, each such region including an active area and a plurality of contacts exposed at said front surface outside of said active area, said lid element overlying said front surface of said wafer element; then
(b) drilling holes in said lid element to expose said contacts; and
(c) severing said wafer element and said lid element along severance lines to thereby form a plurality of units, each such unit including a lid having one or more openings aligned with said contacts, said openings coinciding with said holes.

24. A method as claimed in claim 23, wherein said lid element has an outer surface and an inner surface, said assembling step is performed so that said outer surface faces upwardly, away from said wafer unit, and said hole-forming step is performed so that said holes taper inwardly in a downward direction from said outer surface toward said inner surface.

25. A method as claimed in claim 23, further comprising providing a seal extending between said wafer unit and said lid element, said seal overlying said contacts, and forming holes in said seal in alignment with said holes in said lid element prior to said severing step.

26. A method as claimed in claim 25, wherein said holes in said seal are formed by laser drilling after said holes are formed in said lid element.

27. A method as claimed in claim 25, wherein said holes in said seal are formed by etching after forming said holes in said lid element.

28. A method as claimed in claim 23, wherein said step of drilling is performed using an ultrasonic drilling tool.

29. A method as claimed in claim 28, wherein said ultrasonic drilling tool includes removable rods for contacting said outer surface of said lid element to form said holes, said removable rods being removable when worn and replaceable with other removable rods.

30. A method as claimed in claim 25, wherein, prior to said hole-forming step, said lid element has planar inner and outer surfaces.

31. A method as claimed in claim 23, wherein said step of drilling said holes in said lid element is performed using an ultrasonic tool, wherein said lid element is severed along said lines of severance by simultaneously machining said lid element with said ultrasonic tool while drilling said holes in said lid element.

32. A method as claimed in claim 31, wherein said seal includes at least a portion having a low modulus of elasticity, said seal underlying said severance lines of said lid element and said lid element is severed such that at least a portion of said seal underlying said severance lines remains after said lid element is severed during said simultaneous machining.

33. A method as claimed in claim 32, further comprising severing said wafer element along severance lines of said wafer after drilling said holes and machining said lid element.

34. A method as claimed in claim 33, wherein said seal includes at least a portion having a low modulus of elasticity, said seal underlying said severance lines of said wafer element and said wafer element is severed such that at least a portion of said seal underlying said severance lines of said wafer element remains after said wafer element is severed, said remaining portion of said seal connecting portions of said lid element and said wafer element severed by said machining of said lid element and said step of severing said wafer element.

35. A packaged chip-on-board optoelectronic assembly, comprising:
a circuit panel having a major surface and a recess extending downwardly from said major into a body of said circuit panel;
an optoelectronic chip having a front face and a rear face remote from said front face, an optoelectronic device exposed at said front face, said rear face disposed below said major surface within said recess; and
a turret mounted to said circuit panel, said turret having an optical element aligned to said optoelectronic device of said chip.

36. A packaged assembly as claimed in claim 35, wherein said rear face of said chip is bonded to said circuit panel within said recess.

37. A packaged assembly as claimed in claim 36, wherein said chip is bonded with a die attach adhesive to said circuit panel, wherein said die attach adhesive is disposed wholly below said major surface of said circuit panel.

38. A packaged assembly as claimed in claim 37, wherein said recess is a blind cavity, wherein dimensions of said recess align said chip to said turret.

39. A packaged assembly as claimed in claim 38, wherein said dimensions align said chip to said turret with respect to translation and rotation.

40. A packaged assembly as claimed in claim 35, wherein said recess is a first recess, said circuit panel further including at least one second recess, wherein said turret includes at least one member mounted to said circuit panel within said second recess.

41. A packaged assembly as claimed in claim 40, wherein said member at least assists in aligning said turret to said circuit panel.

42. A packaged assembly as claimed in claim 41, wherein said circuit panel includes a plurality of said second recesses and a plurality of said members mounted to said circuit panel within said second recesses, said members positively aligning said turret to said circuit panel with respect to translation and rotation.

43. A packaged assembly as claimed in claim 42, wherein joints between said members of said turret and said circuit panel include adhesives bonding multiple surfaces of said members to inner walls of said second recesses.

44. A lidded chip, comprising:
a chip having an upwardly facing front surface and a plurality of bond pads exposed in a bond pad region at said front surface;
a lid having an outer surface, an inner surface opposite said outer surface, and a plurality of openings extending between said inner and outer surfaces, said lid being mounted to said chip and spaced therefrom to define a void;
a plurality of electrically conductive interconnects extending at least partially through said openings;
a heat spreader mounted to a rear surface of said chip opposite from said front surface, said heat spreader covering substantially all of said rear surface.

45. A lidded chip as claimed in claim 44, wherein a mechanical strength of said lidded chip is increased by presence of said heat spreader.

46. A lidded chip as claimed in claim 45, wherein said bond pad region extends to edges of said chip and each of said openings extends in a direction along said edges to expose a plurality of said bond pads.

47. A lidded chip as claimed in claim 44, wherein each of said edges of said chip and said heat spreader are aligned.

48. A lidded chip, comprising:
a chip having a device including at least one device selected from a microelectronic or a micro-electromechanical device at a front face of the chip; and
a lid overlying the at least one device;
a supporting structure overlying the front face and supporting the lid above the front face, the supporting structure having a first material affixed to one of an inner surface of the lid or the front face of the chip; and
an adhesive including a second material joining the supporting structure to the other of the inner surface of the lid or the front face of the chip.

49. A method of making a lidded chip as claimed in claim 48, wherein the adhesive is a flowable adhesive applied to an exposed surface of the supporting structure to join the supporting structure to the other of the inner surface of the lid or the front face of the chip.

50. A method of making a lidded chip as claimed in claim 49, wherein the adhesive is applied to the exposed surface of the supporting structure using a roller.

51. A lidded chip as claimed in claim 48, wherein the adhesive has a thickness of about 1 micron.

52. A lidded chip as claimed in claim 48 wherein the thickness of the supporting structure in a direction of a height of the inner surface of the lid above the front surface is at least about ten times the thickness of the adhesive in that direction.

53. A lidded chip as claimed in claim 48 wherein the supporting structure is affixed to the inner surface of the lid.

54. A lidded chip as claimed in claim 48, wherein the supporting structure is affixed to the front face of the chip.

55. A lidded chip as claimed in claim 49, further comprising a plurality of conductive interconnects exposed at an outer surface of the lid, the conductive interconnects extending from contacts on the front face of the chip at least partially through the through holes in the lid.
